(19) United States
(12) Patent Application Publication
(10) Pub. No.: US 2026/0259494 A1
(43) Pub. Date: Sep. 3, 2026

(54) RESIN COMPOSITION, CURED PRODUCT, LAMINATE, METHOD FOR PRODUCING CURED PRODUCT, METHOD FOR PRODUCING LAMINATE, METHOD FOR PRODUCING SEMICONDUCTOR DEVICE, SEMICONDUCTOR DEVICE, AND METHOD FOR PRODUCING RESIN

(71) Applicant: FUJIFILM Corporation, Tokyo (JP)

(72) Inventors: Michihiro Ogawa, Shizuoka (JP); Kazuya Oota, Shizuoka (JP)

(73) Assignee: FUJIFILM Corporation, Tokyo (JP)

(21) Appl. No.: 19/649,535

(22) Filed: Apr. 16, 2026

Related U.S. Application Data
(63) Continuation of application No. PCT/JP2024/040135, filed on Nov. 12, 2024.

(30) Foreign Application Priority Data
Nov. 13, 2023 (JP) 2023-193254

(51) Int. Cl. G03F 7/038; C08G 73/14; H10W 70/695

(52) U.S. Cl. CPC G03F 7/0388; C08G 73/14; H10W 70/695

(57) ABSTRACT

A resin composition including a resin having at least one repeating unit selected from the group consisting of a repeating unit represented by Formula (1-2), a repeating unit represented by Formula (1-3), and a repeating unit represented by Formula (1-4), a polymerization initiator, and a solvent, in which an imidization rate of the resin is 40% to 85%; a cured product obtained by curing the composition, and a producing method therefor; a laminate including the cured product, and a producing method therefor; a semiconductor device, and a producing method therefor; and a method for producing a resin.

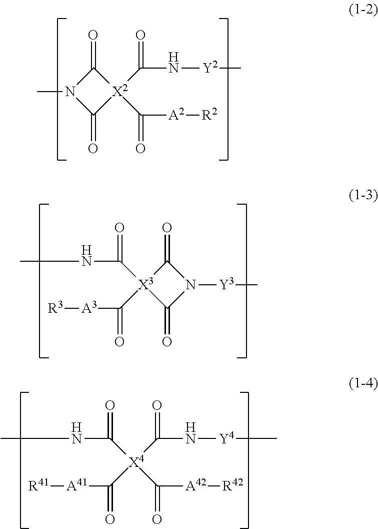

### CROSS-REFERENCE TO RELATED APPLICATIONS

This application is a Continuation of PCT International Application No. PCT/JP2024/040135 filed on Nov. 12, 2024, which claims priority under 35 U.S.C § 119(a) to Japanese Patent Application No. 2023-193254 filed on Nov. 13, 2023. Each of the above application(s) is hereby expressly incorporated by reference, in its entirety, into the present application.

### BACKGROUND OF THE INVENTION

### 1. Field of the Invention

The present invention relates to a resin composition, a cured product, a laminate, a method for producing a cured product, a method for producing a laminate, a method for producing a semiconductor device, a semiconductor device, and a method for producing a resin.

### 2. Description of the Related Art

In recent years, a resin material that has been produced from a resin composition containing a resin has been utilized in various fields.

A resin such as a polyimide is applied to various use applications since it has an excellent heat resistance and insulating properties. The above-described use applications are not particularly limited, and examples thereof in a semiconductor device for mounting include the use as a material of an insulating film or sealing material, or as a protective film. In addition, such a resin can also be used as a base film, a coverlay, or the like for a flexible substrate.

For example, in the above-described applications, a resin such as polyimide is used in the form of a resin composition containing a resin such as a polyimide precursor.

Such a resin composition is applied onto a base material by coating or the like to form a photosensitive film, and then, as necessary, subjected to exposure, development, or heating, whereby a cured product can be formed on the base material.

Since the resin composition can be applied by a publicly known coating method or the like, it can be said that the resin composition is excellent in the manufacturing adaptability, for example, a high degree of freedom in designing the shape, size, application position during application of the resin composition to be applied. From the viewpoint of such excellent manufacturing adaptability in addition to the high performance possessed by the polyimide, the industrial application and development of the above-described resin composition are expected increasingly.

For example, JP2022-054416A discloses a photosensitive resin composition containing: a polyimide precursor having a specific structure: 100 parts by mass; (B) a photosensitizer: 0.5 to 10 parts by mass; and (D) a solvent: 100 to 300 parts by mass, in which a value of an imidization rate b, which is obtained by dividing an imidization index of a photosensitive resin layer before exposure, which is obtained by removing the solvent from the photosensitive resin composition, the imidization index being obtained by dividing a peak intensity in a vicinity of 1380 cm⁻¹ by a peak intensity in a vicinity of 1500 cm⁻¹ in an infrared absorption spectrum of the photosensitive resin layer by an ATR (Attenuated Total Reflection) method, by an imidization index of a cured film obtained by heating and curing the photosensitive resin composition at 350° C., is 15% to 50%, and in a polyimide of the cured polyimide film, an imide group concentration a, which is a proportion of an imide group to a molecular weight of a repeating unit including a structure derived from a tetracarboxylic acid and a diamine, is 12 wt % to 30 wt %.

### SUMMARY OF THE INVENTION

In a case where a cured product formed from a resin composition containing polyimide or a precursor thereof is used as an insulating member or the like in a wiring pattern, it is required to suppress unevenness during coating of the resin composition and to suppress shrinkage during curing in order to obtain a desired shape, dimension, and the like of the cured product.

An object of the present invention is to provide a resin composition with which a cured product in which unevenness during coating and shrinkage during curing are suppressed can be obtained, a cured product obtained by curing the resin composition, a laminate including the cured product, a method for producing a cured product, a method for producing a laminate, a method for producing a semiconductor device including the method for producing a cured product, and a semiconductor device including the cured product.

In addition, an object of the present invention is to provide a novel method for synthesizing a resin.

Examples of representative aspects according to the present invention are described below.

<1> A resin composition including a resin having at least one repeating unit selected from the group consisting of a repeating unit represented by Formula (1-2), a repeating unit represented by Formula (1-3), and a repeating unit represented by Formula (1-4),
a polymerization initiator, and
a solvent,
in which an imidization rate of the resin is 40% to 85%.

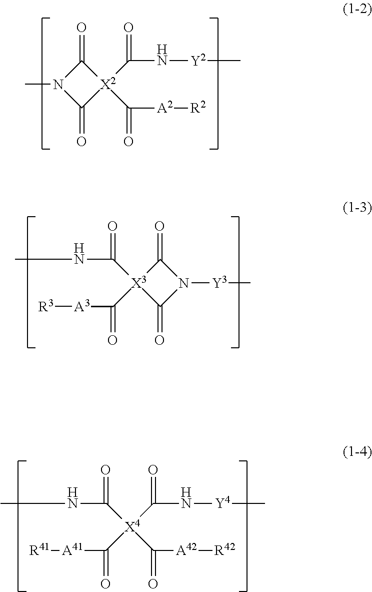

In Formula (1-2), A² is —O— or —NR^{Z}—, R^{Z} is a hydrogen atom or a monovalent organic group, R² is a hydrogen atom or a monovalent organic group, X² is a tetravalent organic group, and Y² is a divalent organic group.

In Formula (1-3), A³ is —O— or —NR^{Z}—, R^{Z} is a hydrogen atom or a monovalent organic group, R³ is a hydrogen atom or a monovalent organic group, X³ is a tetravalent organic group, and Y³ is a divalent organic group.

In Formula (1-4), A⁴¹ and A⁴² are each independently —O— or —NR^{Z}—, R^{Z} is a hydrogen atom or a monovalent organic group, R⁴¹ and R⁴² are each independently a hydrogen atom or a monovalent organic group, X⁴ is a tetravalent organic group, and Y⁴ is a divalent organic group.

<2> The resin composition according to <1>, in which the resin includes at least one repeating unit selected from the group consisting of a repeating unit A-2, a repeating unit A-3, and a repeating unit A-4.

Repeating unit A-2: a repeating unit represented by Formula (1-2), in which X² is any of structures represented by Formulae (2a) to (2g)

Repeating unit A-3: a repeating unit represented by Formula (1-3), in which X³ is any of structures represented by Formulae (2a) to (2g)

Repeating unit A-4: a repeating unit represented by Formula (1-4), in which X⁴ is any of structures represented by Formulae (2a) to (2g)

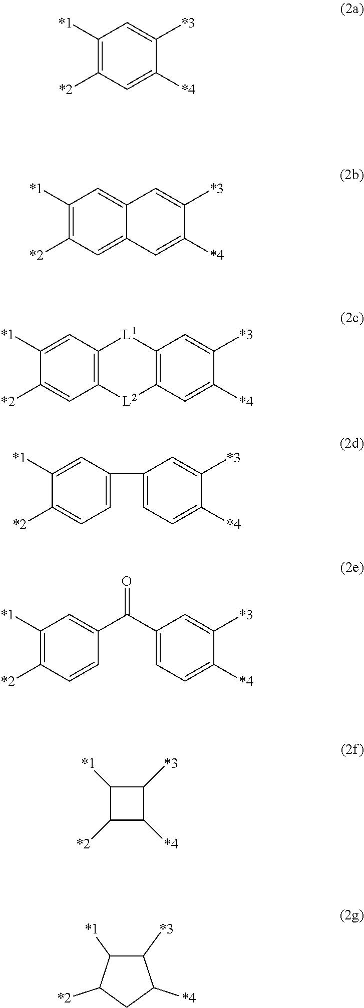

In Formulae (2a) to (2g), L¹ and L² are each independently a divalent group that is not conjugated with a benzene ring to which each of L¹ and L² is bonded, or a single bond, *1 to *4 each represent a bonding site to the carbonyl group described in Formula (1-2), Formula (1-3), or Formula (1-4), and hydrogen atoms in these structures may be substituted with a substituent.

<3> The resin composition according to <2>, in which the resin further includes at least one repeating unit selected from the group consisting of a repeating unit B-2, a repeating unit B-3, and a repeating unit B-4.

Repeating unit B-2: a repeating unit represented by Formula (1-2), in which X² includes a structure obtained by removing two or more hydrogen atoms from a structure represented by any of Formulae (V-1) to (V-10)

Repeating unit B-3: a repeating unit represented by Formula (1-3), in which X³ includes a structure obtained by removing two or more hydrogen atoms from a structure represented by any of Formulae (V-1) to (V-10)

Repeating unit B-4: a repeating unit represented by Formula (1-4), in which X⁴ includes a structure obtained by removing two or more hydrogen atoms from a structure represented by any of Formulae (V-1) to (V-10)

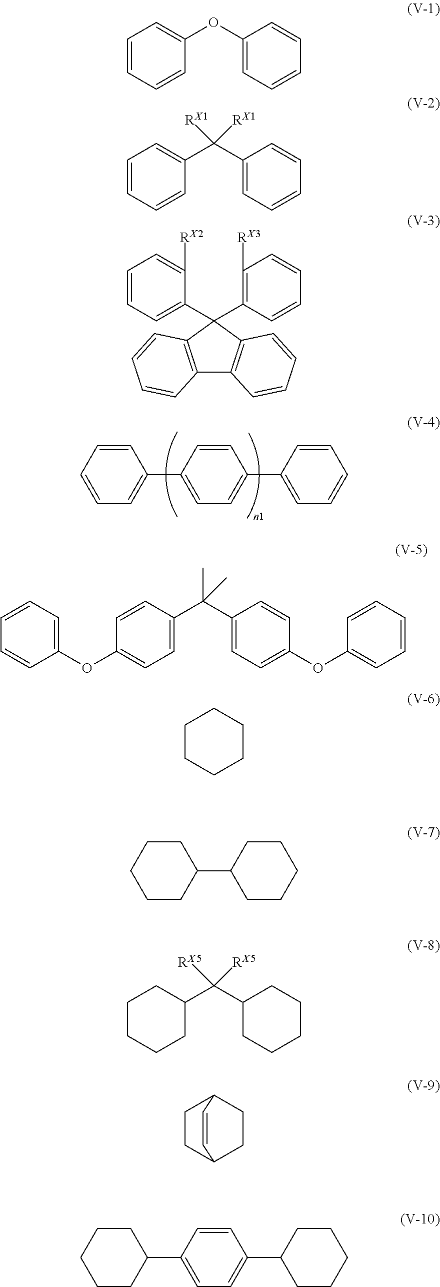

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

In Formula (V-4), n1 represents an integer of 1 or more.

In Formula (V-8), R^{X5}'s each independently represent a hydrogen atom, an alkyl group, or a halogenated alkyl group.

<4> The resin composition according to any one of <1> to <3>, in which the resin includes at least one repeating unit selected from the group consisting of a repeating unit represented by Formula (1-2), in which R² is a monovalent organic group having an ethylenically unsaturated bond, a repeating unit represented by Formula (1-3), in which R³ is a monovalent organic group having an ethylenically unsaturated bond, and a repeating unit represented by Formula (1-4), in which at least one of R⁴¹ or R⁴² is a monovalent organic group having an ethylenically unsaturated bond.

<5> The resin composition according to any one of <1> to <4>, in which the resin includes at least one repeating unit selected from the group consisting of a repeating unit represented by Formula (1-2), in which Y² is a structure including a structure represented by Formulae (C-1) to (C-5), a repeating unit represented by Formula (1-3), in which Y³ is a structure including a structure represented by Formulae (C-1) to (C-5), and a repeating unit represented by Formula (1-4), in which Y⁴ is a structure including a structure represented by Formulae (C-1) to (C-5).

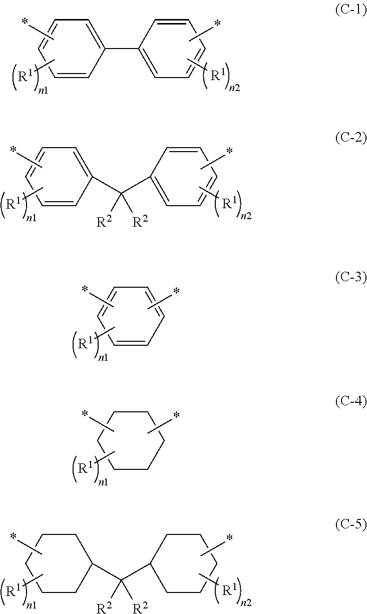

In Formula (C-1), R¹'s each independently represent a hydrogen atom or a monovalent organic group, n1 represents an integer of 0 to 3, n2 represents an integer of 0 to 3, and * represents a bonding site to another structure.

In Formula (C-2), R¹'s each independently represent a hydrogen atom or a monovalent organic group, n1 represents an integer of 0 to 3, n2 represents an integer of 0 to 3, R²'s each independently represent an alkyl group or a fluoroalkyl group, and * represents a bonding site to another structure.

In Formula (C-3), R¹'s each independently represent a hydrogen atom or a monovalent organic group, n1 represents an integer of 0 to 3, and * represents a bonding site to another structure.

In Formula (C-4), R¹'s each independently represent a hydrogen atom or a monovalent organic group, n1 represents an integer of 0 to 3, and * represents a bonding site to another structure.

In Formula (C-5), R¹'s each independently represent a hydrogen atom or a monovalent organic group, n1 represents an integer of 0 to 3, n2 represents an integer of 0 to 3, R²'s each independently represent an alkyl group or a fluoroalkyl group, and * represents a bonding site to another structure.

<6> The resin composition according to any one of <1> to <5>, in which the resin includes a repeating unit represented by Formula (1-1).

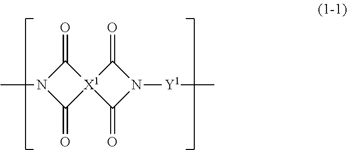

X¹ is a tetravalent organic group, and Y¹ is a divalent organic group.

<7> The resin composition according to any one of <1> to <6>, in which a weight-average molecular weight of the resin is 5,000 or more and less than 120,000.

<8> The resin composition according to any one of <1> to <7>, in which the resin composition contains no polymerizable compound or contains a polymerizable compound in an amount of less than 15% by mass with respect to a total solid content.

<9> The resin composition according to any one of <1> to <7>, in which the resin composition contains no polymerizable compound or contains a polymerizable compound in an amount of 10 parts by mass or less with respect to 100 parts by mass of the resin.

<10> The resin composition according to any one of <1> to <7>, in which the resin composition contains a polymerizable compound in an amount of 1 to 10 parts by mass with respect to 100 parts by mass of the resin.

<11> The resin composition according to any one of <1> to <10>, in which the imidization rate is 55% or more and less than 70%.

<12> The resin composition according to any one of <1> to <11>, in which the resin composition is a negative-type photosensitive resin composition.

<13> The resin composition according to any one of <1> to <12>, in which the resin composition is used for forming an interlayer insulating film for a re-distribution layer.

<14> A cured product obtained by curing the resin composition according to any one of <1> to <13>.

<15> A laminate including two or more layers consisting of the cured product according to <14>, and a metal layer provided between any of the layers consisting of the cured product.

<16> A method for producing a cured product, further including a film forming step of applying the resin composition according to any one of <1> to <13> onto a base material to form a film.

<17> The method for producing a cured product according to <16>, further including an exposure step of selectively exposing the film; and a development step of developing the film using a developer to form a pattern.

<18> The method for producing a cured product according to <16> or <17>, further including a heating step of heating the film at 50° C. to 450° C.

<19> A method for producing a laminate, including the method for producing a cured product according to any one of <16> to <18>.

<20> A method for producing a semiconductor device, including the method for producing a cured product according to any one of <16> to <18>.

<21> A semiconductor device including the cured product according to <14>.

<22> A method for producing a resin, including a step of synthesizing a polyimide oligomer having an amino group at a terminal, and
a step of reacting the polyimide oligomer with a compound represented by Formula (A-1).

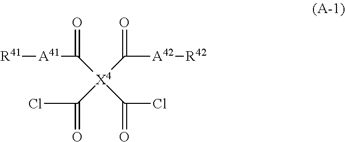

In Formula (A-1), A⁴¹ and A⁴² are each independently —O— or —NR^{Z}—, R^{Z} is a hydrogen atom or a monovalent organic group, R⁴¹ and R⁴² are each independently a hydrogen atom or a monovalent organic group, and X⁴ is a tetravalent organic group.

According to the present invention, there are provided a resin composition from which a cured product in which unevenness during coating and shrinkage during curing are suppressed is obtained, a cured product obtained by curing the resin composition, a laminate including the cured product, a method for producing a cured product, a method for producing a laminate, a method for producing a semiconductor device including the method for producing a cured product, and a semiconductor device including the cured product.

In addition, according to the present invention, there is provided a novel method for synthesizing a resin.

### DESCRIPTION OF THE PREFERRED EMBODIMENTS

Hereinafter, the main embodiments according to the present invention will be described. However, the present invention is not limited to the specified embodiments.

In the present specification, a numerical value range described by using “to” means a range including numerical values described before and after the preposition “to” as a lower limit value and an upper limit value, respectively.

In the present specification, the term “step” means not only an independent step but also a step that cannot be clearly distinguished from other steps as long as the desired action of the step can be achieved.

In describing a group (an atomic group) in the present specification, in a case where a description of substitution and unsubstitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

In the present specification, the “exposure” includes not only exposure using light but also exposure using corpuscular beams such as an electron beam and an ion beam, unless otherwise specified. In addition, examples of the light that is used for exposure include actinic rays or radiation such as an emission line spectrum of a mercury lamp, a far ultraviolet ray represented by an excimer laser, an extreme ultraviolet ray (EUV light), an X-ray, or an electron beam.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the structural formulae of the present specification, Me represents a methyl group, Et represents an ethyl group, Bu represents a butyl group, and Ph represents a phenyl group.

In the present specification, the total solid content refers to the total mass of components excluding a solvent from the entire components of the composition. In addition, in the present specification, the concentration of solid contents is a mass percentage of other components excluding a solvent with respect to the total mass of the composition.

In the present specification, weight-average molecular weight (Mw) and number-average molecular weight (Mn) are each a value measured using gel permeation chromatography (GPC) unless otherwise specified, which are defined as a polystyrene equivalent value. In the present specification, the weight-average molecular weight (Mw) and the number-average molecular weight (Mn) can be determined, for example, by using HLC-8220 GPC (manufactured by Tosoh Corporation) and using GUARD COLUMN HZ-L, TSKgel Super HZM-M, TSK gel Super HZ4000, TSK gel Super HZ3000, and TSK gel Super HZ2000 (all of which are manufactured by Tosoh Corporation) as a column connected in series. The molecular weights thereof are measured using N-methyl-2-pyrrolidone (NMP) as an eluant unless otherwise specified. However, in a case where NMP is not suitable as an eluent, for example, in a case where the solubility is low, tetrahydrofuran (THF) can also be used. In addition, the detection in GPC measurement is carried out using a detector with an ultraviolet ray (a UV ray) of a wavelength of 254 nm unless otherwise specified.

In the present specification, in a case where the positional relationship of respective layers constituting the laminate is described as “upper” or “lower”, it suffices that another layer is on the upper side or the lower side of the reference layer among the plurality of layers of interest. That is, a third layer or element may be further interposed between the reference layer and the other layer, and the reference layer and the other layer need not be in contact with each other. Unless otherwise specified, the direction in which the layers are laminated on the base material is referred to as “upward”, or in a case where a resin composition layer is present, the direction from the base material to the resin composition layer is referred to as “upper”. The opposite direction thereof is referred to as “downward”. It is noted that such a setting of the upward or downward direction is for convenience in the present specification, and in an actual aspect, the “upward” direction in the present specification may be different from the vertically upward direction.

In the present specification, a composition may contain, as each component contained in the composition, two or more compounds corresponding to the component unless otherwise particularly specified. The content of each component in the composition means the total content of all the compounds corresponding to the component unless otherwise specified.

In the present specification, unless otherwise specified, the temperature is 23° C., the atmospheric pressure is 101,325 Pa (1 atm), and the relative humidity is 50% RH.

In addition, in the present specification, a combination of preferred aspects is a more preferred aspect.

### (Resin Composition)

The resin composition according to the embodiment of the present invention contains a resin having at least one repeating unit selected from the group consisting of a repeating unit represented by Formula (1-2), a repeating unit represented by Formula (1-3), and a repeating unit represented by Formula (1-4), a polymerization initiator, and a solvent, in which an imidization rate of the resin is 40% to 85%.

In the present invention, the resin having at least one repeating unit selected from the group consisting of a repeating unit represented by Formula (1-2), a repeating unit represented by Formula (1-3), and a repeating unit represented by Formula (1-4), and having an imidization rate of 40% to 85% is also referred to as a “specific resin”.

The resin composition according to the embodiment of the present invention is preferably used for forming a photosensitive film that is subjected to exposure and development, and more preferably used for forming a film that is subjected to exposure and development using a developer containing an organic solvent.

The resin composition according to the embodiment of the present invention can be used, for example, for forming an insulating film of a semiconductor device, an interlayer insulating film for a re-distribution layer, or a stress buffer film, and it is preferably used for forming an interlayer insulating film for a re-distribution layer.

The resin composition according to the embodiment of the present invention is preferably a negative-type photosensitive resin composition. In the present invention, the resin composition used for forming a photosensitive film to be subjected to negative tone development is referred to as a negative-type photosensitive resin composition.

In the present invention, the negative tone development refers to development in which, in exposure and development, a non-exposed portion is removed by the development, and the positive tone development means a development in which an exposed portion is removed by the development.

As the exposure method, the developer, and the development method, for example, the following ones in the description of the method for producing a cured product, which will be described later, are used: an exposure method to be described in the exposure step, and a developer and a development method to be described in the development step.

According to the resin composition of the present invention, unevenness during coating of the resin composition is suppressed, and shrinkage during curing is suppressed.

The present inventors have found that the above-described objects can be achieved by using a specific resin.

The mechanism by which the effect is obtained by the above-described configuration is not clear, but is presumed as follows.

The present inventors have found that it is effective to increase the concentration of solid contents of the composition in order to reduce unevenness during coating, and it is effective to increase the imidization rate of the resin to reduce components to be eliminated from the resin during curing in order to suppress shrinkage during curing.

However, it has been found that, in a case where the imidization rate of the resin is too high, the resin is not dissolved in the solvent in the composition, and the resin cannot be handled.

It is considered that, in a case where the imidization rate of the resin is 40% or more, the components to be eliminated from the resin during curing can be reduced, and thus the curing shrinkage is suppressed.

In addition, it is considered that, in a case where the imidization rate of the resin is 85% or less, the solubility of the resin in the solvent can be ensured to some extent, and thus the concentration of solid contents of the composition can be increased, and the coating unevenness is suppressed.

Here, JP2022-054416A does not describe a resin composition containing a specific resin.

Hereinafter, the components contained in the resin composition according to the embodiment of the present invention will be described in detail.

### <Specific Resin>

The resin composition according to the embodiment of the present invention contains a resin (specific resin) having at least one repeating unit selected from the group consisting of a repeating unit represented by Formula (1-2), a repeating unit represented by Formula (1-3), and a repeating unit represented by Formula (1-4), in which the imidization rate is 40% to 85%,

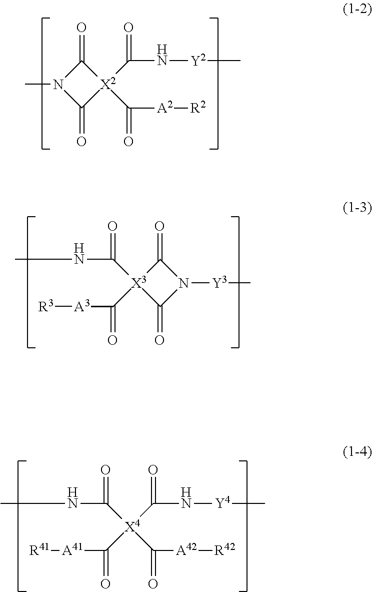

In Formula (1-2), A² is —O— or —NR^{Z}—, R^{Z} is a hydrogen atom or a monovalent organic group, R² is a hydrogen atom or a monovalent organic group, X² is a tetravalent organic group, and Y² is a divalent organic group.

In Formula (1-3), A³ is —O— or —NR^{Z}—, R^{Z} is a hydrogen atom or a monovalent organic group, R³ is a hydrogen atom or a monovalent organic group, X³ is a tetravalent organic group, and Y³ is a divalent organic group.

In Formula (1-4), A⁴¹ and A⁴² are each independently —O— or —NR^{Z}—, R^{Z} is a hydrogen atom or a monovalent organic group, R⁴¹ and R⁴² are each independently a hydrogen atom or a monovalent organic group, X⁴ is a tetravalent organic group, and Y⁴ is a divalent organic group.

The specific resin is preferably a polyimide precursor.

The polyimide precursor refers to a resin which is polyimide due to a change in chemical structure caused by an external stimulus, and a resin which is polyimide due to a change in chemical structure caused by heat is preferable, and a resin which is polyimide due to a ring closure reaction caused by heat to form a ring structure is more preferable.

In the present invention, the polyimide refers to a resin having a repeating unit containing an imide group in a molecular chain, and a resin having a repeating unit containing an imide ring structure in a molecular chain is preferable.

In addition, in a case where the polyimide is a linear resin, the polyimide is preferably a resin having a repeating unit containing an imide group in a main chain, and more preferably a resin having a repeating unit containing an imide ring structure in a main chain.

In the present specification, the “main chain” represents a relatively longest bonding chain in a resin molecule, and the “side chain” refers to other bonding chains.

In the present specification, the imide group refers to a structure represented by *—C(═O)N(—*)C(═O)—*, in which * represents a bonding site to other structures, and is preferably a bonding site to a carbon atom and more preferably a bonding site to a quaternary carbon atom.

In the present specification, the imide ring structure refers to a ring structure including two carbon atoms and all nitrogen atoms in the imide as ring members. The imide ring structure is preferably a 5-membered ring.

The polyimide may be a so-called polyamideimide having an amide group in a molecular chain in addition to the imide group. In the present specification, the amide group refers to a structure represented by *—C(═O)N(-#)-*, in which * represents a bonding site to other structures, and is preferably a bonding site to a carbon atom and more preferably a bonding site to a quaternary carbon atom. In addition, #represents a bonding site to other structures, and is preferably a bonding site to a hydrogen atom or a carbon atom and more preferably a bonding site to a hydrogen atom.

The specific resin preferably has a polymerizable group and more preferably contains a radically polymerizable group.

In a case where the specific resin has a radically polymerizable group, the resin composition according to the embodiment of the present invention preferably contains a radical polymerization initiator as a polymerization initiator. In addition, from the viewpoint of resolution, it is also preferable that the resin composition contains a radical polymerization initiator and a radical crosslinking agent.

Furthermore, a sensitizer can be contained in these aspects as necessary. From such a resin composition, for example, a negative-type photosensitive film is formed.

In addition, the specific resin may have a polarity converting group such as an acid-decomposable group.

In a case where the specific resin has an acid-decomposable group, it is preferable that the resin composition contains a photoacid generator. From such a resin composition, for example, a positive-type photosensitive film or a negative-type photosensitive film, which is a chemical amplification type photosensitive film, is formed.

### [Imidization Rate]

In the present invention, the imidization rate is a value calculated by the following method.

The resin is dissolved in γ-butyrolactone, diluted so that the viscosity is 2,000 mPa·s, and applied onto a silicon wafer by a spin coating method to form a resin layer. In a case where the resin layer cannot be formed due to the reason that the solubility of the resin in γ-butyrolactone is low, the solvent may be changed to another solvent. As the other solvents, solvents contained in the resin composition can also be used, and examples thereof include NMP.

In addition, the viscosity may be appropriately changed within a range in which the viscosity can be adjusted. The silicon wafer to which the obtained resin layer is applied is dried on a hot plate at 110° C. for 5 minutes to obtain a resin layer having a uniform thickness of a film thickness of about 15 μm after film formation on the silicon wafer. Here, in a case where only a resin solution having a small viscosity is obtained and a resin layer having a film thickness of 15 μm is difficult to obtain, the film thickness may be appropriately changed. For example, in a case where the film thickness is 5 μm or more, the same value as the imidization rate can be obtained.

The above-described resin layer is measured by an ATR method using Nicolet iS20 (manufactured by Thermo Fisher Scientific, Inc.), and the measurement is performed in a measurement range of 4,000 to 700 cm⁻¹ and 50 times of measurement. A value obtained by dividing a peak height in the vicinity of 1,380 cm⁻¹ (in a case where there are a plurality of peaks, the peak having the maximum peak intensity in a range of 1,350 to 1,450 cm⁻¹) by a peak height in the vicinity of 1,500 cm⁻¹ (in a case where there are a plurality of peaks, the peak having the maximum peak intensity in a range of 1,460 to 1,550 cm⁻¹) is defined as an imidization index A of the resin, an imidization index B is calculated by the same method for a film heated at 350° C. for 1 hour by raising the temperature at a temperature rising rate of 10° C./min in a nitrogen atmosphere, and a value obtained by dividing the imidization index A by the imidization index B is calculated as the imidization rate of the resin.

From the viewpoint of suppressing curing shrinkage, the imidization rate of the specific resin is preferably 45% or more, more preferably 50% or more, and still more preferably 55% or more.

From the viewpoint of suppressing coating unevenness, the imidization rate of the specific resin is preferably 80% or less, more preferably 75% or less, and still more preferably 70% or less.

### [Repeating Unit Represented by Formula (1-2), Formula (1-3), or Formula (1-4)]

The specific resin has at least one repeating unit selected from the group consisting of a repeating unit represented by Formula (1-2), a repeating unit represented by Formula (1-3), and a repeating unit represented by Formula (1-4).

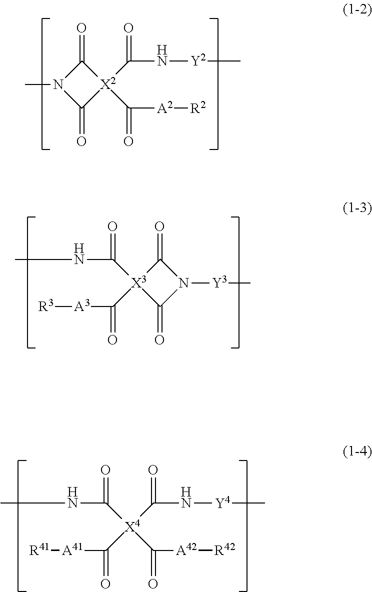

In Formula (1-2), A² is —O— or —NR^{Z}—, R^{Z} is a hydrogen atom or a monovalent organic group, R² is a hydrogen atom or a monovalent organic group, X² is a tetravalent organic group, and Y² is a divalent organic group.

In Formula (1-3), A³ is —O— or —NR^{Z}—, R^{Z} is a hydrogen atom or a monovalent organic group, R³ is a hydrogen atom or a monovalent organic group, X³ is a tetravalent organic group, and Y³ is a divalent organic group.

In Formula (1-4), A⁴¹ and A⁴² are each independently —O— or —NR^{Z}—, R^{Z} is a hydrogen atom or a monovalent organic group, R⁴¹ and R⁴² are each independently a hydrogen atom or a monovalent organic group, X⁴ is a tetravalent organic group, and Y⁴ is a divalent organic group.

### -A²-

A² in Formula (1-2) represents an oxygen atom or —NR^{Z}—, and an oxygen atom is preferable.

R^{Z} represents a hydrogen atom or a monovalent organic group, and a hydrogen atom is preferable.

### —R²—

R² in Formula (1-2) represents a hydrogen atom or a monovalent organic group. The monovalent organic group preferably includes a linear or branched alkyl group, a cyclic alkyl group, an aromatic group, or a polyalkyleneoxy group.

In addition, it is preferable that R² includes a polymerizable group. The polymerizable group is preferably a group capable of undergoing a crosslinking reaction under the action of heat, a radical, or the like, where the group is a radically polymerizable group.

Specific examples of the polymerizable group include a group having an ethylenically unsaturated bond, an alkoxymethyl group, a hydroxymethyl group, an acyloxymethyl group, an epoxy group, an oxetanyl group, a benzoxazolyl group, a blocked isocyanate group, and an amino group. The radically polymerizable group contained in the specific resin is preferably a group having an ethylenically unsaturated bond.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, a (meth)acrylamide group, a (meth)acryloyloxy group, and a group represented by Formula (III), where a group represented by Formula (III) is preferable.

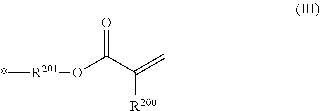

In Formula (III), R²⁰⁰ represents a hydrogen atom, a methyl group, an ethyl group, or a methylol group, where a hydrogen atom or a methyl group is preferable.

In Formula (III), * represents a bonding site to another structure.

In Formula (III), R²⁰¹ represents an alkylene group having 2 to 12 carbon atoms, —CH₂CH(OH)CH₂—, a cycloalkylene group, or a polyalkyleneoxy group.

Suitable examples of R²⁰¹ include an alkylene group such as an ethylene group, a propylene group, a trimethylene group, a tetramethylene group, a pentamethylene group, a hexamethylene group, an octamethylene group, or a dodecamethylene group, a 1,2-butanediyl group, a 1,3-butanediyl group, —CH₂CH(OH)CH₂—, and a polyalkyleneoxy group, where an alkylene group such as an ethylene group or a propylene group, —CH₂CH(OH)CH₂—, a cyclohexyl group, or a polyalkyleneoxy group is more preferable, and an alkylene group such as an ethylene group or a propylene group, or a polyalkyleneoxy group is still more preferable.

In the present invention, the polyalkyleneoxy group refers to a group to which two or more alkyleneoxy groups are directly bonded. The alkylene group in the plurality of alkyleneoxy groups contained in the polyalkyleneoxy group may be the same or different from each other.

In a case where the polyalkyleneoxy group contains a plurality of kinds of alkyleneoxy groups having different alkylene groups, the sequence of the alkyleneoxy groups in the polyalkyleneoxy group may be a randomly arranged sequence, may be a sequence arranged to have a block, or may be a sequence arranged to have an alternating pattern or the like.

The number of carbon atoms of the alkylene group (including the number of carbon atoms of the substituent in a case where the alkylene group has a substituent) is preferably 2 or more, more preferably 2 to 10, still more preferably 2 to 6, even more preferably 2 to 5, even still more preferably 2 to 4, even further still more preferably 2 or 3, and particularly preferably 2.

In addition, the alkylene group may have a substituent. Examples of the preferred substituent include an alkyl group, an aryl group, and a halogen atom.

In addition, the number of alkyleneoxy groups contained in the polyalkyleneoxy group (the number of repetitions of the polyalkyleneoxy group) is preferably 2 to 20, more preferably 2 to 10, and still more preferably 2 to 6.

The polyalkyleneoxy group is preferably a polyethyleneoxy group, a polypropyleneoxy group, a polytrimethyleneoxy group, a polytetramethyleneoxy group, or a group obtained by bonding a plurality of ethyleneoxy groups with a plurality of propyleneoxy groups, more preferably a polyethyleneoxy group or a polypropyleneoxy group, and still more preferably a polyethyleneoxy group, from the viewpoint of solubility in a solvent and solvent resistance. In the group obtained by bonding a plurality of ethyleneoxy groups with a plurality of propyleneoxy groups, the ethyleneoxy groups and the propyleneoxy groups may be randomly arranged, may be arranged by forming a block, or may be arranged in an alternately patterned manner or the like. The preferred aspect of the number of repetitions of the ethyleneoxy group and the like in these groups is as described above.

In Formula (1-2), in a case where R² is a hydrogen atom, the specific resin may form a counter salt with a tertiary amine compound having an ethylenically unsaturated bond.

Examples of the tertiary amine compound having such an ethylenically unsaturated bond include N,N-dimethylaminopropyl methacrylate.

In Formula (1-2), R² may be a polarity converting group such as an acid-decomposable group. The acid-decomposable group is not particularly limited as long as it decomposes by the action of the acid to generate an alkali-soluble group such as a phenolic hydroxy group or a carboxy group; however, it is preferably an acetal group, a ketal group, a silyl group, or a silyl ether group, a tertiary alkyl ester group, or the like, and from the viewpoint of exposure sensitivity, it is more preferably an acetal group or a ketal group.

Specific examples of the acid-decomposable group include a tert-butoxycarbonyl group, an isopropoxycarbonyl group, a tetrahydropyranyl group, a tetrahydrofuranyl group, an ethoxyethyl group, a methoxyethyl group, an ethoxymethyl group, a trimethylsilyl group, a tert-butoxycarbonylmethyl group, and a trimethylsilyl ether group. From the viewpoint of exposure sensitivity, an ethoxyethyl group or a tetrahydrofuranyl group is preferable.

### —X²—

In Formula (1-2), the number of carbon atoms in X² is preferably 4 or more, more preferably 4 to 50, and still more preferably 6 to 40.

In Formula (1-2), X² is preferably any of structures represented by Formulae (2a) to (2g).

A repeating unit represented by Formula (1-2) and in which X² is any of the structures represented by Formulae (2a) to (2g) is also referred to as a repeating unit A-2.

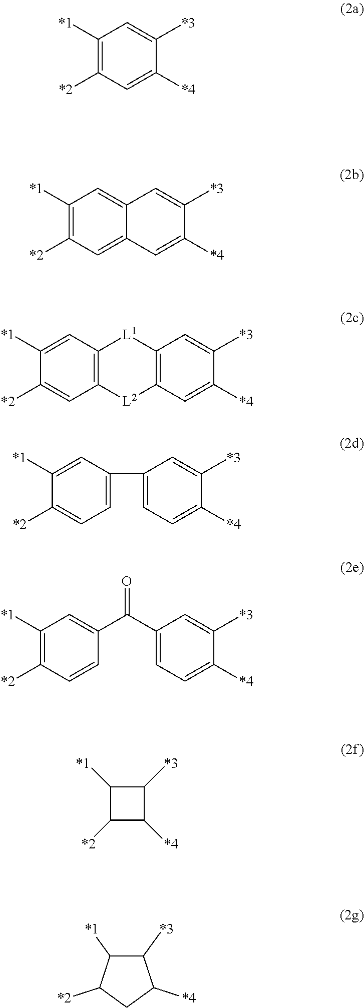

In Formulae (2a) to (2g), L¹ and L² each independently represent a divalent group which is not conjugated to the benzene ring to which each of L¹ and L² is bonded, or a single bond, *1 to *4 each represent a bonding site to the carbonyl group described in Formula (1-2), and hydrogen atoms in these structures may be substituted with substituents.

In Formula (2c), it is preferable that L¹ and L² each independently represent —CH₂— or —O—.

The hydrogen atom in Formulae (2a) to (2g) may be substituted with a substituent, and examples of the substituent include an alkyl group and a halogenated alkyl group. An alkyl group having 1 to 4 carbon atoms or a halogenated alkyl group having 1 to 4 carbon atoms is preferable, and a methyl group or a trifluoromethyl group is more preferable. The halogenated alkyl group refers to a group in which at least one hydrogen atom of an alkyl group is substituted with a halogen atom. As the halogen atom, F or Cl is preferable, and F is more preferable.

In addition, in Formula (1-2), it is also preferable that X² includes a structure obtained by removing two or more hydrogen atoms from a structure represented by any of Formulae (V-1) to (V-10).

By being an organic group including a structure obtained by removing two or more hydrogen atoms from a structure represented by any of Formula (V-1) to Formula (V-10), chemical resistance and flatness of the cured product are improved.

By X² being an organic group including a structure obtained by removing two or more hydrogen atoms from a structure represented by any of Formula (V-1) to Formula (V-5), the chemical resistance and flatness of the cured product are improved.

In addition, by X² being an organic group including a structure obtained by removing two or more hydrogen atoms from a structure represented by any of Formula (V-1) to Formula (V-5), effects such as suppression of generation of development residues, reduction of the dielectric constant of the cured product, and reduction of the coefficient of thermal expansion can also be obtained.

Here, since the organic group is an organic group including a structure obtained by removing two or more hydrogen atoms from a structure represented by any of Formula (V-6) to Formula (V-10), effects such as that the pattern is less likely to be tapered due to improvement in the transmittance of ultraviolet light and that the tolerance to the exposure amount is wide can also be obtained.

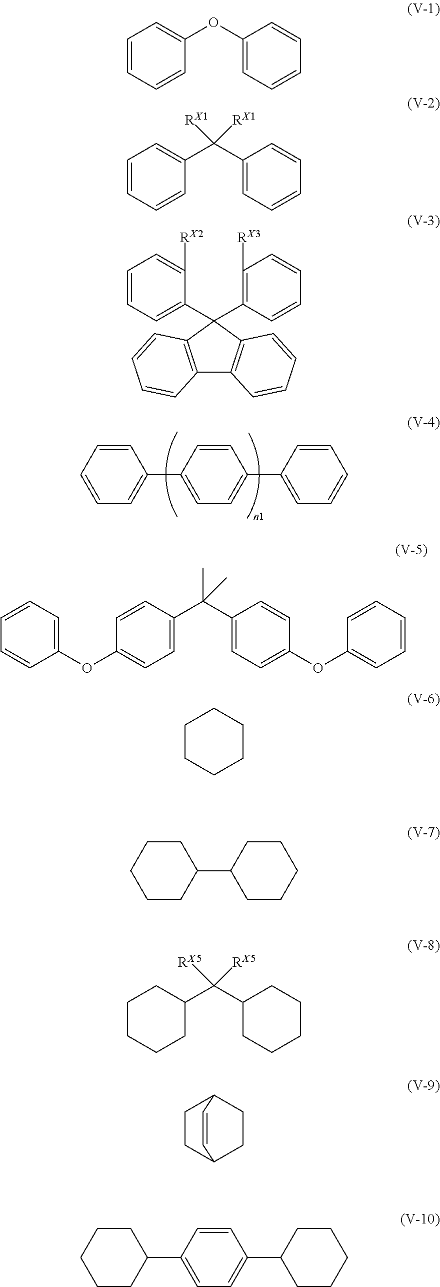

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

In Formula (V-4), n1 represents an integer of 1 or more.

In Formula (V-8), R^{X5}'s each independently represent a hydrogen atom, an alkyl group, or a halogenated alkyl group.

In Formula (V-2), R^{X1}'s are each independently preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogenated alkyl group refers to a group in which at least one hydrogen atom of an alkyl group is substituted with a halogen atom. As the halogen atom, F or Cl is preferable, and F is more preferable.

In Formula (V-3), R^{X2} and R^{X3} are each independently preferably a hydrogen atom.

In a case where R^{X2} and R^{X3} are bonded to each other to form a ring structure, the structure formed by the bonding of R^{X2} and R^{X3} is preferably a single bond, —O—, or —C(R)₂—, more preferably —O— or —C(R)₂—, and still more preferably —O—. R represents a hydrogen atom or a monovalent organic group, preferably a hydrogen atom, an alkyl group, or an aryl group, and more preferably a hydrogen atom.

In Formula (V-4), n1 is preferably an integer of 1 to 5, more preferably an integer of 1 to 3, still more preferably 1 or 2, and particularly preferably 1.

In Formula (V-8), R^{X5}'s are each independently preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogenated alkyl group refers to a group in which at least one hydrogen atom of an alkyl group is substituted with a halogen atom. As the halogen atom, F or Cl is preferable, and F is more preferable.

In a case where X² is a group including a structure obtained by removing two or more hydrogen atoms from a structure represented by Formula (V-1), X² is preferably a group represented by Formula (V-1-1). In the following Formula, * represents a bonding site to four carbonyl groups to which X² in Formula (1-2) is bonded, and n1 represents an integer of 0 to 5, and it is also preferable that n1 is an integer of 1 to 5. In addition, the hydrogen atom in the following structure may be further substituted with a known substituent such as a hydrocarbon group.

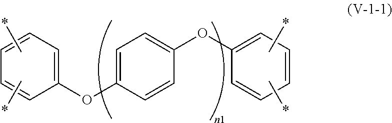

In a case where X² represents a group including a structure in which two or more hydrogen atoms have been removed from the structure represented by Formula (V-2), X² is preferably a group represented by Formula (V-2-1). In the present specification, a bond that intersects with a side of a ring structure means that any hydrogen atom in the ring structure is substituted. In the following Formula, L^{X1} represents a single bond or —O—, and * represents a bonding site to four carbonyl groups to which X² in Formula (1-2) is bonded. In addition, the definition and preferred aspect of R^{X1} are as described above. In addition, the hydrogen atom in these structures may be further substituted with a known substituent such as a hydrocarbon group.

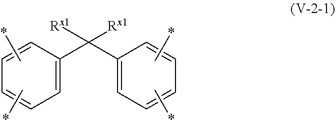

In a case where X² is a group including a structure obtained by removing two or more hydrogen atoms from a structure represented by Formula (V-3), X² is preferably a group represented by Formula (V-3-1) or Formula (V-3-2), and from the viewpoint of reducing the dielectric constant of the cured product or the like, X² is more preferably a group represented by Formula (V-3-2). In the formulae, * represents a bonding site to the four carbonyl groups to which X² in Formula (1-2) is bonded. In addition, the definitions and preferred aspects of R^{X2} and R^{X3} are as described above. In addition, the hydrogen atom in these structures may be further substituted with a known substituent such as a hydrocarbon group.

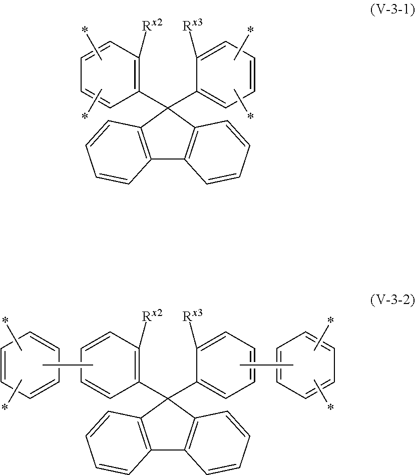

In a case where X² is a group including a structure obtained by removing two or more hydrogen atoms from a structure represented by Formula (V-4), X² is preferably a group represented by Formula (V-4-1).

In Formula (V-4-1), * represents a bonding site to the four carbonyl groups to which X² in Formula (1-2) is bonded, and n1 represents an integer of 1 to 5. In addition, the hydrogen atom in Formula (V-4-1) may be further substituted with a known substituent such as a hydrocarbon group. Examples of the known substituent include an alkyl group, a halogenated alkyl group, and a halogen atom. However, it is also preferable that none of the hydrogen atoms in the structure represented by (V-4-1) are substituted.

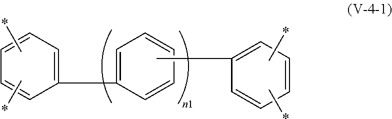

In a case where X² is a group including a structure obtained by removing two or more hydrogen atoms from a structure represented by Formula (V-5), X² is preferably a group represented by Formula (V-5-1). In the formulae, * represents a bonding site to the four carbonyl groups to which X² in Formula (1-2) is bonded. In addition, the hydrogen atom in Formula (V-5-1) may be further substituted with a known substituent such as a hydrocarbon group. Examples of the known substituent include an alkyl group, a halogenated alkyl group, and a halogen atom. However, it is also preferable that none of the hydrogen atoms in the structure represented by (V-5-1) are substituted.

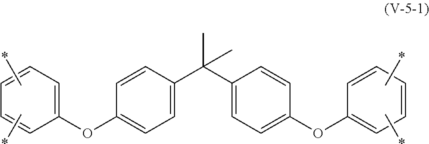

In a case where X² is a group including a structure obtained by removing two or more hydrogen atoms from a structure represented by Formula (V-6), X² is preferably a group represented by Formula (V-6-1). In the formulae, * represents a bonding site to the four carbonyl groups to which X² in Formula (1-2) is bonded. In addition, the hydrogen atom in the following structure may be further substituted with a known substituent such as a hydrocarbon group.

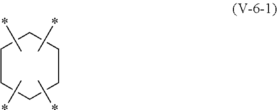

In a case where X² is a group including a structure obtained by removing two or more hydrogen atoms from a structure represented by Formula (V-7), X² is preferably a group represented by Formula (V-7-1). In the formulae, * represents a bonding site to the four carbonyl groups to which X² in Formula (1-2) is bonded. In addition, the hydrogen atom in the following structure may be further substituted with a known substituent such as a hydrocarbon group.

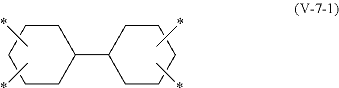

In a case where X² is a group including a structure obtained by removing two or more hydrogen atoms from a structure represented by Formula (V-8), X² is preferably a group represented by Formula (V-8-1). In the formulae, * represents a bonding site to the four carbonyl groups to which X² in Formula (1-2) is bonded. The definition and preferred aspects of R^{X5} are as described above. In addition, the hydrogen atom in the following structure may be further substituted with a known substituent such as a hydrocarbon group.

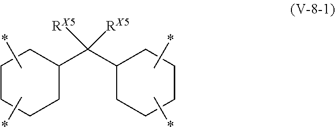

In a case where X² is a group including a structure obtained by removing two or more hydrogen atoms from a structure represented by Formula (V-9), X² is preferably a group represented by Formula (V-9-1). In the formulae, * represents a bonding site to the four carbonyl groups to which X² in Formula (1-2) is bonded. In addition, the hydrogen atom in the following structure may be further substituted with a known substituent such as a hydrocarbon group.

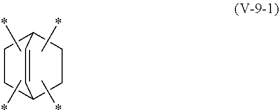

In a case where X² is a group including a structure obtained by removing two or more hydrogen atoms from a structure represented by Formula (V-10), X² is preferably a group represented by Formula (V-10-1). In the formulae, * represents a bonding site to the four carbonyl groups to which X² in Formula (1-2) is bonded. In addition, the hydrogen atom in the following structure may be further substituted with a known substituent such as a hydrocarbon group.

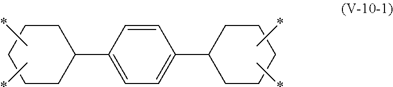

In addition, X² may be a tetracarboxylic acid residue remaining after the removal of the anhydride group from the tetracarboxylic acid dianhydride described in paragraphs 0055 to 0057 of JP2023-003421A.

In addition, it is preferable that X² does not include an imide bond in the structure.

In addition, it is preferable that X² does not contain a urethane bond, a urea bond, and an amide bond in the structure.

In the present invention, the urethane bond is a bond represented by *—O—C(═O)—NR^{N}—*, where R^{N} represents a hydrogen atom or a monovalent organic group, and *'s each represent a bonding site to a carbon atom. R^{N} is preferably a hydrogen atom or a hydrocarbon group, more preferably a hydrogen atom or an alkyl group, and still more preferably a hydrogen atom.

In the present invention, the urea bond is a bond represented by *—NR^{N}—C(═O)—NR^{N}—* where R^{N}'s each independently represent a hydrogen atom or a monovalent organic group, and *'s each represent a bonding site to a carbon atom. The preferred aspect of R^{N} is as described above.

Furthermore, it is preferable that X² does not contain an ester bond in the structure.

In the present invention, the ester bond is a bond represented by *—O—C(═O)—*.

Among these, it is preferable that X² does not contain an imide bond, a urethane bond, a urea bond, and an amide bond, and it is preferable that X² does not contain an imide bond, a urethane bond, a urea bond, an amide bond, and an ester bond.

### —Y²—

In Formula (2), the number of carbon atoms in Y² is preferably 4 or more, more preferably 4 to 50, and still more preferably 6 to 40.

In Formula (2), Y² is preferably a structure including a structure represented by Formulae (C-1) to (C-5).

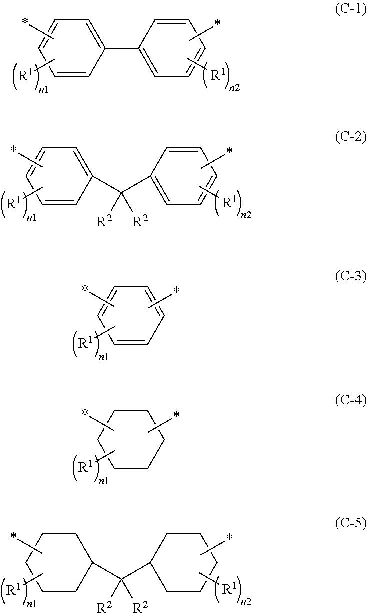

In Formula (C-1), R¹'s each independently represent a hydrogen atom or a monovalent organic group, n1 represents an integer of 0 to 3, n2 represents an integer of 0 to 3, and * represents a bonding site to another structure.

In Formula (C-2), R¹'s each independently represent a hydrogen atom or a monovalent organic group, n1 represents an integer of 0 to 3, n2 represents an integer of 0 to 3, R²'s each independently represent an alkyl group or a fluoroalkyl group, and * represents a bonding site to another structure.

In Formula (C-3), R¹'s each independently represent a hydrogen atom or a monovalent organic group, n1 represents an integer of 0 to 3, and * represents a bonding site to another structure.

In Formula (C-4), R¹'s each independently represent a hydrogen atom or a monovalent organic group, n1 represents an integer of 0 to 3, and * represents a bonding site to another structure.

In Formula (C-5), R¹'s each independently represent a hydrogen atom or a monovalent organic group, n1 represents an integer of 0 to 3, n2 represents an integer of 0 to 3, R²'s each independently represent an alkyl group or a fluoroalkyl group, and * represents a bonding site to another structure.

In Formula (C-1), R¹'s each independently represent preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogen atom in the halogenated alkyl group is preferably F or Cl and more preferably F.

In Formula (C-1), n1 is preferably 0 or 1 and more preferably 1.

In Formula (C-1), n2 is preferably 0 or 1 and more preferably 1.

In Formula (C-2), preferred aspects of R¹, n1, and n2 are the same as the preferred aspects of R¹, n1, and n2 in Formula (C-1), respectively.

In Formula (C-2), R² is preferably an alkyl group having 1 to 4 carbon atoms or a halogenated alkyl group having 1 to 4 carbon atoms, and more preferably a methyl group or a trifluoromethyl group.

In Formula (C-3), preferred aspects of R¹ and n1 are the same as the preferred aspects of R¹ and n1 in Formula (C-1), respectively.

In Formula (C-4), preferred aspects of R¹ and n1 are the same as the preferred aspects of R¹ and n1 in Formula (C-1), respectively.

In Formula (C-5), preferred aspects of R¹, R², n1, and n2 are the same as the preferred aspects of R¹, R², n1, and n2 in Formula (C-2), respectively.

In Formulae (C-1) to (C-5), it is preferable that *'s are all bonding sites to a nitrogen atom.

In addition, Y² may be a group described in paragraphs 0042 to 0053 of JP2023-003421A.

In addition, it is preferable that Y² does not include an imide bond in the structure.

In addition, it is preferable that Y² does not include a urethane bond, a urea bond, and an amide bond in the structure.

Further, it is preferable that Y² does not include an ester bond in the structure.

Among these, it is preferable that Y² does not contain an imide bond, a urethane bond, a urea bond, and an amide bond, and it is more preferable that Y² does not contain an imide bond, a urethane bond, a urea bond, an amide bond, and an ester bond.

-A³, R³, X³, Y³—

Preferred aspects of A³, R³, X³, and Y³ in Formula (1-3) are the same as the preferred aspects of A², R², X², and Y² in Formula (1-2). Here, the description of “Formula (1-2)” in the description of A², R², X², and Y² shall be read as “Formula (1-3)”.

-A⁴¹, A⁴², R⁴¹, R⁴², X⁴, Y⁴—

Preferred aspects of A⁴¹ and A⁴² in Formula (1-4) are the same as the preferred aspects of A² in Formula (1-2), respectively.

Preferred aspects of R⁴¹ and R⁴² in Formula (1-4) are the same as the preferred aspects of R² in Formula (1-2), respectively. Here, the description of “Formula (1-2)” in the description of R² shall be read as “Formula (1-4)”.

Preferred aspects of X⁴ and Y⁴ in Formula (1-4) are the same as the preferred aspects of X and Y² in Formula (1-2). Here, the description of “Formula (1-2)” in the description of X² and Y² shall be read as “Formula (1-4)”.

The specific resin preferably includes at least one repeating unit selected from the group consisting of the following repeating unit A-2, repeating unit A-3, and repeating unit A-4.

Repeating unit A-2: repeating unit represented by Formula (1-2), in which X² is any of structures represented by Formulae (2a) to (2g)

Repeating unit A-3: repeating unit represented by Formula (1-3), in which X³ is any of structures represented by Formulae (2a) to (2g)

Repeating unit A-4: repeating unit represented by Formula (1-4), in which X⁴ is any of structures represented by Formulae (2a) to (2g)

The specific resin preferably includes at least one repeating unit selected from the group consisting of the following repeating unit B-2, repeating unit B-3, and repeating unit B-4.

In particular, the specific resin preferably includes at least one repeating unit selected from the group consisting of the repeating unit A-2, the repeating unit A-3, and the repeating unit A-4, and at least one repeating unit selected from the group consisting of the following repeating unit B-2, repeating unit B-3, and repeating unit B-4.

Repeating unit B-2: repeating unit represented by Formula (1-2), in which X² includes a structure obtained by removing two or more hydrogen atoms from a structure represented by any of Formulae (V-1) to (V-10)

Repeating unit B-3: repeating unit represented by Formula (1-3), in which X³ includes a structure obtained by removing two or more hydrogen atoms from a structure represented by any of Formulae (V-1) to (V-10)

Repeating unit B-4: repeating unit represented by Formula (1-4), in which X⁴ includes a structure obtained by removing two or more hydrogen atoms from a structure represented by any of Formulae (V-1) to (V-10)

The specific resin preferably includes at least one repeating unit selected from the group consisting of a repeating unit represented by Formula (1-2), in which R² is a monovalent organic group having an ethylenically unsaturated bond, a repeating unit represented by Formula (1-3), in which R³ is a monovalent organic group having an ethylenically unsaturated bond, and a repeating unit represented by Formula (1-4), in which at least one of R⁴¹ or R⁴² is a monovalent organic group having an ethylenically unsaturated bond.

The specific resin preferably includes at least one repeating unit selected from the group consisting of a repeating unit represented by Formula (1-2), in which Y² is a structure including a structure represented by Formulae (C-1) to (C-5), a repeating unit represented by Formula (1-3), in which Y³ is a structure including a structure represented by Formulae (C-1) to (C-5), and a repeating unit represented by Formula (1-4), in which Y⁴ is a structure including a structure represented by Formulae (C-1) to (C-5).

Here, the repeating unit in which Y² is a structure including a structure represented by Formulae (C-1) to (C-5) is preferably a repeating unit corresponding to the above-described repeating unit A-2 or repeating unit B-2.

Here, the repeating unit in which Y³ is a structure including a structure represented by Formulae (C-1) to (C-5) is preferably a repeating unit corresponding to the above-described repeating unit A-3 or repeating unit B-3.

Here, the repeating unit in which Y⁴ is a structure including a structure represented by Formulae (C-1) to (C-5) is preferably a repeating unit corresponding to the above-described repeating unit A-4 or repeating unit B-4.

The specific resin preferably includes a repeating unit represented by Formula (1-1).

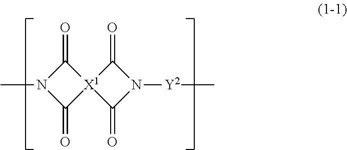

X¹ is a tetravalent organic group, and Y¹ is a divalent organic group.

In Formula (1-1), preferred aspects of X¹ and Y¹ are the same as the preferred aspects of X² and Y² in Formula (1-2). Here, the description of “Formula (1-2)” in the description of X² and Y² shall be read as “Formula (1-1)”.

In addition, the specific resin preferably includes the following repeating unit A-1.

Repeating unit A-1: a repeating unit represented by Formula (1-1), in which X¹ is any of structures represented by Formulae (2a) to (2g)

In addition, the specific resin preferably includes the following repeating unit B-1.

In particular, the specific resin preferably includes the repeating unit A-1 and the following repeating unit B-1.

Repeating unit B-1: a repeating unit represented by Formula (1-1), in which X¹ includes a structure obtained by removing two or more hydrogen atoms from a structure represented by any of Formulae (V-1) to (V-10)

Examples of one embodiment of the specific resin in the present invention include an aspect in which a total content of the repeating units represented by Formula (1-1), Formula (1-2), Formula (1-3), or Formula (1-4) is 50% by mole or more with respect to all repeating units.

The above-described total content is more preferably 70% by mole or more, still more preferably 90% by mole or more, and particularly preferably more than 90% by mole. The upper limit of the total content is not particularly limited, and all repeating units in the specific resin excluding the terminal may be repeating units represented by Formula (1-1), Formula (1-2), Formula (1-3), or Formula (1-4).

In addition, examples of another embodiment of the specific resin in the present invention include an aspect in which a total content of the repeating units represented by Formula (1-1) or Formula (1-4) is 50% by mole or more with respect to all repeating units. The above-described total content is more preferably 70% by mole or more, still more preferably 90% by mole or more, and particularly preferably more than 90% by mole. The upper limit of the total content is not particularly limited, and all repeating units in the specific resin excluding the terminal may be repeating units represented by Formula (1-1) or Formula (1-4).

In addition, in the specific resin in the present invention, it is preferable that a total content of repeating units (also referred to as “repeating unit A”) corresponding to the repeating unit A-1, the repeating unit A-2, the repeating unit A-3, or the repeating unit A-4 is 20% by mole or more with respect to all repeating units. The total content is more preferably 30% by mole or more, still more preferably 40% by mole or more, and particularly preferably 50% by mole or more. The upper limit of the total content is not particularly limited, and all repeating units in the specific resin excluding the terminal may be the repeating unit A.

In addition, in the specific resin in the present invention, it is preferable that a total content of repeating units (also referred to as “repeating unit B”) corresponding to the repeating unit B-1, the repeating unit B-2, the repeating unit B-3, or the repeating unit B-4 is 0% by mole to 80% by mole with respect to all repeating units. The total content is more preferably 5% to 70% by mole, still more preferably 10% to 60% by mole, and particularly preferably 15% to 50% by mole.

In addition, in the specific resin in the present invention, it is preferable that a total content of the repeating unit A and the repeating unit B is 50% by mole or more with respect to all repeating units. The above-described total content is more preferably 70% by mole or more, still more preferably 90% by mole or more, and particularly preferably more than 90% by mole.

The upper limit of the total content is not particularly limited, and all repeating units in the specific resin excluding the terminal may be the repeating unit A or the repeating unit B.

A weight-average molecular weight (Mw) of the specific resin is preferably 120,000 or less, more preferably 50,000 or less, and still more preferably 40,000 or less.

In addition, the Mw is preferably 5,000 or more, more preferably 10,000 or more, and still more preferably 15,000 or more.

A number-average molecular weight (Mn) of the specific resin is preferably 40,000 or less, more preferably 30,000 or less, and still more preferably 20,000 or less.

In addition, the Mn is preferably 2,000 or more, more preferably 3,000 or more, and still more preferably 4,000 or more.

A dispersity of a molecular weight of the specific resin is preferably 1.5 or more, more preferably 1.8 or more, and still more preferably 2.0 or more. An upper limit value of the dispersity of the molecular weight of the specific resin is not particularly limited, but is, for example, preferably 7.0 or less, more preferably 6.5 or less, and still more preferably 6.0 or less.

In the present specification, the dispersity of the molecular weight is a value obtained by calculating “weight-average molecular weight/number-average molecular weight”.

In a case where the resin composition contains a plurality of kinds of specific resins as the specific resin, it is preferable that the weight-average molecular weight, the number-average molecular weight, and the dispersity of at least one kind of specific resin are in the above ranges. It is also preferable that the weight-average molecular weight, the number-average molecular weight, and the dispersity, calculated by using the plurality of kinds of specific resins as one resin, are within the above ranges.

### [Method for Producing Specific Resin]

The specific resin is synthesized, for example, by the methods described in the following (1) to (3).
(1) Method of producing polyimide precursor in the related art using polyimide oligomer having amino group at terminal as diamine component
(2) Method of imidizing polyimide precursor produced by method in the related art such that imidization rate is 40% to 85% by thermal imidization, chemical imidization, or the like
(3) Method of synthesizing polyamic acid, esterifying a part of carboxylic acid, and imidizing non-esterified carboxylic acid moiety by thermal imidization, chemical imidization, or the like

The above-described (1) preferably includes a step of synthesizing a polyimide oligomer having an amino group at a terminal, and
a step of reacting the polyimide oligomer with a compound represented by Formula (A-1).

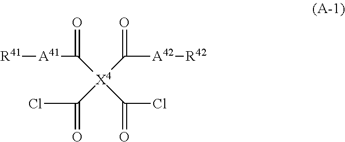

In Formula (A-1), A⁴¹ and A⁴² are each independently —O— or —NR^{Z}—, where R^{Z} is a hydrogen atom or a monovalent organic group, R⁴¹ and R⁴² are each independently a hydrogen atom or a monovalent organic group, and X⁴ is a tetravalent organic group.

The step of synthesizing a polyimide oligomer having an amino group at a terminal is not particularly limited, and a known method can be used.

Examples thereof include a method of reacting a tetracarboxylic acid dianhydride with a diamine at a low temperature, a method of reacting a tetracarboxylic acid dianhydride with a diamine at a low temperature to obtain a polyamic acid, and then esterifying the polyamic acid using a condensing agent or an alkylating agent, a method of obtaining a diester from a tetracarboxylic acid dianhydride and an alcohol, and then reacting the diester with a diamine in the presence of a condensing agent, a method of obtaining a diester from a tetracarboxylic acid dianhydride and an alcohol, and then converting the remaining dicarboxylic acid to an acid halide using a halogenating agent, and then reacting the diester with a diamine, and a method of obtaining a polyimide precursor using these methods, and imidizing the polyimide precursor by a known thermal imidization or chemical imidization method to synthesize a polyimide oligomer.

In addition, the polyimide oligomer may be produced by a one-step method from a tetracarboxylic acid dianhydride and a diisocyanate.

Examples of the method of having an amino group at a terminal include a method of using an excess amount of a diamine used in the synthesis, and a method of using a compound having an amino group as a terminal blocking agent.

Examples of the polyimide oligomer include a resin having the repeating unit represented by Formula (1-1) described above and having an amino group at a terminal.

As the reaction conditions in the step of reacting the polyimide oligomer with the compound represented by Formula (A-1), the conditions of a known amidation method using an acid halide and an amine can be adopted.

In Formula (A-1), preferred aspects of A⁴¹, A⁴², R⁴¹, R⁴², and X⁴ are the same as the preferred aspects of A⁴¹, A⁴², R⁴¹, R⁴², and X⁴ in Formula (1-4) described above.

The compound represented by Formula (A-1) is obtained, for example, by obtaining a diester from a tetracarboxylic acid dianhydride and an alcohol, and then converting the remaining dicarboxylic acid to an acid halide using a halogenating agent.

Examples of the halogenating agent include thionyl chloride, oxalyl chloride, and phosphorus oxychloride.

As the method of producing the polyimide precursor in (2) described above, for example, the method described in paragraphs 0049 to 0051 of WO2023/162905A can be referred to.

For the thermal imidization and chemical imidization methods, a known method may be referred to.

As the method of synthesizing the polyamic acid and the method of esterifying a part of the carboxylic acid in (3) described above, for example, the method described in paragraphs 0049 to 0051 of WO2023/162905A can be referred to.

For the thermal imidization and chemical imidization methods, a known method may be referred to.

Here, since the non-esterified portion is more easily imidized than the esterified portion, the imidization rate of the specific resin obtained by adjusting the amount of esterification can be adjusted.

### [Content]

The content of the specific resin in the resin composition according to the embodiment of the present invention is preferably 20% by mass or more, more preferably 30% by mass or more, still more preferably 40% by mass or more, and even still more preferably 50% by mass or more, with respect to the total solid content of the resin composition. In addition, the content of the resin in the resin composition according to the embodiment of the present invention is preferably 99.5% by mass or less, more preferably 99% by mass or less, still more preferably 98% by mass or less, still more preferably 97% by mass or less, and even still more preferably 95% by mass or less, with respect to the total solid content of the resin composition.

The resin composition according to the embodiment of the present invention may contain only one kind of specific resin or may contain two or more kinds thereof. In a case where two or more kinds thereof are included, the total amount thereof is preferably within the above-described range.

### <Another Resin>

The resin composition according to the embodiment of the present invention may contain the above-described specific resin and another resin (hereinafter, also simply referred to as “the other resin”) that is different from the specific resin.

Examples of the other resin include a phenol resin, polyamide, an epoxy resin, polysiloxane, a resin containing a siloxane structure, a (meth)acrylic resin, a (meth)acrylamide resin, a urethane resin, a butyral resin, a styryl resin, a polyether resin, and a polyester resin.

For example, in a case where a (meth)acrylic resin is further added, it is possible to obtain a resin composition having excellent coatability, and it is possible to obtain a pattern (a cured product) having excellent solvent resistance.

For example, in a case where a (meth)acrylic resin having a high content of polymerizable groups and having a weight-average molecular weight of 20,000 or less (for example, a molar amount of a polymerizable group contained in 1 g of a resin is 1×10⁻³ mol/g or more) is added to the resin composition instead of a polymerizable compound described later or in addition to a polymerizable compound described later, it is possible to improve the coatability of the resin composition, the solvent resistance of the pattern (the cured product).

In a case where the resin composition according to the embodiment of the present invention contains the other resin, the content of the other resin is preferably 0.01% by mass or more, more preferably 0.05% by mass or more, still more preferably 1% by mass or more, even still more preferably 2% by mass or more, even still more preferably 5% by mass or more, and even further still more preferably 10% by mass or more, with respect to the total solid content of the resin composition.

In a case where the resin composition according to the embodiment of the present invention contains the other resin, the content of the other resin is preferably 80% by mass or less, more preferably 75% by mass or less, still more preferably 70% by mass or less, even still more preferably 60% by mass or less, and even further still more preferably 50% by mass or less, with respect to the total solid content of the resin composition.

As one preferred aspect of the resin composition according to the embodiment of the present invention, an aspect in which the content of the other resin is a low content can be adopted. In the above aspect, the content of the other resin is preferably 20% by mass or less, more preferably 15% by mass or less, still more preferably 10% by mass or less, still more preferably 5% by mass or less, and even still more preferably 1% by mass or less, with respect to the total solid content of the resin composition. The lower limit of the content is not particularly limited, and it may be any content of 0% by mass or more.

The resin composition according to the embodiment of the present invention may contain only one kind of the other resin or may contain two or more kinds thereof. In a case where two or more kinds thereof are included, the total amount thereof is preferably within the above-described range.

### <Polymerizable Compound>

The resin composition according to the embodiment of the present invention preferably does not contain a polymerizable compound, or contains a polymerizable compound in an amount of 15 parts by mass or less with respect to 100 parts by mass of the specific resin, more preferably does not contain a polymerizable compound, or contains a polymerizable compound in an amount of 10 parts by mass or less with respect to 100 parts by mass of the specific resin, and still more preferably does not contain a polymerizable compound, or contains a polymerizable compound in an amount of 5 parts by mass or less with respect to 100 parts by mass of the specific resin.

In addition, from the viewpoint of resolution, it is also preferable to contain a polymerizable compound in an amount of 1 part by mass or more with respect to 100 parts by mass of the specific resin. In the above-described aspect, the above-described content is preferably 2 parts by mass or more, and more preferably 3 parts by mass or more. In addition, in the above-described aspect, the above-described content is preferably 10 parts by mass or less, and more preferably 5 parts by mass or less.

Examples of the polymerizable compound include a polymerizable compound having a radically polymerizable group (radical crosslinking agent), or other crosslinking agents.

### [Radical Crosslinking Agent]

The resin composition according to the embodiment of the present invention preferably contains a radical crosslinking agent.

The radical crosslinking agent is a compound having a radically polymerizable group.

The radically polymerizable group is preferably a group containing an ethylenically unsaturated bond. Examples of the group containing an ethylenically unsaturated bond include a vinyl group, an allyl group, a vinylphenyl group, a (meth)acryloyl group, a maleimide group, and a (meth)acrylamide group.

Among these, a (meth)acryloyl group, a (meth)acrylamide group, or a vinylphenyl group is preferable, and from the viewpoint of reactivity, a (meth)acryloyl group is more preferable.

In particular, the resin composition according to the embodiment of the present invention preferably contains a compound having a (meth)acryloyl group as the polymerizable compound.

The radical crosslinking agent is preferably a compound having one or more ethylenically unsaturated bonds; however, a compound having two or more ethylenically unsaturated bonds is more preferable. The radical crosslinking agent may have three or more ethylenically unsaturated bonds.

The compound having 2 or more ethylenically unsaturated bonds is preferably a compound having 2 to 15 ethylenically unsaturated bonds, more preferably a compound having 2 to 10 ethylenically unsaturated bonds, and still more preferably a compound having 2 to 6 ethylenically unsaturated bonds.

From the viewpoint of the film hardness of the pattern (cured product) to be obtained, the resin composition according to the embodiment of the present invention preferably contains a compound having two ethylenically unsaturated bonds and a compound having three or more ethylenically unsaturated bonds.

The molecular weight of the radical crosslinking agent is preferably 2,000 or less, more preferably 1,500 or less, and still more preferably 900 or less. The lower limit of the molecular weight of the radical crosslinking agent is preferably 100 or more.

Specific examples of the radical crosslinking agent include unsaturated carboxylic acids (for example, acrylic acid, methacrylic acid, itaconic acid, crotonic acid, isocrotonic acid, and maleic acid), and esters and amides thereof, where esters between unsaturated carboxylic acids and polyhydric alcohol compounds and amides between unsaturated carboxylic acids and polyvalent amine compounds are preferable. In addition, addition reaction products produced by reacting unsaturated carboxylic acid esters or amides, having a nucleophilic substituent such as a hydroxy group, an amino group, or a sulfanyl group, with monofunctional or polyfunctional isocyanates or epoxies, dehydration condensation reaction products produced by reacting the above esters or amides with a monofunctional or polyfunctional carboxylic acid, or the like are also suitably used. In addition, an addition reaction product produced by reacting unsaturated carboxylic acid esters or amides, having an electrophilic substituent such as an isocyanate group or an epoxy group, with monofunctional or polyfunctional alcohols, amines, or thiols, and further, a substitution reaction product produced by reacting unsaturated carboxylic acid esters or amides, having an eliminable substituent such as a halogeno group or a tosyloxy group, with monofunctional or polyfunctional alcohols, amines, or thiols is also suitable. In addition, as other examples, it is also possible to use a group of compounds in which the unsaturated carboxylic acid described above is replaced with an unsaturated phosphonic acid, a vinylbenzene derivative such as styrene, a vinyl ether, an allyl ether, or the like. Regarding the specific examples thereof, reference can be made to the description of paragraphs 0113 to 0122 of JP2016-027357A, the content of which is incorporated in the present specification.

The radical crosslinking agent is also preferably a compound having a boiling point of 100° C. or higher under normal pressure. Examples of the compound having a boiling point of 100° C. or higher under normal pressure include the compounds described in paragraph 0203 of WO2021/112189A. The contents thereof are incorporated into the present specification.

Examples of the preferred radical crosslinking agent other than those described above include the radically polymerizable compounds described in paragraphs 0204 to 0208 of WO2021/112189A. The contents thereof are incorporated into the present specification.

As the radical crosslinking agent, dipentaerythritol triacrylate (as a commercially available product, KAYARAD D-330 (manufactured by Nippon Kayaku Co., Ltd.)), dipentaerythritol tetraacrylate (as a commercially available product, KAYARAD D-320 (manufactured by Nippon Kayaku Co., Ltd.)), A-TMMT (manufactured by Shin-Nakamura Chemical Co., Ltd.), dipentaerythritol penta(meth)acrylate (as a commercially available product, KAYARAD D-310 (manufactured by Nippon Kayaku Co., Ltd.)), dipentaerythritol hexa(meth)acrylate (as a commercially available product, KAYARAD DPHA (manufactured by Nippon Kayaku Co., Ltd.)), A-DPH (manufactured by Shin-Nakamura Chemical Co., Ltd.), and a structure in which a (meth)acryloyl group thereof is bonded through an ethylene glycol residue or a propylene glycol residue is preferable. These compounds in oligomer types can also be used.

Examples of the commercially available products of the radical crosslinking agent include SR-494 which is a tetrafunctional acrylate having four ethyleneoxy chains, SR-209, SR-231, and SR-239 which are difunctional methacrylates having four ethyleneoxy chains (all of which are manufactured by Sartomer Company Inc.), DPCA-60 which is a hexafunctional acrylate having six pentyleneoxy chains and TPA-330 which is a trifunctional acrylate having three isobutyleneoxy chains (all of which are manufactured by Nippon Kayaku Co., Ltd.), UAS-10 and UAB-140 which are a urethane oligomer (all of which are manufactured by Nippon Paper Industries Co., Ltd.), NK Ester M-40G, NK Ester 4G, NK Ester M-9300, NK Ester A-9300, and UA-7200 (all of which are manufactured by Shin-Nakamura Chemical Co., Ltd.), DPHA-40H (manufactured by Nippon Kayaku Co., Ltd.), UA-306H, UA-306T, UA-306I, AH-600, T-600, and AI-600 (all of which are manufactured by KYOEISHA CHEMICAL Co., Ltd.), and Brenmer PME400 (manufactured by NOF Corporation).

As the radical crosslinking agent, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. As the radical crosslinking agent, the compounds having an amino structure or a sulfide structure in the molecule as described in JP1988-277653A (JP-S63-277653A), JP1988-260909A (JP-S63-260909A), and JP1989-105238A (JP-HO1-105238A) can also be used.

The radical crosslinking agent may be a radical crosslinking agent having an acid group such as a carboxy group or a phosphate group. The radical crosslinking agent having an acid group is preferably an ester between an aliphatic polyhydroxy compound and an unsaturated carboxylic acid and more preferably a radical crosslinking agent obtained by reacting an unreacted hydroxy group of an aliphatic polyhydroxy compound with a non-aromatic carboxylic acid anhydride to have an acid group. The radical crosslinking agent is particularly preferably a compound in which an aliphatic polyhydroxy compound is pentaerythritol or dipentaerythritol in a radical crosslinking agent having an acid group obtained by reacting an unreacted hydroxy group of the aliphatic polyhydroxy compound with a non-aromatic carboxylic acid anhydride.

Examples of the commercially available products thereof include M-510 and M-520 as polybasic acid-modified acrylic oligomers which are manufactured by Toagosei Co., Ltd.

An acid value of the radical crosslinking agent having an acid group is preferably 0.1 to 300 mgKOH/g and more preferably 1 to 100 mgKOH/g. In a case where the acid value of the radical crosslinking agent is within the above-described range, excellent manufacturing handleability is exhibited, and excellent developability is exhibited. In addition, good polymerization properties are exhibited. The acid value is measured according to the description of JIS K 0070: 1992.

The radical crosslinking agent is also preferably a radical crosslinking agent having at least one selected from the group consisting of a urea bond and a urethane bond (hereinafter, also referred to as a “crosslinking agent U”).

In the present invention, the urea bond is a bond represented by *—NR^{N}—C(═O)—NR^{N}*, where R^{N}'s each independently represent a hydrogen atom or a monovalent organic group, and s each represent a bonding site to a carbon atom.

In the present invention, the urethane bond is a bond represented by *—O—C(═O)—NR^{N}—*, where R^{N} represents a hydrogen atom or a monovalent organic group, and *'s each represent a bonding site to a carbon atom.

In a case where the resin composition contains a crosslinking agent U, chemical resistance, resolution, and the like may be improved.

The mechanism by which the above-described effect is obtained is not revealed; however, it is considered that, for example, a part of the crosslinking agent U undergoes thermal decomposition during curing by heating or the like to generate an amine or the like, and the amine or the like accelerates the cyclization of the precursor of the cyclization resin such as the polyimide precursor.

The crosslinking agent U may have only one urea bond or urethane bond, may have one or more urea bonds and one or more urethane bonds, may have two or more urea bonds without having a urethane bond, or may have two or more urethane bonds without having a urea bond.

The total number of urea bonds and urethane bonds in the crosslinking agent U is 1 or more, and it is preferably 1 to 10, more preferably 1 to 4, and still more preferably 1 or 2.

In a case where the crosslinking agent U does not have a urethane bond, the number of urea bonds in the crosslinking agent U is 1 or more, and it is preferably 1 to 10, more preferably 1 to 4, and still more preferably 1 or 2.

In a case where the crosslinking agent U does not have a urea bond, the number of urethane bonds in the crosslinking agent U is 1 or more, and it is preferably 1 to 10, more preferably 1 to 4, and still more preferably 1 or 2.

The radically polymerizable group in the crosslinking agent U is not particularly limited; however, examples thereof include a vinyl group, an allyl group, a (meth)acryloyl group, a (meth)acryloxy group, a (meth)acrylamide group, a vinylphenyl group, and a maleimide group, where a (meth)acryloxy group, a (meth)acrylamide group, a vinylphenyl group, or a maleimide group is preferable, and a (meth)acryloxy group is more preferable.

In a case where the crosslinking agent U has two or more radically polymerizable groups, the structures of the respective radically polymerizable groups may be the same or different from each other.

The number of radically polymerizable groups in the crosslinking agent U may be only one or may be two or more, and it is preferably 1 to 10, more preferably 1 to 6, and particularly preferably 1 to 4.

The radically polymerizable group value (the mass of the compound per 1 mol of the radically polymerizable group) in the crosslinking agent U is preferably 150 to 400 g/mol.

From the viewpoint of the chemical resistance of the cured product, the lower limit of the above-described radically polymerizable group value is more preferably 200 g/mol or more, still more preferably 210 g/mol or more, even more preferably 220 g/mol or more, even still more preferably 230 g/mol or more, even still more preferably 240 g/mol or more, and particularly preferably 250 g/mol or more.

From the viewpoint of developability, the upper limit of the above-described radically polymerizable group value is more preferably 350 g/mol or less, still more preferably 330 g/mol or less, and particularly preferably 300 g/mol or less.

Among the above, the polymerizable group value of the crosslinking agent U is preferably 210 to 400 g/mol and more preferably 220 to 400 g/mol.

The crosslinking agent U has preferably, for example, a structure represented by Formula (U-1).

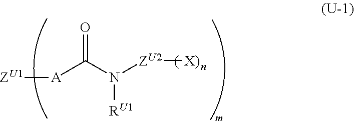

In Formula (U-1), R^{U1} is a hydrogen atom or a monovalent organic group, A is —O—, or —NR^{N}—, R^{N} is a hydrogen atom or a monovalent organic group, Z^{U1} is an m-valent organic group, Z^{U2} is an (n+1)-valent organic group, X is a radically polymerizable group, n is an integer of 1 or more, and m is an integer of 1 or more.

R^{U1} is preferably a hydrogen atom, an alkyl group, or an aromatic hydrocarbon group, and more preferably a hydrogen atom.

R^{N} is preferably a hydrogen atom, an alkyl group, or an aromatic hydrocarbon group, and more preferably a hydrogen atom.

Z^{U1} is preferably a hydrocarbon group, —O—, —C(═O)—, —S—, —S(═O)₂—, —NR^{N}—, or a group in which two or more of these are bonded, and more preferably a hydrocarbon group or a group in which a hydrocarbon group is bonded to at least one group selected from the group consisting of —O—, —C(═O)—, —S—, —S(═O)₂—, and —NR^{N}—.

As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. Examples of the above-described hydrocarbon group include a saturated aliphatic hydrocarbon group, an aromatic hydrocarbon group, and a group represented by bonding of these groups. R^{N} represents a hydrogen atom or a monovalent organic group, and it is preferably a hydrogen atom or a hydrocarbon group, more preferably a hydrogen atom or an alkyl group, and still more preferably a hydrogen atom or a methyl group.

Z^{U2} is preferably a hydrocarbon group, —O—, —C(═O)—, —S—, —S(═O)₂—, —NR^{N}—, or a group in which two or more of these are bonded, and more preferably a hydrocarbon group or a group in which a hydrocarbon group is bonded to at least one group selected from the group consisting of —O—, —C(═O)—, —S—, —S(═O)₂—, and —NR^{N}—.

Examples of the hydrocarbon group include the same ones as those exemplified as Z^{U1}, and the same applies to the preferred aspect thereof.

X is not particularly limited; however, examples thereof include a vinyl group, an allyl group, a (meth)acryloyl group, a (meth)acryloxy group, a (meth)acrylamide group, a vinylphenyl group, and a maleimide group, where a (meth)acryloxy group, a (meth)acrylamide group, a vinylphenyl group, or a maleimide group is preferable, and a (meth)acryloxy group is more preferable.

n is preferably an integer of 1 to 10, more preferably an integer of 1 to 4, still more preferably 1 or 2, and particularly preferably 1.

m is preferably an integer of 1 to 10, more preferably an integer of 1 to 4, and still more preferably 1 or 2.

It is also preferable that the crosslinking agent U has at least one of a hydroxy group, an alkyleneoxy group, an amide group, or a cyano group.

From the viewpoint of the chemical resistance of the cured film to be obtained, the hydroxy group may be an alcoholic hydroxy group or a phenolic hydroxy group; however, it is preferably an alcoholic hydroxy group.

From the viewpoint of the chemical resistance of the cured film to be obtained, the alkyleneoxy group is preferably an alkyleneoxy group having 2 to 20 carbon atoms, more preferably an alkyleneoxy group having 2 to 10 carbon atoms, still more preferably an alkyleneoxy group having 2 to 4 carbon atoms, even still more preferably an ethylene group or a propylene group, and particularly preferably an ethylene group.

The alkyleneoxy group may be contained in the crosslinking agent U as a polyalkyleneoxy group. The number of repetitions of the alkyleneoxy group in this case is preferably 2 to 10 and more preferably 2 to 6.

The amide group refers to a bond represented by —C(═O)—NR^{N}—. R^{N} is as described above. In a case where the crosslinking agent U has an amide group, the crosslinking agent U can include, for example, a group represented by R—C(═O)—NR^{N}—* or a group represented by *—C(═O)—NR^{N}—R. R represents a hydrogen atom or a monovalent substituent, and it is preferably a hydrogen atom or a hydrocarbon group and more preferably a hydrogen atom, an alkyl group, or an aromatic hydrocarbon group.

The crosslinking agent U may have, in the molecule, two or more structures selected from the group consisting of a hydroxy group, an alkyleneoxy group (however, a polyalkyleneoxy group in a case of constituting a polyalkyleneoxy group), an amide group, and a cyano group; however, an aspect in which only one structure is contained in the molecule is also preferable.

The hydroxy group, the alkyleneoxy group, the amide group, and the cyano group may be present at any position of the crosslinking agent U. However, from the viewpoint of chemical resistance, it is also preferable that the crosslinking agent U is such that at least one selected from the group consisting of the hydroxy group, the alkyleneoxy group, the amide group, and the cyano group, and at least one radically polymerizable group contained in the crosslinking agent U are linked by a linking group (hereinafter, also referred to as a “linking group L2-1”) containing a urea bond or a urethane bond.

In particular, in a case where the crosslinking agent U contains only one radically polymerizable group, it is preferable that the radically polymerizable group contained in the crosslinking agent U and at least one selected from the group consisting of a hydroxy group, an alkyleneoxy group, an amide group, and a cyano group are linked by a linking group including a urea bond or a urethane bond (hereinafter, also referred to as a “linking group L2-2”).

In a case where the crosslinking agent U contains an alkyleneoxy group (however, a polyalkyleneoxy group in a case of constituting a polyalkyleneoxy group) and has the above-described linking group L2-1 or the above-described linking group L2-2, a structure that is bonded to a side of the alkyleneoxy group (however, a polyalkyleneoxy group in a case of constituting a polyalkyleneoxy group) opposite to the linking group L2-1 or the linking group L2-2 is not particularly limited; however, it is preferably a hydrocarbon group, a radically polymerizable group, or a group represented by a combination thereof. As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. Examples of the above-described hydrocarbon group include a saturated aliphatic hydrocarbon group, an aromatic hydrocarbon group, and a group represented by bonding of these groups. In addition, the preferred aspect of the radically polymerizable group is the same as the preferred aspect of the radically polymerizable group in the above-described crosslinking agent U.

In a case where the crosslinking agent U contains an amide group and has the linking group L2-1 or the linking group L2-2, a structure that is bonded to a side of the amide group opposite to the linking group L2-1 or the linking group L2-2 is not particularly limited; however, it is preferably a hydrocarbon group, a radically polymerizable group, or a group represented by a combination thereof. As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. In addition, examples of the above-described hydrocarbon group include a saturated aliphatic hydrocarbon group, an aromatic hydrocarbon group, and a group represented by bonding of these groups. The preferred aspect of the radically polymerizable group is the same as the preferred aspect of the radically polymerizable group in the above-described crosslinking agent U. In addition, in the above aspect, a carbon atom side of the amide group may be bonded to the linking group L2-1 or the linking group L2-2, or a nitrogen atom side of the amide group may be bonded to the linking group L2-1 or the linking group L2-2.

Among these, from the viewpoint of the adhesiveness to the base material, the chemical resistance, and the Cu void suppression, the crosslinking agent U preferably has a hydroxy group.

From the viewpoint of the compatibility with the specific resin and the like, the crosslinking agent U preferably contains an aromatic group.

The aromatic group is preferably directly bonded to a urea bond or a urethane bond contained in the crosslinking agent U. In a case where the crosslinking agent U contains two or more urea bonds or two or more urethane bonds, it is preferable that one of the urea bonds or urethane bonds is directly bonded to the aromatic group.

The aromatic group may be an aromatic hydrocarbon group or an aromatic heterocyclic group and may have a structure in which these groups form a fused ring; however, an aromatic hydrocarbon group is preferable.

The aromatic hydrocarbon group is preferably an aromatic hydrocarbon group having 6 to 30 carbon atoms, more preferably an aromatic hydrocarbon group having 6 to 20 carbon atoms, and still more preferably a group obtained by removing two or more hydrogen atoms from a benzene ring structure.

The aromatic heterocyclic group is preferably a 5-membered or 6-membered aromatic heterocyclic group. Examples of the aromatic heterocyclic ring in such an aromatic heterocyclic group include pyrrole, imidazole, triazole, tetrazole, pyrazole, furan, thiophene, oxazole, isoxazole, thiazole, pyridine, pyrazine, pyrimidine, pyridazine, and triazine. These rings may be further fused with another ring, for example, as in the case of indole or benzimidazole.

The heteroatom contained in the aromatic heterocyclic group is preferably a nitrogen atom, an oxygen atom, or a sulfur atom.

It is preferable that the aromatic group is included in, for example, a linking group that links two or more radically polymerizable groups and links a linking group having a urea bond or a urethane bond, or at least one selected from the group consisting of a hydroxy group, an alkyleneoxy group, an amide group, and a cyano group, to at least one radically polymerizable group contained in the crosslinking agent U.

The number of atoms (linking chain length) between the urea bond or urethane bond and the radically polymerizable group in the crosslinking agent U is not particularly limited; however, it is preferably 30 or less, more preferably 2 to 20, and still more preferably 2 to 10.

In a case where the crosslinking agent U contains two or more urea bonds or urethane bonds in total, the minimum number of atoms (linking chain length) between the urea bond or urethane bond and the radically polymerizable group is sufficient to be within the above-described range in a case where the crosslinking agent U contains two or more radically polymerizable groups, or in a case where the crosslinking agent U contains two or more urea bonds or two or more urethane bonds and two or more radically polymerizable groups.

In the present specification, the phrase “number of atoms (linking chain length) between the urea bond or urethane bond and the radically polymerizable group” refers to the smallest number of atoms (minimum number of atoms) for linking targets among the number of atoms for atomic chains on a path that links two atoms or atomic groups between the linking targets. For example, in a structure represented by the following Formula, the number of atoms (linking chain length) between the urea bond and the radically polymerizable group (methacryloyloxy group) is 2.

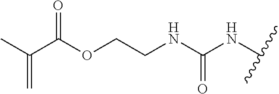 [SMILES: *NC(=O)NCCOC(=O)C(=C)C]

### [Symmetry Axis]

It is also preferable that the crosslinking agent U is a compound having a structure which does not have a symmetry axis.

The fact that the crosslinking agent U does not have a symmetry axis refers to that the crosslinking agent U is a left-right asymmetric compound which does not have an axis that generates the same molecule as the original molecule in a case where the entire compound is rotated. In addition, in a case where the structural formula of the crosslinking agent U is shown on the paper surface, the fact that the crosslinking agent U does not have a symmetry axis refers to that the structural formula of the crosslinking agent U cannot be shown in a form having a symmetry axis.

It is considered that the aggregation of the crosslinking agents U is suppressed in the composition film in a case where the crosslinking agent U does not have a symmetry axis.

### [Molecular Weight]

The molecular weight of the crosslinking agent U is preferably 100 to 2,000, more preferably 150 to 1,500, and still more preferably 200 to 900.

A method for producing the crosslinking agent U is not particularly limited; however, the crosslinking agent U can be obtained, for example, by reacting a compound having a radically polymerizable group and an isocyanate group with a compound having at least one of a hydroxy group or an amino group.

Specific examples of the crosslinking agent U are shown below; however, the crosslinking agent U is not limited thereto.

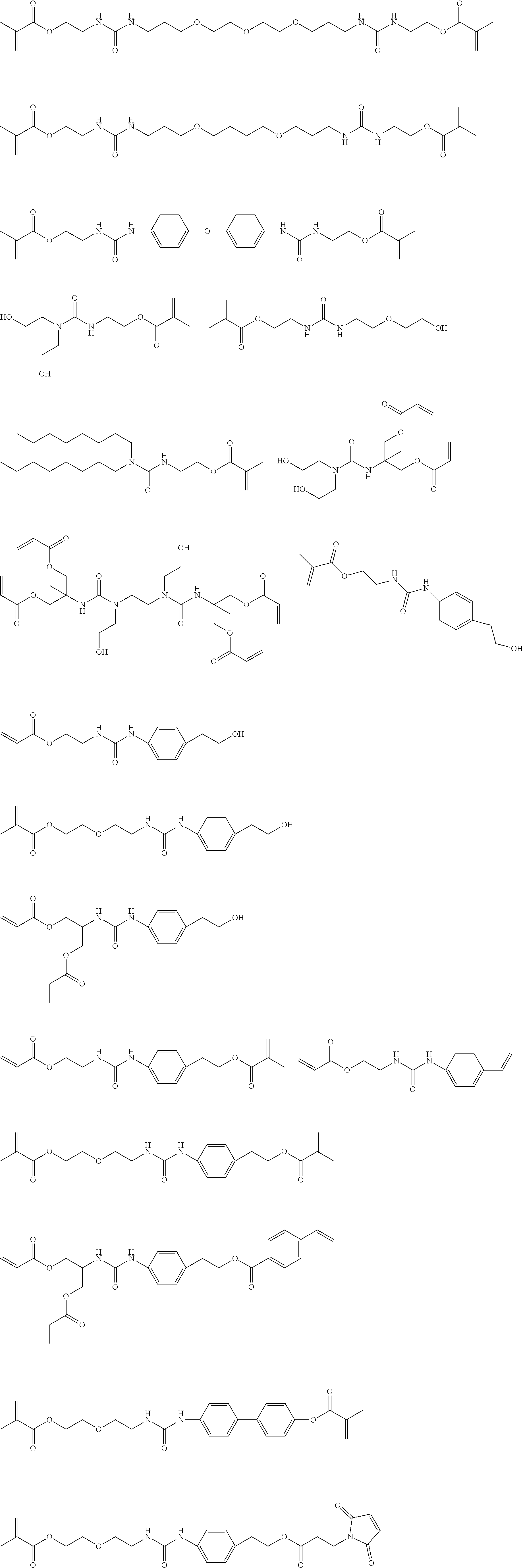

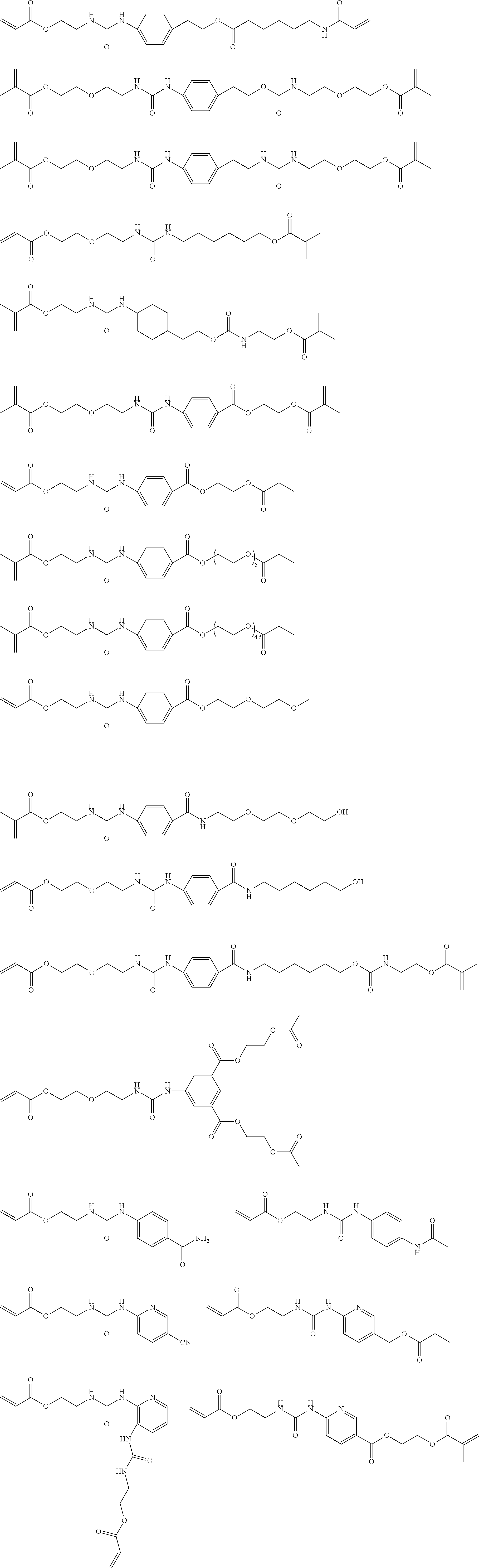

In the resin composition, it is preferable to use difunctional methacrylate or acrylate from the viewpoint of pattern resolution and film elasticity.

Specific examples include: triethylene glycol diacrylate, triethylene glycol dimethacrylate, tetraethylene glycol dimethacrylate, tetraethylene glycol diacrylate, polyethylene glycol (PEG) 200 diacrylate, PEG 200 dimethacrylate, PEG 600 diacrylate, PEG 600 dimethacrylate, polytetraethylene glycol diacrylate, polytetraethylene glycol dimethacrylate, dipropylene glycol diacrylate, tripropylene glycol diacrylate, neopentyl glycol diacrylate, neopentyl glycol dimethacrylate, 3-methyl-1,5-pentanediol diacrylate, 1,6-hexanediol diacrylate, 1,6-hexanediol dimethacrylate, dimethylol-tricyclodecanediacrylate, dimethylol-tricyclodecanedimethacrylate, a diacrylate of an ethylene oxide (EO) adduct of bisphenol A, a dimethacrylate of an EO adduct of bisphenol A, a diacrylate of a propylene oxide (PO) adduct of bisphenol A, a dimethacrylate of a PO adduct of bisphenol A, 2-hydroxy-3-acryloyloxypropyl methacrylate, isocyanuric acid EO-modified diacrylate, isocyanuric acid EO-modified dimethacrylate, another difunctional acrylate having a urethane bond, and difunctional methacrylate having a urethane bond. As necessary, two or more of these can be used as a mixture.

It is noted that, for example, the PEG 200 diacrylate refers to a polyethylene glycol diacrylate having a polyethylene glycol chain Formula weight of about 200.

In the resin composition according to the embodiment of the present invention, a monofunctional radical crosslinking agent can be preferably used as the radical crosslinking agent from the viewpoint of suppressing the warping of the pattern (cured product). As the monofunctional radical crosslinking agent, (meth)acrylic acid derivatives such as n-butyl (meth)acrylate, 2-ethylhexyl (meth)acrylate, 2-hydroxyethyl (meth)acrylate, butoxyethyl (meth)acrylate, carbitol (meth)acrylate, cyclohexyl (meth)acrylate, benzyl (meth)acrylate, phenoxyethyl (meth)acrylate, N-methylol (meth)acrylamide, glycidyl (meth)acrylate, polyethylene glycol mono(meth)acrylate, and polypropylene glycol mono(meth)acrylate, N-vinyl compounds such as N-vinylpyrrolidone and N-vinylcaprolactam, allyl glycidyl ethers, and the like are preferably used. As the monofunctional radical crosslinking agent, a compound having a boiling point of 100° C. or higher under normal pressure is also preferable in order to suppress volatilization before exposure.

In addition, examples of the bi- or higher functional radical crosslinking agent include allyl compounds such as diallyl phthalate and triallyl trimellitate.

In a case where a radical crosslinking agent is contained, the content of the radical crosslinking agent is preferably more than 0% by mass and 60% by mass or less with respect to the total solid content of the resin composition. The lower limit thereof is more preferably 5% by mass or more. An upper limit is more preferably 50% by mass or less and still more preferably 30% by mass or less.

One kind of radical crosslinking agent may be used alone, or two or more kinds thereof may be used as a mixture. In a case where two or more kinds thereof are used in combination, the total amount thereof is preferably in the above range.

### [Another Crosslinking Agent]

The resin composition according to the embodiment of the present invention also preferably contains another crosslinking agent different from the radical crosslinking agent described above.

The other crosslinking agent refers to a crosslinking agent other than the above-described radical crosslinking agent, where it is preferably a compound having a plurality of groups, in the molecule, which accelerates a reaction of forming a covalent bond between other compounds in the composition or reaction products thereof, by the photosensitization of the above-described photoacid generator or photobase generator, and preferably a compound having a plurality of groups, in the molecule, which accelerates a reaction of forming a covalent bond between other compounds in the composition or reaction products thereof, by the action of the acid or the base.

Examples of the other crosslinking agent include the compounds described in paragraphs 0179 to 0207 of WO2022/145355A. The above description is incorporated in the present specification.

The content of the other crosslinking agent is preferably 0.1% to 30% by mass, more preferably 0.1% to 20% by mass, still more preferably 0.5% to 15% by mass, and particularly preferably 1.0% to 10% by mass, with respect to the total solid content of the resin composition.

Only one kind of the other crosslinking agent may be contained, or two or more kinds thereof may be contained. In a case where two or more kinds of the other crosslinking agents are contained, the total thereof is preferably within the above-described range.

### [Polymerization Initiator]

The resin composition according to the embodiment of the present invention contains a polymerization initiator. The polymerization initiator may be a thermal polymerization initiator or a photopolymerization initiator; however, it is particularly preferable to contain a photopolymerization initiator.

The photopolymerization initiator is preferably a photoradical polymerization initiator. The photoradical polymerization initiator is not particularly limited and can be appropriately selected from known photoradical polymerization initiators. For example, a photoradical polymerization initiator having photosensitivity to rays ranging from the ultraviolet ray range to the visible light range is preferable. In addition, it may be an activator that acts with a sensitizer to generate an active radical.

The photoradical polymerization initiator preferably contains at least one compound having a molar absorption coefficient of at least about 50 L·mol⁻¹·cm⁻¹ within a range of a wavelength of about 240 to 800 nm (preferably 330 to 500 nm). The molar absorption coefficient of a compound can be measured using a well-publicly known method. For example, it is preferable to carry out a measurement at a concentration of 0.01 g/L using an ethyl acetate solvent with an ultraviolet-visible spectrophotometer (Cary-5 spectrophotometer manufactured by Varian Medical Systems, Inc.).

As a photoradical polymerization initiator, well-known compounds can be optionally used. Examples thereof include a halogenated hydrocarbon derivative (for example, a compound having a triazine skeleton, a compound having an oxadiazole skeleton, or a compound having a trihalomethyl group), an acylphosphine compound such as an acylphosphine oxide, hexaarylbiimidazole, an oxime compound such as an oxime derivative, an organic peroxide, a thio compound, a ketone compound, an aromatic onium salt, a keto oxime ether, an α-amino ketone compound such as aminoacetophenone, an α-hydroxy ketone compound such as hydroxyacetophenone, an azo-based compound, an azide compound, a metallocene compound, an organic boron compound, and an iron arene complex. With regard to details thereof, reference can be made to the description of paragraphs 0165 to 0182 of JP2016-027357A and paragraphs 0138 to 0151 of WO2015/199219A, the contents of which are incorporated in the present specification. In addition, examples thereof include the compounds described in paragraphs 0065 to 0111 of JP2014-130173A and JP6301489B, the peroxide-based photopolymerization initiator described in MATERIAL STAGE 37 to 60 p, vol. 19, No. 3, 2019, the photopolymerization initiator described in WO2018/221177A, the photopolymerization initiator described in WO2018/110179A, the photopolymerization initiator described in JP2019-043864A, the photopolymerization initiator described in JP2019-044030A, and the peroxide-based initiator described in JP2019-167313A, the contents of which are incorporated in the present specification.

Examples of the ketone compounds include compounds described in paragraph 0087 of JP2015-087611A, the content of which is incorporated in the present specification. As a commercially available product thereof, KAYACURE DETX-S (manufactured by Nippon Kayaku Co., Ltd.) is also suitably used.

In one embodiment according to the present invention, a hydroxyacetophenone compound, an aminoacetophenone compound, and an acylphosphine compound can be suitably used as the photoradical polymerization initiator. More specifically, for example, the aminoacetophenone-based initiator described in JP1998-291969A (JP-H10-291969A) and the acylphosphine oxide-based initiator described in JP4225898B can be used, the contents of which are incorporated in the present specification.

As the α-hydroxy ketone-based initiator, Omnirad 184, Omnirad 1173, Omnirad 2959, Omnirad 127 (all of which are manufactured by IGM Resins B.V.), IRGACURE 184 (IRGACURE is a registered trademark), DAROCUR 1173, IRGACURE 500, IRGACURE-2959, and IRGACURE 127 (all of which are manufactured by BASF SE) can be used.

As the α-amino ketone-based initiator, Omnirad 907, Omnirad 369, Omnirad 369E, Omnirad 379EG (all of which are manufactured by IGM Resins B.V.), IRGACURE 907, IRGACURE 369, and IRGACURE 379 (all of which are manufactured by BASF SE) can be used.

As the aminoacetophenone-based initiator, the acylphosphine oxide-based initiator, and the metallocene compound, it is also possible to suitably use, for example, the compounds described in paragraphs 0161 to 0163 of WO2021/112189A. The contents thereof are incorporated into the present specification.

Examples of the more preferred photoradical polymerization initiator include oxime compounds. In a case where an oxime compound is used, exposure latitude can be more effectively improved. The oxime compound is particularly preferable since the oxime compound has a wide exposure latitude (a wide exposure margin) and also works as a photocuring accelerator.

Specific examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A, the content of which is incorporated in the present specification.

Examples of the preferred oxime compound include compounds having the following structures, 3-(benzoyloxy(imino))butan-2-one, 3-(acetoxy(imino))butan-2-one, 3-(propionyloxy(imino))butan-2-one, 2-(acetoxy(imino))pentan-3-one, 2-(acetoxy(imino))-1-phenylpropan-1-one, 2-(benzoyloxy(imino))-1-phenylpropan-1-one, 3-((4-toluenesulfonyloxy)imino)butan-2-one, and 2-(ethoxycarbonyloxy(imino))-1-phenylpropan-1-one. In the resin composition, it is preferable to use an oxime compound, particularly as a photoradical polymerization initiator. The oxime compound as a photoradical polymerization initiator has a linking group of >C═N—O—C(═O)— in the molecule.

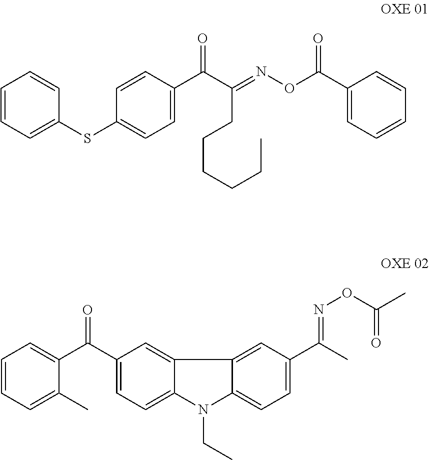 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

Examples of the commercially available products of the oxime compound include IRGACURE OXE 01, IRGACURE OXE 02, IRGACURE OXE 03, and IRGACURE OXE 04 (all of which are manufactured by BASF SE), ADEKA OPTOMER N-1919 (manufactured by ADEKA Corporation, the photoradical polymerization initiator 2 described in JP2012-014052A), TR-PBG-304 and TR-PBG-305 (all of which are manufactured by Changzhou Tronly New Electronic Materials Co., Ltd.), ADEKA ARKLS NCI-730, NCI-831, and ADEKA ARKLS NCI-930 (all of which are manufactured by ADEKA Corporation), DFI-091 (manufactured by DAITO CHEMIX Co., Ltd.), and SpeedCure PDO (manufactured by SARTOMER ARKEMA). In addition, oxime compounds having the following structures can also be used.

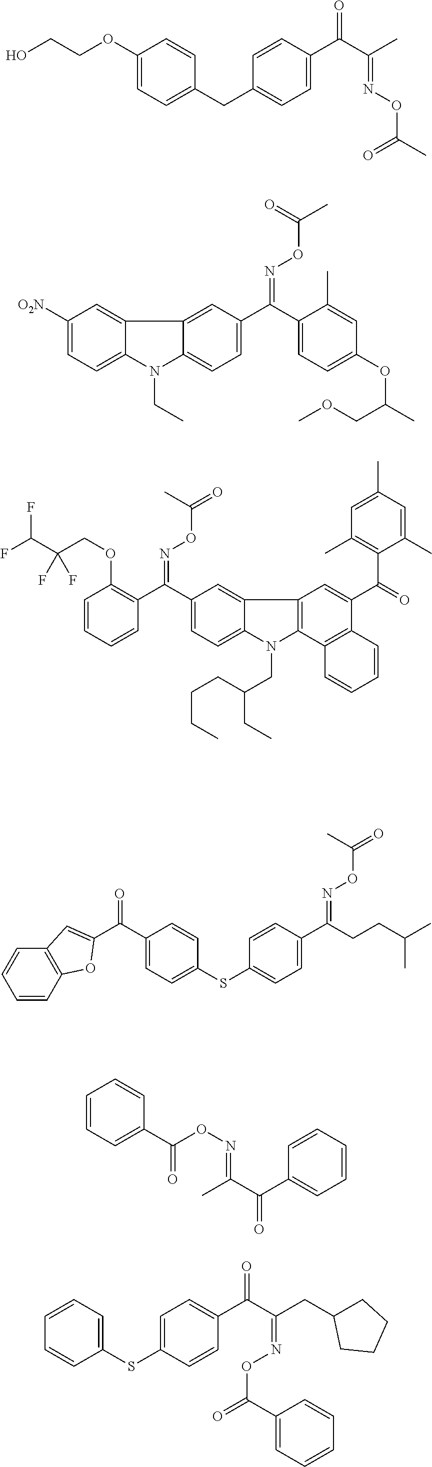

As the photoradical polymerization initiator, itis also possible to use, for example, oxime compounds having a fluorene ring, which are described in paragraphs 0169 to 0171 of WO2021/112189A, oxime compounds having a skeleton in which at least one benzene ring of a carbazole ring is replaced with a naphthalene ring, or oxime compounds having a fluorine atom.

In addition, it is also possible to use oxime compounds having a nitro group, which are described in paragraphs 0208 to 0210 of WO2021/020359A, oxime compounds having a benzofuran skeleton, or oxime compounds in which a substituent having a hydroxy group is bonded to a carbazole skeleton. The contents of which are incorporated in the present specification.

In addition, as the photopolymerization initiator, compounds described in paragraphs 0113 to 0117 of JP2023-058585A can also be used. This description is incorporated in the present specification.

In a case where the resin composition contains a photopolymerization initiator, the content thereof is preferably 0.1% to 30% by mass, more preferably 0.1% to 20% by mass, still more preferably 0.5% to 15% by mass, and even still more preferably 1.0% to 10% by mass with respect to the total solid content of the resin composition. Only one kind of photopolymerization initiator may be contained, or two or more kinds thereof may be contained.

In a case where two or more kinds of photopolymerization initiators are contained, the total amount thereof is preferably within the above-described range.

It is noted that since the photopolymerization initiator may also function as a thermal polymerization initiator, crosslinking with the photopolymerization initiator may be further promoted by heating an oven, a hot plate, or the like.

### [Sensitizer]

The resin composition may contain a sensitizer. The sensitizer absorbs a specific radioactive ray to be in an electronically excited state. The sensitizer in the electronically excited state is brought into contact with a thermal radical polymerization initiator, a photoradical polymerization initiator, or the like, to cause actions such as electron migration, energy transfer, and heat generation. As a result, the thermal radical polymerization and the photoradical polymerization initiator undergo a chemical change and decompose to generate a radical, an acid, or a base.

In addition, as a usable sensitizer, a benzophenone-based compound, a Michler's ketone-based compound, a coumarin-based compound, a pyrazole azo-based compound, an anilino azo-based compound, a triphenylmethane-based compound, an anthraquinone-based compound, an anthracene-based compound, an anthrapyridone-based compound, a benzylidene-based compound, an oxonol-based compound, a pyrazolotriazole azo-based compound, a pyridone azo-based compound, a cyanine-based compound, a phenothiazine-based compound, a pyrrolopyrazole azomethine-based compound, a xanthene-based compound, a phthalocyanine-based compound, a benzopyran-based compound, and an indigo-based compound can be used.

Examples of the sensitizer include, Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylidene indanone, p-dimethylamino benzylidene indanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin (ethyl 7-(diethylamino)coumarin-3-carboxylate), N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho(1,2-d)thiazole, 2-(p-dimethylaminobenzoyl)styrene, diphenylacetamide, benzanilide, N-methylacetanilide, and 3′,4′-dimethylacetanilide.

In addition, other sensitizing dyes may be used.

For details of the sensitizing dye, reference can be made to the description in paragraphs 0161 to 0163 of JP2016-027357A, the content of which is incorporated in the present specification.

In a case where the resin composition contains a sensitizer, the content of the sensitizer is preferably 0.01% to 20% by mass, more preferably 0.1% to 15% by mass, and still more preferably 0.5% to 10% by mass with respect to the total solid content of the resin composition. One kind of sensitizer may be used alone, or two or more kinds thereof may be used in combination.

### [Chain Transfer Agent]

The resin composition according to the embodiment of the present invention may contain a chain transfer agent. The chain transfer agent is defined, for example, in Polymer Dictionary, 3rd Edition, pp. 683 to 684 (edited by The Society of Polymer Science, 2005). As the chain transfer agent, for example, the following compound is used; a group of compounds having —S—S—, —SO₂—S—, —N—O—, SH, PH, SiH, or GeH in the molecule, or a dithiobenzoate compound, a trithiocarbonate compound, dithiocarbamate, and a xanthate compound, each having a thiocarbonylthio group used for reversible addition fragmentation chain transfer (RAFT) polymerization. These can donate hydrogen to a low-activity radical to generate a radical or can be oxidized and then deprotonated to generate a radical. In particular, a thiol compound can be preferably used.

In addition, as the chain transfer agent, the compounds described in paragraphs 0152 and 0153 of WO2015/199219A can also be used, the content of which is incorporated in the present specification.

In a case where the resin composition has a chain transfer agent, the content of the chain transfer agent is preferably 0.01 to 20 parts by mass, more preferably 0.1 to 10 parts by mass, and still more preferably 0.5 to 5 parts by mass, with respect to 100 parts by mass of the total solid content of the resin composition. One kind of chain transfer agent may be used, or two or more kinds thereof may be used. In a case where two or more kinds of chain transfer agents are used, the total thereof is preferably within the above-described range.

In addition, one of the preferred aspects of the present invention is that the resin composition according to the embodiment of the present invention contains two or more kinds of polymerization initiators as the polymerization initiator.

Specifically, the resin composition according to the present invention may contain a photopolymerization initiator and a thermal polymerization initiator described later.

By containing the photopolymerization initiator and the thermal polymerization initiator described later, pattern formation by exposure is possible, and radical polymerization is also likely to proceed during curing in the heating step described later, and thus the performance such as chemical resistance may be improved.

In the content ratio in a case where the photopolymerization initiator and the thermal polymerization initiator described later are contained, the content of the thermal polymerization initiator is preferably 20% to 70% by mass and more preferably 30% to 60% by mass with respect to the total content of the photopolymerization initiator and the thermal polymerization initiator.

The performance such as resolution may be improved by containing a photoradical polymerization initiator and a photoacid generator.

In the content ratio in a case where the photoradical polymerization initiator and the photoacid generator are contained, the content of the photoacid generator is preferably 20% to 70% by mass, and more preferably 30% to 60% by mass with respect to the total content of the photoradical polymerization initiator and the photoacid generator.

### [Thermal Polymerization Initiator]

Examples of the thermal polymerization initiator include a thermal radical polymerization initiator. The thermal radical polymerization initiator is a compound that generates a radical by heat energy and initiates or accelerates a polymerization reaction of a compound having polymerization properties. In a case where a thermal radical polymerization initiator is added, the polymerization reaction of the resin and the polymerizable compound can be allowed to proceed, and thus the solvent resistance can be further improved.

Specific examples of thermal radical polymerization initiators include compounds described in paragraphs 0074 to 0118 of JP2008-063554A, the contents of which are incorporated in the present specification.

In a case where a thermal polymerization initiator is contained, the content thereof is preferably 0.1% to 30% by mass, more preferably 0.1% to 20% by mass, and still more preferably 0.5% to 15% by mass with respect to the total solid content of the resin composition.

Only one kind of thermal polymerization initiator may be contained, or two or more kinds thereof may be contained. In a case where two or more kinds of thermal polymerization initiators are contained, the total amount thereof is preferably within the above-described range.

### <Base Generator>

The resin composition according to the embodiment of the present invention may contain a base generator. Here, the base generator is a compound that is capable of generating a base under a physical or chemical action. Examples of the preferred base generator include a thermal-base generator and a photobase generator.

In particular, in a case where the resin composition contains a precursor of a cyclization resin, it is preferable that the resin composition contains a base generator. In a case where the resin composition contains a thermal-base generator, it is possible to, for example, accelerate the cyclization reaction of the precursor by heating, whereby the mechanical properties and chemical resistance of the cured product are improved and for example, the performance as an interlayer insulating film for a re-distribution layer, included in a semiconductor package, is improved.

The base generator may be an ionic base generator or may be a nonionic base generator. Examples of the base that is generated from the base generator include a secondary amine and a tertiary amine.

The base generator is not particularly limited, and a publicly known base generator can be used. Examples of the publicly known base generator include a carbamoyloxime compound, a carbamoylhydroxylamine compound, a carbamic acid compound, a formamide compound, an acetamide compound, a carbamate compound, a benzylcarbamate compound, a nitrobenzylcarbamate compound, a sulfonamide compound, an imidazole derivative compound, an aminimide compound, a pyridine derivative compound, an α-aminoacetophenone derivative compound, a quaternary ammonium salt derivative compound, an iminium salt, a pyridinium salt, an α-lactone ring derivative compound, a phthalimide derivative compound, and an acyloxyimino compound.

Specific examples of the nonionic base generator include the compounds described in paragraphs 0249 to 0275 of WO2022/145355A. The above description is incorporated in the present specification.

Examples of the base generator include the following compounds; however, the base generator is not limited thereto.

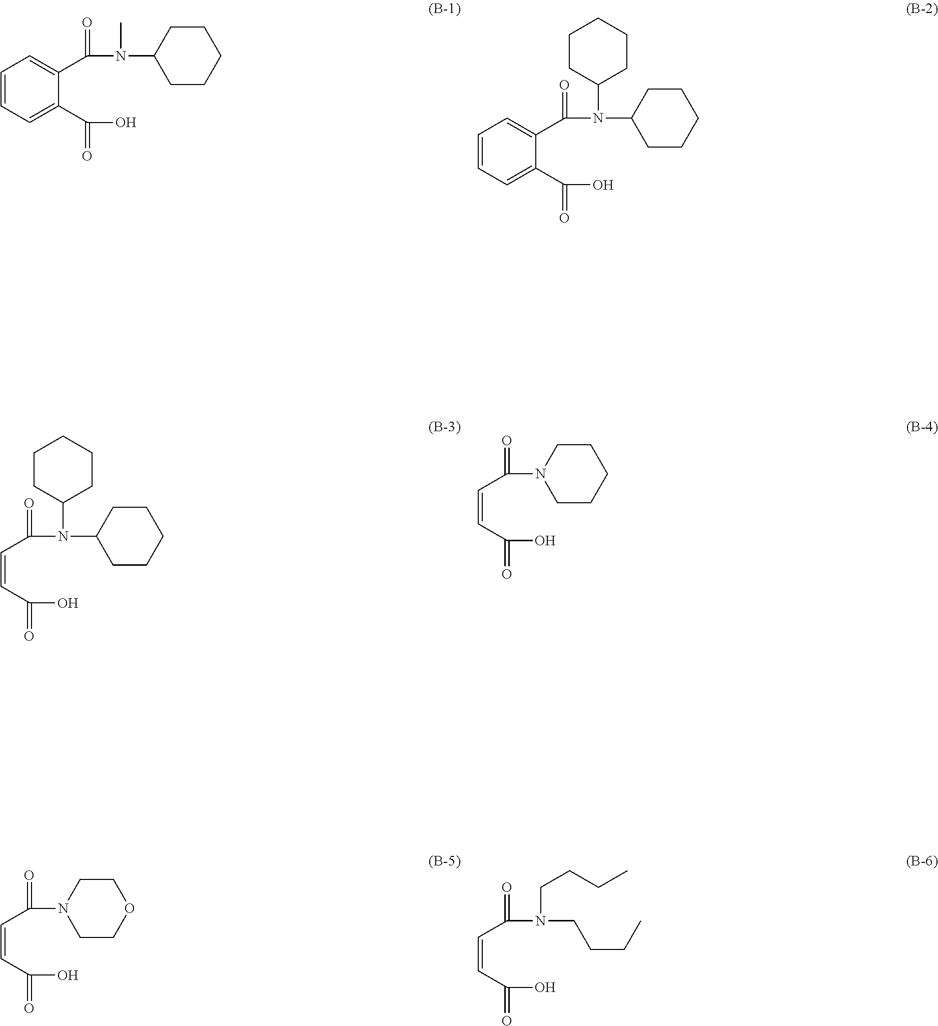 [SMILES: CN(C(=O)c1ccccc1C(=O)O)C1CCCCC1 ; O=C(O)c1ccccc1C(=O)N(C1CCCCC1)C1CCCCC1 ; O=C(O)/C=C\C(=O)N(C1CCCCC1)C1CCCCC1 ; O=C(O)/C=C\C(=O)N1CCCCC1 ; O=C(O)/C=C\C(=O)N1CCOCC1 ; CCCCN(CCCC)C(=O)/C=C\C(=O)O]

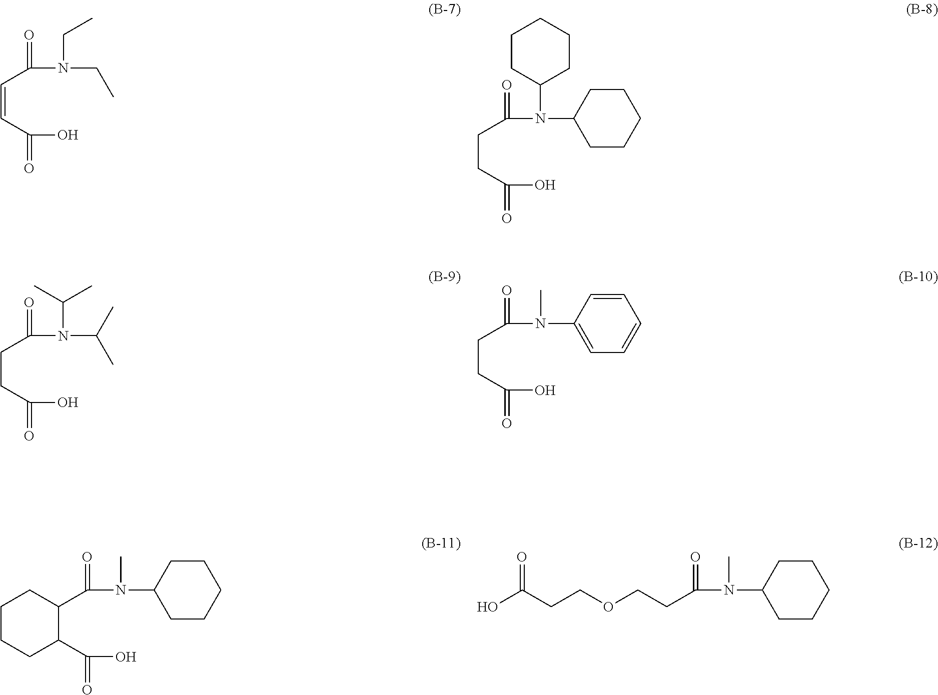 [SMILES: CCN(CC)C(=O)/C=C\C(=O)O ; O=C(O)CCC(=O)N(C1CCCCC1)C1CCCCC1 ; CC(C)N(C(=O)CCC(=O)O)C(C)C ; CN(C(=O)CCC(=O)O)c1ccccc1 ; CN(C(=O)C1CCCCC1C(=O)O)C1CCCCC1 ; CN(C(=O)CCOCCC(=O)O)C1CCCCC1]

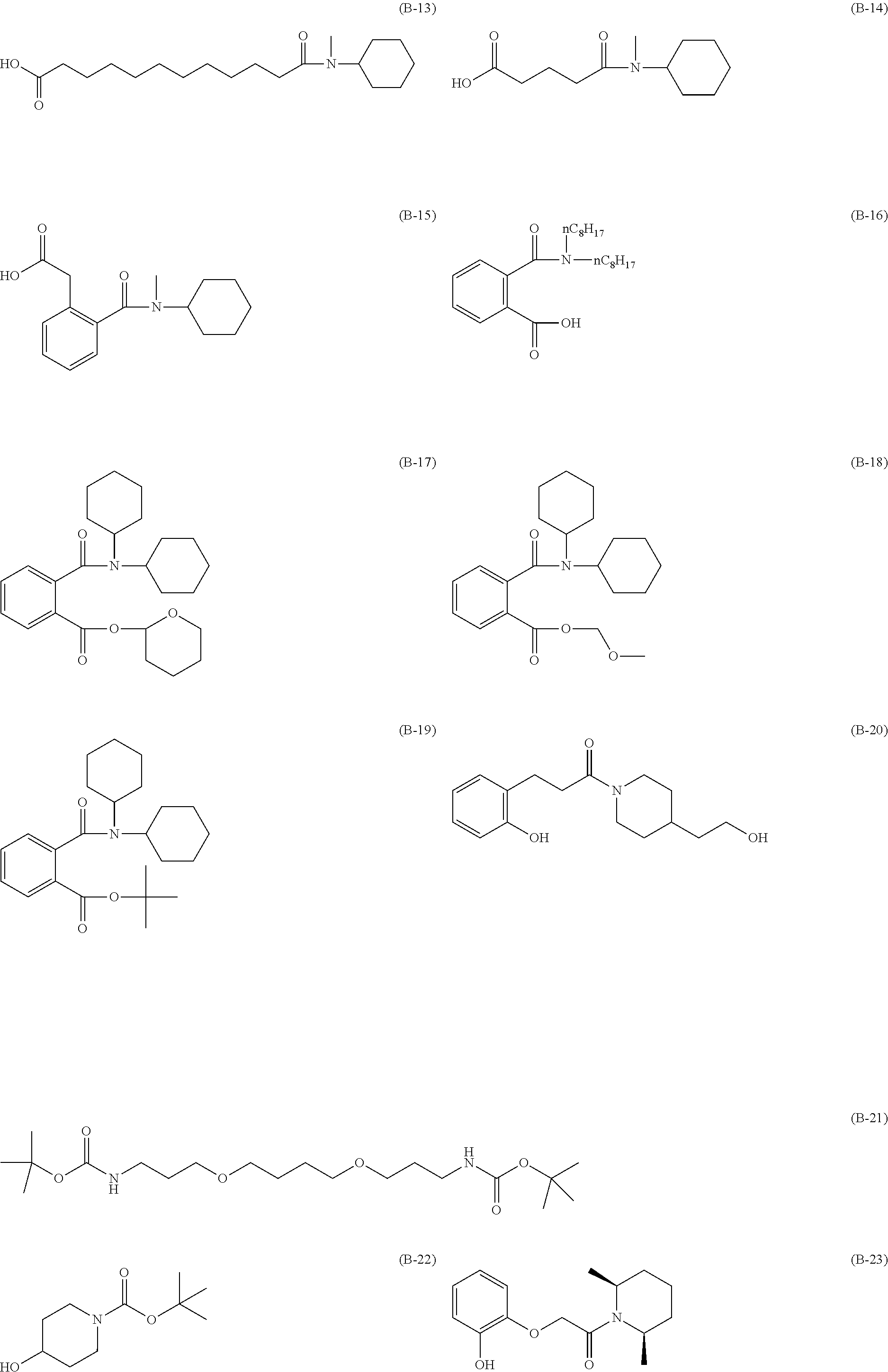

The molecular weight of the nonionic base generator is preferably 800 or less, more preferably 600 or less, and still more preferably 500 or less. The lower limit thereof is preferably 100 or more, more preferably 200 or more, and still more preferably 300 or more.

Examples of the specific preferred compound of the ionic base generator include the compounds described in paragraphs 0148 to 0163 of WO2018/038002A.

Specific examples of the ammonium salt include the following compounds; however, the ammonium salt is not limited thereto.

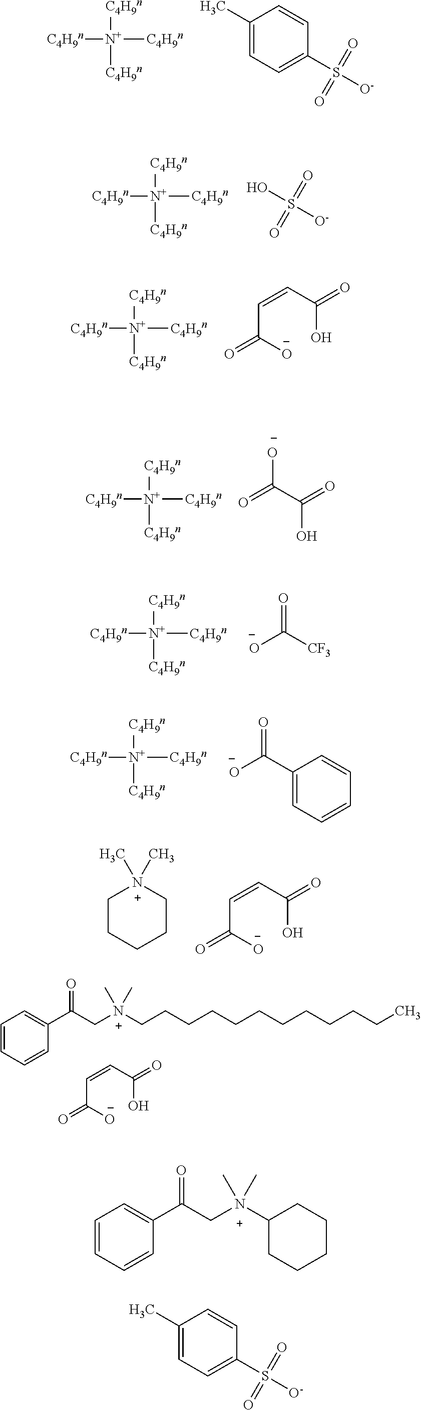

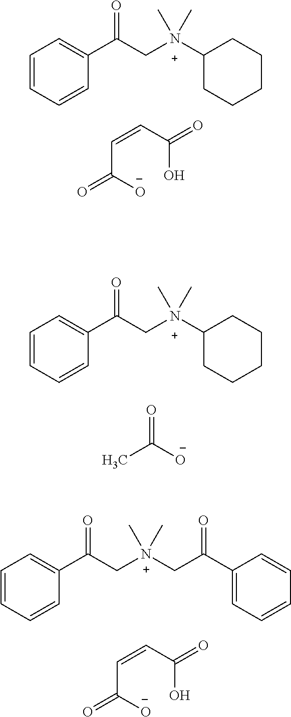

Specific examples of the iminium salt include the following compounds; however, the iminium salt is not limited thereto.

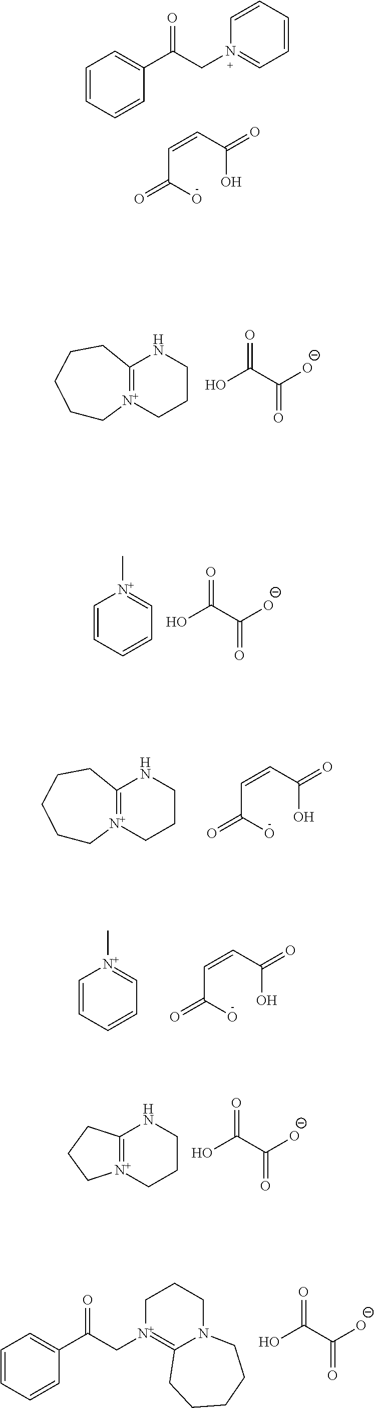

In addition, from the viewpoint of storage stability and generation of a base by deprotection during curing, the base generator is preferably an amine in which an amino group is protected by a t-butoxycarbonyl group.

Examples of the amine compound protected by a t-butoxycarbonyl group include ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexanethanol, 4-(2-aminoethyl)cyclohexanol, N-methylethanolamine, 3-(methylamino)-1-propanol, 3-(isopropylamino)propanol, N-cyclohexylethanolamine, α-[2-(methylamino)ethyl]benzyl alcohol, diethanolamine, diisopropanolamine, 3-pyrrolidinol, 2-pyrrolidinomethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidinethanol, 2-piperidinethanol, 2-(4-piperidyl)-2-propanol, 1,4-butanol bis(3-aminopropyl)ether, 1,2-bis(2-aminoethoxy)ethane, 2,2′-oxybis(ethylamine), 1,14-diamino-3,6,9,12-tetraoxatetradecane, 1-aza-15-crown 5-ether, diethylene glycol bis(3-aminopropyl)ether, 1,11-diamino-3,6,9-trioxaundecane, or a compound in which an amino group of an amino acid and a derivative thereof is protected by a t-butoxycarbonyl group, but the present invention is not limited to these examples.

In a case where the resin composition contains a base generator, the content of the base generator is preferably 0.1 to 50 parts by mass with respect to 100 parts by mass of the resin in the resin composition. The lower limit thereof is more preferably 0.3 parts by mass or more and still more preferably 0.5 parts by mass or more. The upper limit thereof is more preferably 30 parts by mass or less, still more preferably 20 parts by mass or less, even still more preferably 10 parts by mass or less, even further still more preferably 5 parts by mass or less, and particularly preferably 4 parts by mass or less.

One kind or two or more kinds of base generators can be used. In a case where two or more kinds thereof are used, the total amount is preferably within the above-described range.

### <Solvent>

The resin composition according to the embodiment of the present invention contains a solvent.

As the solvent, any known solvent can be used. The solvent is preferably an organic solvent. Examples of the organic solvent include compounds such as esters, ethers, ketones, cyclic hydrocarbons, sulfoxides, amides, ureas, and alcohols.

Suitable examples of the esters include ethyl acetate, n-butyl acetate, isobutyl acetate, hexyl acetate, amyl formate, isoamyl acetate, butyl propionate, isopropyl butyrate, ethyl butyrate, butyl butyrate, methyl lactate, ethyl lactate, γ-butyrolactone, ε-caprolactone, δ-valerolactone, γ-valerolactone, alkyl alkyloxyacetate (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), 3-alkyloxypropionic acid alkyl esters (for example, methyl 3-alkyloxypropionate, and ethyl 3-alkyloxypropionate (for example, methyl 3-methoxypropionate, ethyl 3-methoxypropionate, methyl 3-ethoxypropionate, and ethyl 3-ethoxypropionate)), 2-alkyloxypropionic acid alkyl esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methylpropionate and ethyl 2-alkyloxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, ethyl 2-oxobutanoate, ethyl hexanoate, ethyl heptanoate, dimethyl malonate, and diethyl malonate.

Suitable examples of ethers include ethylene glycol dimethyl ether, diethylene glycol dimethyl ether, diethylene glycol diethyl ether, diethylene glycol ethyl methyl ether, diethylene glycol butyl methyl ether, triethylene glycol dimethyl ether, tetraethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol dimethyl ether, propylene glycol monomethyl ether acetate, propylene glycol monoethyl ether acetate, ethylene glycol monobutyl ether, ethylene glycol monobutyl ether acetate, diethylene glycol ethyl methyl ether, propylene glycol monopropyl ether acetate, and dipropylene glycol dimethyl ether.

Suitable examples of the ketones include methyl ethyl ketone, cyclohexanone, cyclopentanone, 2-heptanone, 3-heptanone, 3-methylcyclohexanone, levoglucosenone, and dihydrolevoglucosenone.

Suitable examples of the cyclic hydrocarbon include aromatic hydrocarbons such as toluene, xylene, and anisole, and cyclic terpenes such as limonene.

Suitable examples of the sulfoxides include dimethyl sulfoxide.

Suitable examples of the amides include N-methyl-2-pyrrolidone, N-ethyl-2-pyrrolidone, N-cyclohexyl-2-pyrrolidone, N,N-dimethylacetamide, N,N-dimethylformamide, N,N-dimethylisobutylamide, 3-methoxy-N,N-dimethylpropionamide, 3-butoxy-N,N-dimethylpropionamide, N-formylmorpholine, and N-acetylmorpholine.

Suitable examples of the ureas include N,N,N′,N′-tetramethylurea and 1,3-dimethyl-2-imidazolidinone.

Examples of the alcohols include methanol, ethanol, 1-propanol, 2-propanol, 1-butanol, 1-pentanol, 1-hexanol, benzyl alcohol, ethylene glycol monomethyl ether, 1-methoxy-2-propanol, 2-ethoxyethanol, diethylene glycol monoethyl ether, diethylene glycol monohexyl ether, triethylene glycol monomethyl ether, propylene glycol monoethyl ether, propylene glycol monomethyl ether, polyethylene glycol monomethyl ether, polypropylene glycol, tetraethylene glycol, ethylene glycol monobutyl ether, ethylene glycol monobenzyl ether, ethylene glycol monophenyl ether, methylphenyl carbinol, n-amyl alcohol, methylamyl alcohol, and diacetone alcohol.

From the viewpoint of improving the properties of a coated surface or the like, it is also preferable to mix two or more kinds of solvents.

In the present invention, the solvent is preferably one solvent selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, γ-butyrolactone, γ-valerolactone, 3-methoxy-N,N-dimethylpropionamide, toluene, dimethyl sulfoxide, ethyl carbitol acetate, butyl carbitol acetate, N-methyl-2-pyrrolidone, propylene glycol methyl ether, and propylene glycol methyl ether acetate, as well as levoglucosenone and dihydrolevoglucosenone, or a mixed solvent composed of two or more of these. A combined use of dimethyl sulfoxide and γ-butyrolactone, a combined use of dimethyl sulfoxide and γ-valerolactone, a combined use of 3-methoxy-N,N-dimethylpropionamide and γ-butyrolactone, a combined use of 3-methoxy-N,N-dimethylpropionamide, γ-butyrolactone, and dimethyl sulfoxide, or a combined use of N-methyl-2-pyrrolidone and ethyl lactate is particularly preferable. An aspect in which an amount of about 1% to 10% by mass of toluene with respect to the total mass of the solvent is further added to these combinedly used solvents is also one of the preferred aspects of the present invention.

In particular, from the viewpoint of the storage stability or the like of the resin composition, an aspect in which γ-valerolactone is included as the solvent is also one of the preferred aspects of the present invention. In such an aspect, the content of γ-valerolactone with respect to the total mass of the solvent is preferably 50% by mass or more, more preferably 60% by mass or more, and still more preferably 70% by mass or more. In addition, the upper limit of the above-described content is not particularly limited, and it may be 100% by mass. The above-described content may be determined in consideration of the solubility or the like of the component contained in the resin composition, such as the specific resin.

In addition, in a case where dimethyl sulfoxide and γ-valerolactone are used in combination, with respect to the total mass of the solvent, it is preferable to contain 60% to 90% by mass of γ-valerolactone and 10% to 40% by mass of dimethyl sulfoxide, it is more preferable to contain 70% to 90% by mass of γ-valerolactone and 10% to 30% by mass of dimethyl sulfoxide, and it is still more preferable to contain 75% to 85% by mass of γ-valerolactone and 15% to 25% by mass of dimethyl sulfoxide.

Regarding the content of the solvent, the amount of the solvent is such that, from the viewpoint of coatability, the concentration of the total solid content of the resin composition according to the embodiment of the present invention is preferably 5% to 80% by mass, more preferably 5% to 75% by mass, still more preferably 10% to 70% by mass, and even still more preferably 20% to 70% by mass. The content of the solvent may be adjusted depending on the desired thickness of the coating film and the coating method. In a case where two or more kinds of solvents are contained, the total thereof is preferably within the above-described range.

### <Metal Adhesiveness Improving Agent>

From the viewpoint of improving adhesiveness to a metal material used for an electrode, wiring, or the like, the resin composition according to the embodiment of the present invention preferably contains a metal adhesiveness improving agent. Examples of the metal adhesiveness improving agent include a silane coupling agent having an alkoxysilyl group, an aluminum-based auxiliary adhesive agent, a titanium-based auxiliary adhesive agent, a compound having a sulfonamide structure and a compound having a thiourea structure, a phosphoric acid derivative compound, a p ketoester compound, and an amino compound.

### [Silane Coupling Agent]

Examples of the silane coupling agent include the compounds described in paragraph 0316 of WO2021/112189A and the compounds described in paragraphs 0067 to 0078 of JP2018-173573A, the contents of which are incorporated in the present specification. In addition, it is also preferable to use two or more kinds of different silane coupling agents as described in paragraphs 0050 to 0058 of JP2011-128358A. It is also preferable to use the following compound as the silane coupling agent. In the following Formulae, Me represents a methyl group, and Et represents an ethyl group. In addition, examples of R shown below include a structure derived from a blocking agent in a blocked isocyanate group. The blocking agent may be selected depending on the desorption temperature; however, examples thereof include an alcohol compound, a phenol compound, a pyrazole compound, a triazole compound, a lactam compound, and an active methylene compound. Caprolactam or the like is preferable, for example, from the viewpoint of setting the desorption temperature to 160° C. to 180° C. Examples of the commercially available products of such a compound include X-12-1293 (manufactured by Shin-Etsu Chemical Co., Ltd.).

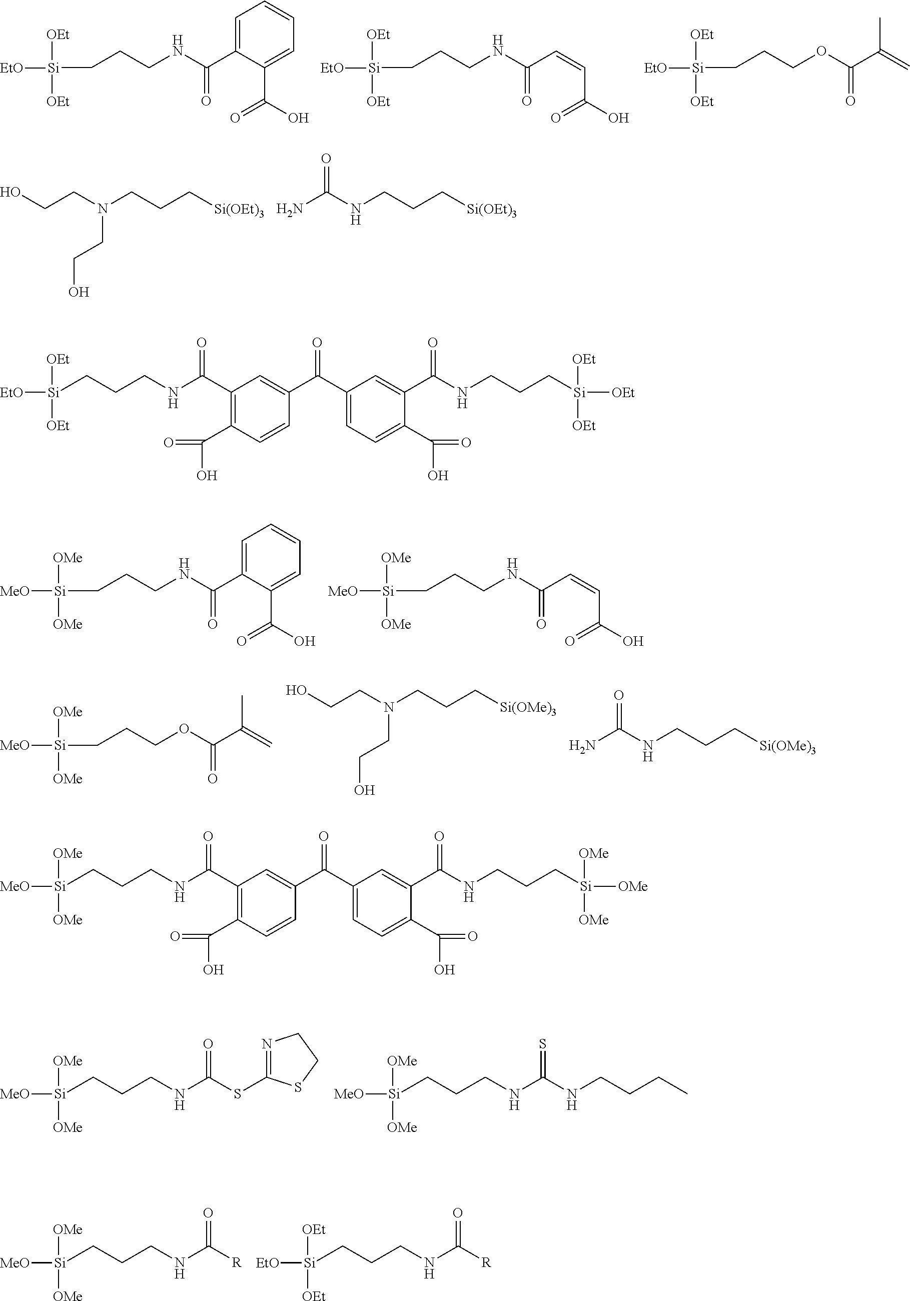

Examples of the other silane coupling agent include vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, tris-(trimethoxysilylpropyl)isocyanurate, 3-ureidopropyltrialkoxysilane, 3-mercaptopropylmethyldimethoxysilane, 3-mercaptopropyltrimethoxysilane, 3-isocyanatepropyltriethoxysilane, and 3-trimethoxysilylpropylsuccinic acid anhydride. These can be used alone or in a combination of two or more thereof.

In addition, an oligomer type compound having a plurality of alkoxysilyl groups can also be used as the silane coupling agent.

Examples of such an oligomer type compound include a compound containing a repeating unit represented by Formula (S-1).

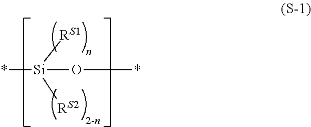

In Formula (S-1), R^{S1} represents a monovalent organic group, R^{S2} represents a hydrogen atom, a hydroxy group, or an alkoxy group, and n represents an integer of 0 to 2.

R^{S1} preferably has a structure including a polymerizable group. Examples of the polymerizable group include a group having an ethylenically unsaturated bond, an epoxy group, an oxetanyl group, a benzoxazolyl group, a blocked isocyanate group, and an amino group.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

R^{S2} is preferably an alkoxy group, and more preferably a methoxy group or an ethoxy group.

n represents an integer of 0 to 2, and it is preferably 1.

Here, structures of a plurality of repeating units represented by Formula (S-1) may be the same, where the plurality of repeating units are contained in the oligomer type compound.

Here, among a plurality of repeating units represented by Formula (S-1), which are contained in the oligomer type compound, it is preferable that at least one repeating unit has n of 1 or 2, it is more preferable that at least two repeating units have n of 1 or 2, and it is still more preferable that at least two repeating units have n of 1.

As such an oligomer type compound, a commercially available product can be used, and examples thereof include KR-513 (manufactured by Shin-Etsu Chemical Co., Ltd.).

### [Aluminum-Based Auxiliary Adhesive Agent]

Examples of the aluminum-based auxiliary adhesive agent include aluminum tris(ethyl acetoacetate), aluminum tris(acetylacetonate), and aluminum diisopropylate ethyl acetoacetate.

As other metal adhesiveness improving agents, the compounds described in paragraphs 0046 to 0049 of JP2014-186186A, and the sulfide-based compounds described in paragraphs 0032 to 0043 of JP2013-072935A can also be used, and the contents of which are incorporated in the present specification.

The content of the metal adhesiveness improving agent is preferably 0.01 to 30 parts by mass, more preferably 0.1 to 10 parts by mass, and still more preferably 0.5 to 5 parts by mass with respect to 100 parts by mass of the specific resin. In a case where the content is set to be equal to or higher than the above lower limit value, good adhesiveness between a pattern and a metal layer is exhibited, and in a case where the content is set to be equal to or lower than the above upper limit value, good heat resistance of the pattern and good mechanical properties are exhibited. Only one kind of metal adhesiveness improving agent may be used, or two or more kinds thereof may be used. In a case where two or more kinds thereof are used, the total content thereof is preferably within the above-described range.

### <Migration Suppressing Agent>

The resin composition according to the embodiment of the present invention preferably further contains a migration suppressing agent. For example, in a case where the resin composition is applied to a metal layer (or a metal wire) to form a film, it is possible to effectively suppress the migration of metal ions derived from the metal layer (or the metal wire) into the film, in a case where a migration suppressing agent is contained.

The migration suppressing agent is not particularly limited; however, examples thereof include a compound having a heterocyclic ring (a pyrrole ring, a furan ring, a thiophene ring, an imidazole ring, an oxazole ring, a thiazole ring, a pyrazole ring, an isoxazole ring, an isothiazole ring, a tetrazole ring, a pyridine ring, a pyridazine ring, a pyrimidine ring, a pyrazine ring, a piperidine ring, a piperazine ring, a morpholine ring, a 2H-pyran ring and a 6H-pyran ring, or a triazine ring), a compound having thioureas and compounds having a sulfanyl group, a hindered phenol-based compound, a salicylic acid derivative-based compound, and a hydrazide derivative-based compound. In particular, it is possible to preferably use a triazole-based compound such as 1,2,4-triazole, benzotriazole, 3-amino-1,2,4-triazole, or 3,5-diamino-1,2,4-triazole, or a tetrazole-based compound such as 1H-tetrazole, 5-phenyltetrazole or 5-amino-1H-tetrazole.

As the migration suppressing agent, an ion trap agent that captures an anion such as a halide ion can also be used.

The rust inhibitors described in paragraph 0094 of JP2013-015701A, the compounds described in paragraphs 0073 to 0076 of JP2009-283711A, the compounds described in paragraph 0052 of JP2011-059656A, the compounds described in paragraphs 0114, 0116, and 0118 of JP2012-194520A, the compounds described in paragraph 0166 of WO2015/199219A, or the like can be used as the other migration suppressing agents, the contents of which are incorporated in the present specification.

Specific examples of the migration suppressing agent include the following compounds.

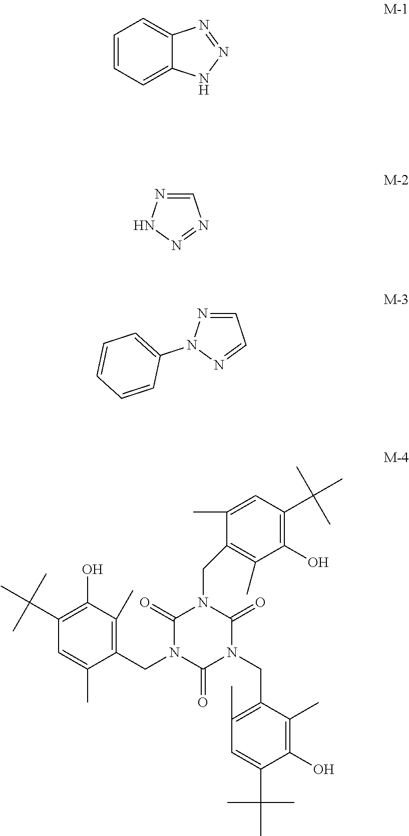 [SMILES: c1ccc2[nH]nnc2c1 ; c1nn[nH]n1 ; c1ccc(-n2nccn2)cc1 ; Cc1cc(C(C)(C)C)c(O)c(C)c1Cn1c(=O)n(Cc2c(C)cc(C(C)(C)C)c(O)c2C)c(=O)n(Cc2c(C)cc(C(C)(C)C)c(O)c2C)c1=O]

In a case where the resin composition according to the embodiment of the present invention contains the migration suppressing agent, the content of the migration suppressing agent is preferably 0.01% to 5.0% by mass, more preferably 0.05% to 2.0% by mass, and still more preferably 0.1% to 1.0% by mass, with respect to the total solid content of the resin composition.

One kind of migration suppressing agent may be used alone, or two or more kinds thereof may be used. In a case where two or more kinds of migration suppressing agents are used, the total thereof is preferably within the above-described range.

### <Light Absorbing Agent>

The resin composition according to the embodiment of the present invention also preferably contains a compound (a light absorbing agent) whose absorbance at the exposure wavelength decreases upon exposure.

Examples of the light absorbing agent include compounds described in paragraphs 0159 to 0183 of WO2022/202647A and compounds described in paragraphs 0088 to 0108 of JP2019-206689A. The contents of which are incorporated in the present specification.

### <Polymerization Inhibitor>

The resin composition according to the embodiment of the present invention preferably contains a polymerization inhibitor. Examples of the polymerization inhibitor include a phenol-based compound, a quinone-based compound, an amino-based compound, an N-oxyl-free radical-based compound, a nitro-based compound, a nitroso-based compound, a heteroaromatic ring-based compound, and a metal compound.

Specific examples of the polymerization inhibitor include the compounds described in paragraph 0310 of WO2021/112189A, p-hydroquinone, o-hydroquinone, a 4-hydroxy-2,2,6,6-tetramethylpiperidine-1-oxyl free radical, phenoxazine, and 1,4,4-trimethyl-2,3-diazabicyclo[3.2.2]nona-2-en-N,N-dioxide. The contents thereof are incorporated into the present specification.

In a case where the resin composition according to the embodiment of the present invention has a polymerization inhibitor, the content of the polymerization inhibitor is preferably 0.01% to 20% by mass, more preferably 0.02% to 15% by mass, and still more preferably 0.05% to 10% by mass, with respect to the total solid content of the resin composition.

One kind of polymerization inhibitor may be used, or two or more kinds thereof may be used. In a case where two or more kinds of polymerization inhibitors are used, the total thereof is preferably within the above-described range.

### <Other Additives>

The resin composition according to the embodiment of the present invention may contain various additives as necessary, for example, a surfactant, a higher fatty acid derivative, a thermal polymerization initiator, inorganic particles, an ultraviolet absorber, an organic titanium compound, an antioxidant, a photoacid generator, an aggregation inhibitor, a phenol-based compound, another polymer compound, a plasticizer, and other auxiliary agents (for example, a defoamer, and a flame retardant) within the scope in which the effect of the present invention is obtained. By appropriately containing these components, properties such as film properties can be adjusted. The details of the components can be found in, for example, paragraph “0183” and subsequent paragraphs of JP2012-003225A (corresponding to paragraph 0237 of US2013/0034812A) and paragraphs 0101 to 0104 and 0107 to 0109 of JP2008-250074A, the contents of which are incorporated in the present specification. In a case where these additives are blended, the total content thereof is preferably 3% by mass or less of the solid content of the resin composition according to the embodiment of the present invention.

### (Surfactant)

As the surfactant, various surfactants such as a fluorine-based surfactant, a silicone-based surfactant, and a hydrocarbon-based surfactant can be used. The surfactant may be a nonionic surfactant, a cationic surfactant, or an anionic surfactant.

In a case where a surfactant is contained in the resin composition according to the embodiment of the present invention, the liquid characteristics (particularly, the fluidity) in a case where a coating liquid composition is prepared are further improved, and thus the uniformity of the coating thickness and the liquid saving property can be further improved.

That is, in a case where a film is formed using a coating liquid containing a surfactant, the interfacial tension between a surface to be coated and a coating liquid is reduced, the wettability to the surface to be coated is improved, and thus the coatability to the surface to be coated is improved. Therefore, it is possible to more suitably form a uniform film having a small thickness unevenness.

Examples of the fluorine-based surfactant include the compounds described in paragraph 0328 of WO2021/112189A, the contents of which are incorporated in the present specification.

As the fluorine-based surfactant, a fluorine-containing polymer compound containing a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used, and examples thereof include the following compounds.

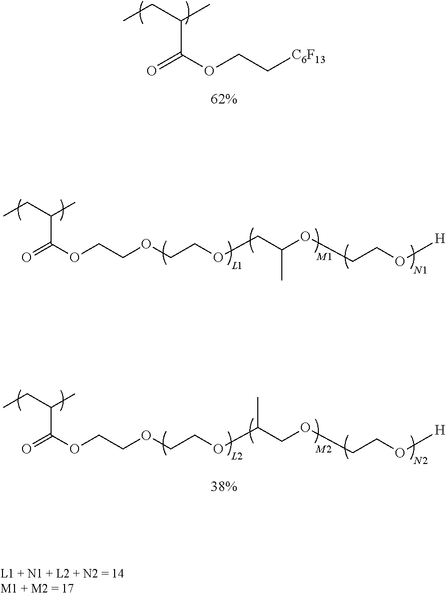

The weight-average molecular weight of the above-described compound is preferably 3,000 to 50,000 and more preferably 5,000 to 30,000.

Regarding the fluorine-based surfactant, a fluorine-containing polymer having an ethylenically unsaturated group in the side chain can also be used as the fluorine-based surfactant. Specific examples thereof include the compounds described in paragraphs “0050” to “0090” and “0289” to “0295” of JP2010-164965A, the content of which is incorporated in the present specification. Further, examples of the commercially available products thereof include MEGAFACE RS-101, RS-102, and RS-718K, all manufactured by DIC Corporation.

The content of fluorine in the fluorine-based surfactant is preferably 3% to 40% by mass, more preferably 5% to 30% by mass, and particularly preferably 7% to 25% by mass. The fluorine-based surfactant in which the fluorine content is in the above-described range is effective from the viewpoints of the uniformity in the thickness of the coating film and liquid saving properties, and the solubility thereof in the composition is also excellent.

Examples of the silicone-based surfactant, the hydrocarbon-based surfactant, the nonionic surfactant, the cationic surfactant, and the anionic surfactant include the compounds described in paragraphs 0329 to 0334 of WO2021/112189A, the contents of which are incorporated in the present specification.

The surfactant may be used alone or in combination with two or more kinds thereof.

The content of the surfactant is preferably 0.001% to 2.0% by mass and more preferably 0.005% to 1.0% by mass with respect to the total solid content of the composition.

### [Inorganic Particle]

Specific examples of the inorganic particle include calcium carbonate, calcium phosphate, silica, kaolin, talc, titanium dioxide, alumina, barium sulfate, calcium fluoride, lithium fluoride, zeolite, molybdenum sulfide, and glass.

The average particle size of the inorganic particles is preferably 0.01 to 2.0 μm, more preferably 0.02 to 1.5 μm, still more preferably 0.03 to 1.0 μm, and particularly preferably 0.04 to 0.5 μm.

The average particle diameter of the inorganic particles is the primary particle diameter and the volume average particle size. The volume average particle size can be measured by, for example, a dynamic light scattering method with Nanotrac WAVE II EX-150 (manufactured by Nikkiso Co., Ltd.).

In a case where the above measurement is difficult, the measurement can also be carried out by a centrifugal sedimentation light transmission method, an X-ray transmission method, or a laser diffraction/light scattering method.

### [Organic Titanium Compound]

In a case where the resin composition contains an organic titanium compound, it is possible to form a resin layer having excellent chemical resistance even in a case where curing is carried out at a low temperature.

Examples of the usable organic titanium compound include those in which an organic group is bonded to a titanium atom through a covalent bond or an ionic bond.

Specific examples of the organic titanium compound are described in I) to VII) below.

I) Titanium chelate compounds: a titanium chelate compound having two or more alkoxy groups is more preferable since the resin composition has good storage stability and a good curing pattern is obtained. Specific examples thereof include titanium bis(triethanolamine)diisopropoxide, titanium di(n-butoxide) bis(2,4-pentanedionate), titanium diisopropoxide bis(2,4-pentanedionate), titanium diisopropoxide bis(tetramethylheptandionate), and titanium diisopropoxide bis(ethyl acetoacetate).

II) Tetraalkoxytitanium compounds: examples thereof include titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, and titanium tetrakis[bis{2,2-(aryloxymethyl)butoxide}].

III) Titanocene compounds: examples thereof include pentamethylcyclopentadienyl titanium trimethoxide, bis(η5-2,4-cyclopentadien-1-yl)bis(2,6-difluorophenyl)titanium, and bis(η5-2,4-cyclopentadien-1-yl)bis(2,6-difluoro-3-(1H-pyrrol-1-yl)phenyl)titanium.

IV) Monoalkoxytitanium compounds: examples thereof include titanium tris(dioctyl phosphate)isopropoxide, and titanium tris(dodecylbenzene sulfonate)isopropoxide.

V) Titanium oxide compounds: examples thereof include titanium oxide bis(pentanedionate), titanium oxide bis(tetramethylheptandionate), and phthalocyanine titanium oxide.

VI) Titanium tetraacetylacetonate compounds: examples thereof include titanium tetraacetylacetoneate.

VII) Titanate coupling agents: examples thereof include isopropyltridodecylbenzenesulfonyl titanate.

Among these, it is preferable that the organic titanium compound is at least one compound selected from the group consisting of the above-described I) titanium chelate compound, II) tetraalkoxytitanium compound, and III) titanocene compound, from the viewpoint of more favorable chemical resistance. In particular, titanium diisopropoxide bis(ethyl acetoacetate), titanium tetra(n-butoxide), and bis(η5-2,4-cyclopentadiene-1-yl) bis(2,6-difluoro-3-(1H-pyrrole-1-yl)phenyl)titanium are preferable.

In addition, it is also preferable that a compound represented by Formula (T-1) is contained as the organic titanium compound or instead of the organic titanium compound.

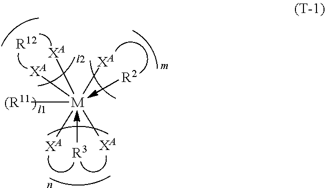

In Formula (T-1), M is titanium, zirconium, or hafnium, l1 is an integer of 0 to 2, l2 is 0 or 1, l1+l2×2 is an integer of 0 to 2, m is an integer of 0 to 4, n is an integer of 0 to 2, l1+l2+m+n×2=4 is satisfied, R¹¹'s are each independently a substituted or unsubstituted cyclopentadienyl group, a substituted or unsubstituted alkoxy group, or a substituted or unsubstituted phenoxy group, R¹² is a substituted or unsubstituted hydrocarbon group, R²'s are each independently a group including a structure represented by Formula (T-2), R³'s are each independently a group including a structure represented by Formula (T-2), and X^{A}'s are each independently an oxygen atom or a sulfur atom.

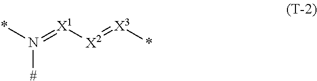

In Formula (T-2), X¹ to X³ each independently represent —C(—*)= or —N═, *'s each represent a bonding site to another structure, and #represents a bonding site to a metal atom.

In Formula (T-1), it is preferable that M represents titanium from the viewpoint of the storage stability of the composition.

An aspect in which l1 and l2 in Formula (T-1) are 0 is also one of the preferred aspects of the present invention.

In Formula (T-1), m is preferably 2 or 4, and more preferably 2.

In Formula (T-1), n is preferably 1 or 2, and more preferably 1.

Here, in Formula (T-1), it is also preferable that 11 and 12 are 0 and m is 0, 2, or 4.

In Formula (T-1), R¹¹ is preferably a substituted or unsubstituted cyclopentadienyl ligand from the viewpoint of the stability of the specific metal complex.

In addition, the cyclopentadienyl group, the alkoxy group, and the phenoxy group as R¹¹ may be substituted; however, an aspect in which these are unsubstituted is also one of the preferred aspects of the present invention.

In Formula (T-1), R¹² is preferably a hydrocarbon group having 1 to 20 carbon atoms and more preferably a hydrocarbon group having 2 to 10 carbon atoms.

The hydrocarbon group as R¹² may be any of an aliphatic hydrocarbon group or an aromatic hydrocarbon group; however, it is preferably an aromatic hydrocarbon group.

The aliphatic hydrocarbon group may be a saturated aliphatic hydrocarbon group or an unsaturated aliphatic hydrocarbon group; however, it is preferably a saturated aliphatic hydrocarbon group.

The aromatic hydrocarbon group is preferably an aromatic hydrocarbon group having 6 to 20 carbon atoms, more preferably an aromatic hydrocarbon group having 6 to 10 carbon atoms, and still more preferably a phenylene group.

The substituent as R¹² is preferably a monovalent substituent, and examples thereof include a halogen atom. In addition, in a case where R¹² is an aromatic hydrocarbon group, it may have an alkyl group as a substituent.

Among these, in Formula (T-1), R¹² is preferably an unsubstituted phenylene group.

In addition, the phenylene group as R¹² is preferably a 1,2-phenylene group.

In Formula (T-1), in a case where m is 2 or more and two or more R²'s are contained, the structures of the two or more R²'s may be the same or different from each other.

In Formula (T-1), in a case where n is 2 or more and two or more R³'s are contained, the structures of the two or more R³'s may be the same or different from each other.

In Formula (T-2), X¹ to X³ each independently represent —C(—*)= or —N═. It is preferable that at least one thereof represents —C(—*)=, and it is more preferable that at least two thereof represent —C(—*)=.

Specific examples of the compound represented by Formula (T-1) include compounds corresponding to I-5 to I-8 in Examples, but the present invention is not limited thereto.

In a case of containing an organic titanium compound, the content thereof is preferably 0.05 to 10 parts by mass and more preferably 0.1 to 5 parts by mass with respect to 100 parts by mass of the specific resin. In a case where the content thereof is 0.05 parts by mass or more, the heat resistance and the chemical resistance of the cured pattern to be obtained are further improved, and in a case where the content thereof is 10 parts by mass or less, the storage stability of the composition is more excellent.

In a case of containing an organic titanium compound, the content thereof is preferably 0.05 to 10 parts by mass and more preferably 0.1 to 2 parts by mass with respect to 100 parts by mass of the specific resin. In a case where the content thereof is 0.05 parts by mass or more, the heat resistance and the chemical resistance of the cured pattern to be obtained are further improved, and in a case where the content thereof is 10 parts by mass or less, the storage stability of the composition is more excellent.

Examples of the other additives include the compounds described in paragraphs 0249 to 0282 and 0316 to 0358 of WO2022/145355A. The above description is incorporated in the present specification.

### <Characteristics of Resin Composition>

The viscosity of the resin composition according to the embodiment of the present invention can be adjusted by the concentration of solid contents of the resin composition. From the viewpoint of the coating film thickness, the viscosity is preferably 1,000 mm²/s to 12,000 mm²/s, more preferably 2,000 mm²/s to 10,000 mm²/s, and still more preferably 2,500 mm²/s to 8,000 mm²/s. Within the above range, it is easy to obtain a coating film having high uniformity.

In a case of being 1,000 mm²/s or more, it is easy to carry out coating at a film thickness to be required as, for example, an insulating film for re-distribution of a wiring line, and in a case of being 12,000 mm²/s or less, a coating film having an excellent coating surface shape is obtained.

### <Restrictions on Substances Contained in Resin Composition>

The moisture content of the resin composition according to the embodiment of the present invention is preferably less than 2.0% by mass, more preferably less than 1.5% by mass, and still more preferably less than 1.0% by mass. In a case where the moisture content is less than 2.0%, the storage stability of the resin composition is improved.

Examples of the method of maintaining the moisture content include adjusting the humidity under storage conditions and reducing the void ratio of the storage container during storage.

From the viewpoint of insulating properties, the metal content of the resin composition according to the embodiment of the present invention is preferably less than 5 parts per million (ppm) by mass, more preferably less than 1 ppm by mass, and still more preferably less than 0.5 ppm by mass. Examples of the metal include sodium, potassium, magnesium, calcium, iron, copper, chromium, and nickel, however, a metal contained as a complex of an organic compound and a metal is excluded. In a case where a plurality of metals are contained, the total of these metals is preferably within the above-described range.

In addition, as a method of reducing metal impurities which are unintentionally contained in the resin composition according to the embodiment of the present invention, a method of selecting a raw material containing a low metal content as the raw material that constitutes the resin composition according to the embodiment of the present invention, a method of filtering a raw material constituting the resin composition according to the embodiment of the present invention, a method of distilling under the conditions in which the inside of the device is lined with polytetrafluoroethylene or the like to suppress the contamination as little as possible, and the like can be mentioned.

In the resin composition according to the embodiment of the present invention, in a case of considering the use application as a semiconductor material, the content of halogen atoms is preferably less than 500 ppm by mass, more preferably less than 300 ppm by mass, and still more preferably less than 200 ppm by mass, from the viewpoint of wiring corrosiveness.

Among these, in a case where halogen ions are present, the content is preferably less than 5 ppm by mass, more preferably less than 1 ppm by mass, and still more preferably less than 0.5 ppm by mass. Examples of the halogen atom include a chlorine atom and a bromine atom. It is preferable that the total content of the chlorine atom and the bromine atom, or the total content of the chlorine ion and the bromine ion is within the above-described range.

Preferred examples of the method of adjusting the content of halogen atoms include ion exchange treatment.

A storage container publicly known in the related art can be used as a storage container for the resin composition according to the embodiment of the present invention. As the storage container, for the intended purpose of suppressing the incorporation of impurities into the raw materials and the resin composition according to the embodiment of the present invention, a multilayer bottle in which an inner wall of a container is composed of six kinds of six layers of resin, and a bottle with six kinds of resin being made as a seven-layer structure are preferably used. Examples of such a container include containers described in JP2015-123351A.

### <Cured Product of Resin Composition>

In a case of curing the resin composition according to the embodiment of the present invention, it is possible to obtain a cured product of the resin composition.

The cured product according to the embodiment of the present invention is a cured product formed by curing the resin composition.

The curing of the resin composition is preferably carried out by heating. The heating temperature is more preferably 120° C. to 400° C., still more preferably 140° C. to 380° C., and particularly preferably 170° C. to 350° C. The form of the cured product of the resin composition is not particularly limited and can be selected depending on the use application, where the form includes a film shape, a rod shape, a spherical shape, a pellet shape, and the like.

In the present invention, the cured product preferably has a film shape. The shape of the cured product can also be selected depending on the use application by the pattern processing of the resin composition, where the use application includes the formation of a protective film on a wall surface, formation of via holes for conduction, adjustment of impedance, electrostatic capacity, or internal stress, impartment of heat radiation function, and the like. The film thickness of the cured product (the film consisting of the cured product) is preferably 0.5 μm or more and 150 μm or less.

The shrinkage ratio of the resin composition according to the embodiment of the present invention after curing is preferably 50% or less, more preferably 45% or less, and still more preferably 40% or less. Here, the shrinkage ratio refers to a percentage of a change in the volume of the resin composition before and after curing, and it can be calculated according to the following expression.

$$Shrinkage ratio [ \% ] = 100 - ( volume after curing / volume before curing ) \times 100$$

### <Characteristics of Cured Product of Resin Composition>

The imidization reaction rate of the cured product of the resin composition according to the embodiment of the present invention is preferably 70% or more, more preferably 80% or more, and still more preferably 90% or more. In a case where the imidization reaction rate is 70% or more, a cured product having excellent mechanical properties may be obtained.

The breaking elongation of the cured product of the resin composition according to the embodiment of the present invention is preferably 30% or more, more preferably 40% or more, and still more preferably 50% or more.

The glass transition temperature (Tg) of the cured product of the resin composition according to the embodiment of the present invention is preferably 180° C. or higher, more preferably 210° C. or higher, and still more preferably 230° C. or higher.

### <Preparation of Resin Composition>

The resin composition according to the embodiment of the present invention can be prepared by mixing the above-described components. The mixing method is not particularly limited, and mixing can be carried out by methods publicly known in the related art.

Examples of the mixing method include mixing with a stirring blade, mixing with a ball mill, and mixing by rotating a tank.

The temperature during the mixing is preferably 10° C. to 30° C., and more preferably 15° C. to 25° C.

It is preferable to carry out filtration using a filter for the intended purpose of removing foreign substances such as dust and fine particles in the resin composition according to the embodiment of the present invention. The filter pore diameter is, for example, preferably 5 μm or less, more preferably 1 μm or less, still more preferably 0.5 μm or less, and even still more preferably 0.1 μm or less. The material of the filter is preferably polytetrafluoroethylene, polyethylene, or nylon. In a case where the material of the filter is polyethylene, it is more preferable to use high-density polyethylene (HDPE). As the filter, a filter which has been washed with an organic solvent in advance may be used. In the filtration step using the filter, a plurality of kinds of filters may be connected in series or in parallel and used. In a case where a plurality of kinds of filters are used, filters having different pore diameters or different materials may be used in combination. Examples of the connection aspect include an aspect in which an HDPE filter having a pore diameter of 1 μm is connected in series as the first stage and an HDPE filter having a pore diameter of 0.2 μm is connected in series as the second stage.

In addition, various materials may be filtered a plurality of times. In a case of being filtered a plurality of times, circulation filtration may be used. In addition, filtration may be carried out under pressure. In a case where filtration is performed under pressure, the pressure for pressurization is, for example, preferably 0.01 MPa or more and 1.0 MPa or less, more preferably 0.03 MPa or more and 0.9 MPa or less, still more preferably 0.05 MPa or more and 0.7 MPa or less, and even still more preferably 0.05 MPa or more and 0.5 MPa or less.

In addition to filtration using a filter, impurity removal treatment using an adsorbing material may be carried out. The filtration using a filter and the impurity removal treatment using an adsorbing material may be combined. As the adsorbing material, a publicly known adsorbing material can be used. Examples thereof include an inorganic adsorbing material such as silica gel and zeolite and an organic adsorbing material such as activated carbon.

After filtration using a filter, a step of placing a bottle filled with the resin composition under reduced pressure to carry out degassing may be provided.

### (Method for Producing Cured Product)

The method for producing a cured product according to the embodiment of the present invention preferably includes a film forming step of applying a resin composition onto a base material to form a film.

The method for producing a cured product more preferably includes the above-described film forming step, an exposure step of selectively exposing the film formed by the film forming step, and a development step of developing the film exposed by the exposure step using a developer to form a pattern.

It is particularly preferable that the method for producing a cured product includes the film forming step, the exposure step, the development step, and at least one of a heating step of heating a pattern obtained by the development step or a post-development exposure step of exposing the pattern obtained by the development step.

In addition, it is also preferable that the method for producing a cured product includes the above-described film forming step and a step of heating the film.

Hereinafter, details of each step will be described.

### <Film Forming Step>

The resin composition according to the embodiment of the present invention can be applied onto a base material, thereby being used in a film forming step of forming a film.

The method for producing a cured product according to the embodiment of the present invention preferably includes a film forming step of applying a resin composition onto a base material to form a film.

### [Substrate]

The kind of the base material can be appropriately determined depending on the use application and is not particularly limited. Examples of the base material include a base material for semiconductor production, such as silicon, silicon nitride, polysilicon, silicon oxide, or amorphous silicon, quartz, glass, an optical film, a ceramic material, a vapor-deposited film, a magnetic film, a reflective film, a metal base material (for example, it may be any one of a base material formed from a metal or a base material having a metal layer formed by plating, vapor deposition, or the like) such as Ni, Cu, Cr, or Fe, paper, spin-on-glass (SOG), a thin film transistor (TFT) array base material, a mold base material, and an electrode plate of a plasma display panel (PDP). In particular, the base material is preferably a base material for semiconductor production, and more preferably a silicon base material, a Cu base material, or a mold base material.

A layer such as an adhesion layer formed using hexamethyl disilazane (HMDS) or the like, or an oxide layer may be provided on the surface of these base materials.

The shape of the base material is not particularly limited, and it may be a circular shape or may be a rectangular shape.

In a case where the base material has a circular shape, the size of the base material is, for example, preferably a diameter of 100 to 450 mm and more preferably 200 to 450 mm. In a case of a rectangular shape, the length of the short side is, for example, preferably 100 to 1,000 mm and more preferably 200 to 700 mm.

As the base material, for example, a base material having a plate shape and preferably a base material (a substrate) having a panel shape are used.

In a case where the resin composition is applied to form a film on a surface of a resin layer (for example, a layer consisting of a cured product) or on a surface of a metal layer, the resin layer or the metal layer serves as the base material.

The means for applying the resin composition onto a base material is preferably coating.

Specific examples of the means for application include a dip coating method, an air knife coating method, a curtain coating method, a wire bar coating method, a gravure coating method, an extrusion coating method, a spray coating method, a spin coating method, a slit coating method, and an inkjet method. From the viewpoint of the uniformity of the film thickness, a spin coating method, a slit coating method, a spray coating method, or an inkjet method is preferable, and from the viewpoint of the uniformity of the film thickness and the viewpoint of productivity, a spin coating method or a slit coating method is more preferable.

A film having a desired thickness can be obtained by adjusting the concentration of solid contents of the resin composition and application conditions according to the means to be applied. In addition, the coating method can be appropriately selected depending on the shape of the base material. In a case where a circular base material such as a wafer is used, a spin coating method, a spray coating method, an inkjet method, or the like is preferable, and in a case where a rectangular base material is used, a slit coating method, a spray coating method, an inkjet method, or the like is preferable. For example, the spin coating method can be applied at a rotation speed of 500 to 3,500 rpm for about 10 seconds to 3 minutes.

In addition, it is also possible to apply a method of transferring a coating film formed in advance on a temporary support by the above-described coating method, onto a base material.

Regarding the transfer method, the production methods described in paragraphs 0023 and 0036 to 0051 of JP2006-023696A and paragraphs 0096 to 0108 of JP2006-047592A can also be suitably used.

In addition, a step of removing an unnecessary film at the end part of the base material may be carried out. Examples of such a step include edge bead rinsing (EBR) and back rinsing.

A pre-wetting step of applying various solvents onto the base material before applying the resin composition onto the base material to improve the wettability of the base material and then applying the resin composition may be adopted.

### <Drying Step>

The above film may be subjected to a step (a drying step) of drying the film (or the layer) to remove the solvent, after the film forming step (the layer forming step).

That is, the method for producing a cured product according to the embodiment of the present invention may include a drying step of drying the film formed by the film forming step.

It is preferable that the drying step is carried out after the film forming step and before the exposure step.

The drying temperature of the film in the drying step is preferably 50° C. to 150° C., more preferably 70° C. to 130° C., and still more preferably 90° C. to 110° C. In addition, the drying may be carried out by reducing the pressure. Examples of the drying time include 30 seconds to 20 minutes, and the drying time is preferably 1 minute to 10 minutes and more preferably 2 minutes to 7 minutes.

### <Exposure Step>

The film may be subjected to an exposure step of selectively exposing the film.

The method for producing a cured product may include an exposure step of selectively exposing the film formed by the film forming step.

The selective exposure means that a part of the film is exposed. In addition, by selectively exposing the film, an exposed region (an exposed portion) and an unexposed region (a non-exposed portion) are formed in the film.

The exposure amount is not particularly limited as long as the resin composition according to the embodiment of the present invention can be cured; however, it is, for example, preferably 50 to 10,000 mJ/cm² and more preferably 200 to 8,000 mJ/cm² in terms of conversion of exposure energy at a wavelength of 365 nm.

The exposure wavelength can be appropriately determined in a range of 190 to 1,000 nm and preferably in a range of 240 to 550 nm.

Examples of the exposure wavelength, which are mentioned in the relationship with the light source, include (1) a semiconductor laser (wavelength: 830 nm, 532 nm, 488 nm, 405 nm, 375 nm, 355 nm, or the like); (2) a metal halide lamp; (3) a high pressure mercury lamp, a g-line (wavelength: 436 nm), an h-line (wavelength: 405 nm), an i-line (wavelength: 365 nm), or Broad (three wavelengths of the g, h, and i-line); (4) an excimer laser, a KrF excimer laser (wavelength: 248 nm), an ArF excimer laser (wavelength: 193 nm), or an F₂ excimer laser (wavelength: 157 nm); (5) an extreme ultraviolet ray: EUV (wavelength: 13.6 nm); (6) an electron beam; and (7) a second harmonic wave of 532 nm and a third harmonic wave of 355 nm of a YAG laser. Regarding the resin composition according to the embodiment of the present invention, exposure with a high pressure mercury lamp is particularly preferable, and from the viewpoint of exposure sensitivity, exposure with an i-line is more preferable.

The exposure method is not particularly limited as long as at least a part of the film consisting of the resin composition according to the embodiment of the present invention is exposed; however, examples thereof include exposure using a photo mask and exposure by a laser direct imaging method.

### <Post-Exposure Heating Step>

The film may be subjected to a step of carrying out heating after the exposure (a post-exposure heating step).

That is, the method for producing a cured product according to the embodiment of the present invention may include a post-exposure heating step of heating the film exposed in the exposure step.

The post-exposure heating step can be carried out after the exposure step and before the development step.

The heating temperature in the post-exposure heating step is preferably 50° C. to 140° C. and more preferably 60° C. to 120° C.

The heating time in the post-exposure heating step is preferably 30 seconds to 300 minutes and more preferably 1 minute to 10 minutes.

In the post-exposure heating step, the temperature rising rate from the temperature at the start of heating to the maximum heating temperature is preferably 1 to 12° C./min, more preferably 2 to 10° C./min, and still more preferably 3 to 10° C./min.

In addition, the temperature rising rate may be appropriately changed during heating.

The heating means in the post-exposure heating step is not particularly limited, and a publicly known hot plate, oven, infrared heater, or the like can be used.

In addition, it is also preferable to carry out the heating in an atmosphere having a low oxygen concentration by allowing an inert gas such as nitrogen, helium, argon, or the like to flow.

### <Developing Step>

The exposed film may be subjected to a development step of carrying out development using a developer to form a pattern.

That is, the method for producing a cured product according to the embodiment of the present invention may include a development step of developing the film exposed in the exposure step using a developer to form a pattern.

By carrying out the development, one of the exposed portion and the non-exposed portion of the film is removed, and a pattern is formed.

Here, the development in which the non-exposed portion of the film is removed by the development step is referred to as negative tone development, and the development in which the exposed portion of the film is removed by the development step is referred to as positive tone development.

### [Developer]

Examples of the developer that is used in the development step include an alkaline aqueous solution or a developer containing an organic solvent.

In a case where the developer is an alkaline aqueous solution, examples of the basic compound that can be contained in the alkaline aqueous solution include inorganic alkalis, primary amines, secondary amines, tertiary amines, and a quaternary ammonium salt. The basic compound is preferably tetramethylammonium hydroxide (TMAH), potassium hydroxide, sodium carbonate, sodium hydroxide, sodium silicate, sodium metasilicate, ammonia, ethylamine, n-propylamine, diethylamine, di-n-butylamine, triethylamine, methyldiethylamine, dimethylethanolamine, triethanolamine, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, dibutyldipentylammonium hydroxide, dimethylbis(2-hydroxyethyl)ammonium hydroxide, trimethylphenylammonium hydroxide, trimethylbenzylammonium hydroxide, triethylbenzylammonium hydroxide, pyrrole, or piperidine, and it is more preferably TMAH. The content of the basic compound in the developer is preferably 0.01% to 10% by mass, more preferably 0.1% to 5% by mass, and still more preferably 0.3% to 3% by mass in the total mass of the developer.

In a case where the developer contains an organic solvent, the compounds described in paragraph 0387 of WO2021/112189A can be used as the organic solvent. The contents thereof are incorporated into the present specification. In addition, suitable examples of the alcohols include methanol, ethanol, propanol, isopropanol, butanol, pentanol, octanol, diethylene glycol, propylene glycol, methyl isobutyl carbinol, and triethylene glycol, and suitable examples of the amides include N-methylpyrrolidone, N-ethylpyrrolidone, and dimethylformamide.

In a case where the developer contains an organic solvent, one kind of organic solvent can be used, or two or more kinds thereof can be used as a mixture. In the present invention, in particular, a developer containing at least one selected from the group consisting of cyclopentanone, 7-butyrolactone, dimethyl sulfoxide, N-methyl-2-pyrrolidone, and cyclohexanone is preferable, a developer containing at least one selected from the group consisting of cyclopentanone, 7-butyrolactone, and dimethyl sulfoxide is more preferable, and a developer containing cyclopentanone is particularly preferable.

In a case where the developer contains an organic solvent, the content of the organic solvent with respect to the total mass of the developer is preferably 50% by mass or more, more preferably 70% by mass or more, still more preferably 80% by mass or more, and particularly preferably 90% by mass or more. In addition, the above content may be 100% by mass.

The developer may further contain another component.

Examples of the other component include a known surfactant and a known defoamer.

### [Supply Method for Developer]

The method of supplying a developer is not particularly limited as long as a desired pattern can be formed, and it includes a method of immersing a base material on which a film has been formed in a developer, puddle development in which a developer is supplied to a film formed on a base material using a nozzle, and a method of continuously supplying a developer. The kind of nozzle is not particularly limited, and examples thereof include a straight nozzle, a shower nozzle, and a spray nozzle.

From the viewpoint of the permeability of the developer, the removability of the non-image area, and the manufacturing efficiency, a method of supplying a developer with a straight nozzle or a method of continuously supplying a developer with a spray nozzle is preferable, and from the viewpoint of the permeability of the developer into the image area, a method of supplying a developer with a spray nozzle is more preferable.

In addition, after the continuous supply by a straight nozzle, the base material is spun to remove the developer from the base material, and then the developer is continuously supplied by the straight nozzle again after the spin drying, a step of spinning the base material to remove the developer from the base material may be adopted, and this step may be repeated a plurality of times.

Examples of the method of supplying a developer in the development step include a step of continuously supplying a developer to a base material, a step of keeping a developer in a substantially stationary state on a base material, a step of vibrating a developer on a base material by ultrasonic waves or the like, and a step obtained by combining these steps.

The development time is preferably 10 seconds to 10 minutes and more preferably 20 seconds to 5 minutes. The temperature of the developer during development is not particularly limited; however, it is preferably 10° C. to 45° C. and more preferably 18° C. to 30° C.

In the development step, washing (rinsing) of the pattern with a rinsing liquid may be further carried out after the treatment with the developer. In addition, a method such as supplying a rinsing liquid before the developer which is in contact with the pattern is completely dried may be adopted.

### [Rinsing Liquid]

In a case where the developer is an alkaline aqueous solution, it is possible to use, for example, water as the rinsing liquid. In a case where the developer is a developer containing an organic solvent, it is possible to use as the rinsing liquid, for example, a solvent (for example, water, an organic solvent different from the organic solvent contained in the developer) different from the solvent contained in the developer.

Examples of the organic solvent in a case where the rinsing liquid contains an organic solvent include the same organic solvents as the organic solvents exemplified in the above-described case where the developer contains an organic solvent.

The organic solvent contained in the rinsing liquid is preferably an organic solvent different from the organic solvent contained in the developer, and it is more preferably an organic solvent having a solubility of the pattern, which is lower than that of the organic solvent contained in the developer.

In a case where the rinsing liquid contains an organic solvent, one kind of organic solvent can be used, or two or more kinds thereof can be used as a mixture. The organic solvent is preferably cyclopentanone, γ-butyrolactone, dimethyl sulfoxide, N-methylpyrrolidone, cyclohexanone, PGMEA, or PGME, more preferably cyclopentanone, γ-butyrolactone, dimethyl sulfoxide, PGMEA, or PGME, and still more preferably cyclohexanone and PGMEA.

In a case where the rinsing liquid contains an organic solvent, the organic solvent is preferably 50% by mass or more, more preferably 70% by mass or more, and still more preferably 90% by mass or more with respect to the total mass of the rinsing liquid. In addition, the organic solvent may be 100% by mass with respect to the total mass of the rinsing liquid.

The rinsing liquid may further contain another component.

Examples of the other component include a known surfactant and a known defoamer.

### [Method of Supplying Rinsing Liquid]

The method of supplying a rinsing liquid is not particularly limited as long as a desired pattern can be formed and includes a method of immersing a base material in a rinsing liquid, a method of supplying a rinsing liquid to a base material by liquid filling, a method of supplying a rinsing liquid to a base material with a shower, and a method of continuously supplying a rinsing liquid to a base material by means such as a straight nozzle.

From the viewpoint of the permeability of the rinsing liquid, the removability of non-image area, and the manufacturing efficiency, there is a method of supplying a rinsing liquid with a shower nozzle, a straight nozzle, a spray nozzle, or the like, and a method of continuously supplying a rinsing liquid with a spray nozzle is preferable. From the viewpoint of the permeability of the rinsing liquid into the image area, a method of supplying a rinsing liquid with a spray nozzle is more preferable. The kind of nozzle is not particularly limited, and examples thereof include a straight nozzle, a shower nozzle, and a spray nozzle.

That is, the rinsing step is preferably a step of supplying the rinsing liquid to the film after the exposure using a straight nozzle, or continuously supplying the rinsing liquid, and it is more preferably a step of supplying the rinsing liquid using a spray nozzle.

In the method of supplying a rinsing liquid in the rinsing step, a step of continuously supplying a rinsing liquid to a base material, a step of keeping a rinsing liquid in a substantially stationary state on a base material, a step of vibrating a rinsing liquid on the base material by ultrasonic waves or the like, and a step obtained by combining these steps can be adopted.

The rinsing time is preferably 10 seconds to 10 minutes and more preferably 20 seconds to 5 minutes. The temperature of the rinsing liquid during rinsing is not particularly limited; however, it is preferably 10° C. to 45° C. and more preferably 18° C. to 30° C.

### <Heating Step>

The pattern obtained by the development step (a pattern after the rinsing in a case where the rinsing step is carried out) may be subjected to a heating step of heating the pattern obtained by the development.

That is, the method for producing a cured product according to the embodiment of the present invention may include a heating step of heating the pattern obtained by the development step.

In addition, the method for producing a cured product according to the embodiment of the present invention may include a heating step of heating a pattern obtained by another method without carrying out the development step, or a heating step of heating a film obtained by the film forming step.

In the heating step, the resin such as the polyimide precursor is cyclized to become a resin such as polyimide.

In addition, the crosslinking of unreacted crosslinkable groups in the specific resin or a crosslinking agent other than the specific resin also proceeds.

The heating temperature (the maximum heating temperature) in the heating step is preferably 50° C. to 450° C., more preferably 150° C. to 350° C., still more preferably 150° C. to 250° C., even still more preferably 160° C. to 250° C., and particularly preferably 160° C. to 230° C.

The heating step is preferably a step of accelerating the cyclization reaction of the polyimide precursor in the pattern under the action of the base or the like generated from the base generator by heating.

The heating in the heating step is preferably carried out at a temperature rising rate of 1 to 12° C./min from the temperature at the start of heating to the maximum heating temperature.

The temperature rising rate is more preferably 2 to 10° C./min and still more preferably 3 to 10° C./min. In a case where the above temperature rising rate is set to 1° C./min or higher, the excessive volatilization of the acid or solvent can be prevented while securing productivity, and in a case where the above temperature rising rate is set to 12° C./min or lower, the residual stress of the cured product can be relaxed.

In addition, in a case of an oven that enables rapid heating, the heating is preferably carried out at a temperature rising rate of 1 to 8° C./sec from the temperature at the start of heating to the maximum heating temperature, more preferably 2 to 7° C./sec, and still more preferably 3 to 6° C./sec.

The temperature at the start of heating is preferably 20° C. to 150° C., more preferably 20° C. to 130° C., and still more preferably 25° C. to 120° C. The temperature at the start of heating refers to a temperature at which the step of heating to the maximum heating temperature is started. For example, in a case where the resin composition according to the embodiment of the present invention is applied on a base material and then dried, the temperature at the start of heating is the temperature of the film (the layer) after drying, and for example, it is preferable to raise the temperature from a temperature lower by 30° C. to 200° C. than the boiling point of the solvent contained in the resin composition.

The heating time (the heating time at the maximum heating temperature) is preferably 5 to 360 minutes, more preferably 10 to 300 minutes, and still more preferably 15 to 240 minutes.

In particular, in a case of forming a multilayered laminate, the heating temperature is preferably 30° C. or higher, more preferably 80° C. or higher, still more preferably 100° C. or higher, and particularly preferably 120° C. or higher, from the viewpoint of adhesiveness between layers.

The upper limit of the heating temperature is preferably 350° C. or lower, more preferably 250° C. or lower, and still more preferably 240° C. or lower.

The heating may be carried out stepwise. For example, a step in which the temperature is raised from 25° C. to 120° C. at 3° C./min, held at 120° C. for 60 minutes, raised from 120° C. to 180° C. at 2° C./min, and held at 180° C. for 120 minutes, may be carried out. In addition, it is also preferable to carry out the treatment while irradiating with ultraviolet rays as described in U.S. Pat. No. 9,159,547B. By such a pretreatment step, it is possible to improve the properties of the film.

The pretreatment step may be carried out for a short time of about 10 seconds to 2 hours and more preferably 15 seconds to 30 minutes. The pretreatment step may be carried out as a step of two or more stages, for example, a first stage pretreatment step may be carried out in a range of 100° C. to 150° C., and then a second stage pretreatment step may be carried out in a range of 150° C. to 200° C.

Further, cooling may be carried out after heating, and the cooling rate, in this case, is preferably 1 to 5° C./min.

From the viewpoint of preventing the decomposition of the specific resin, it is preferable that the heating step is carried out in an atmosphere of a low oxygen concentration, for example, by allowing an inert gas such as nitrogen, helium, argon, or the like to flow, or carrying out heating under reduced pressure. The oxygen concentration is preferably 50 ppm (volume ratio) or lower, and more preferably 20 ppm (volume ratio) or lower.

The heating means in the heating step is not particularly limited; however, examples thereof include a hot plate, an infrared furnace, an electric heating oven, a hot air oven, and an infrared oven.

### <Post-Development Exposure Step>

The pattern obtained by the development step (a pattern after the rinsing in a case where the rinsing step is carried out) may be subjected to a post-development exposure step of exposing the pattern after the development step, instead of the heating step or in addition to the heating step.

That is, the method for producing a cured product according to the embodiment of the present invention may include a post-development exposure step of exposing the pattern obtained by the development step. The method for producing a cured product according to the embodiment of the present invention may include the heating step and the post-development exposure step or may include only one of the heating step and the post-development exposure step.

In the post-development exposure step, it is possible to accelerate, for example, a reaction in which the cyclization of a polyimide precursor or the like proceeds by photosensitization of a photobase generator, a reaction in which the elimination of an acid-decomposable group proceeds by photosensitization of a photoacid generator.

In the post-development exposure step, it is sufficient that at least a part of the pattern obtained in the development step is exposed; however, it is preferable that the whole of the above pattern is exposed.

The exposure amount in the post-development exposure step is preferably 50 to 20,000 mJ/cm² and more preferably 100 to 15,000 mJ/cm² in terms of conversion of exposure energy at the wavelength at which the photosensitive compound has a sensitivity.

The post-development exposure step can be carried out using, for example, the light source in the above-described exposure step, and it is preferable to use broadband light.

### <Metal Layer Forming Step>

The pattern (preferably a pattern that has been subjected to at least one of the heating step or the post-development exposure step) obtained by the development step may be subjected to a metal layer forming step of forming a metal layer on the pattern.

That is, it is preferable that the method for producing a cured product according to the embodiment of the present invention includes a metal layer forming step of forming a metal layer on the pattern (preferably a pattern that has been subjected to at least one of the heating step or the post-development exposure step) obtained by the development step.

For the metal layer, existing metal kinds can be used without particular limitations. Examples thereof include copper, aluminum, nickel, vanadium, titanium, chromium, cobalt, gold, tungsten, tin, silver, and an alloy including these metals, where copper and aluminum are more preferable, and copper is still more preferable.

The method of forming the metal layer is not particularly limited, and the existing method can be applied. For example, the methods disclosed in JP2007-157879A, JP2001-521288A, JP2004-214501A, JP2004-101850A, U.S. Pat. Nos. 7,888,181B2, and 9,177,926B2 can be used. For example, photolithography, physical vapor deposition method (PVD), chemical vapor phase growth method (CVD), lift-off, electrolytic plating, electroless plating, etching, printing, and a method obtained by combining these may be conceivable. More specific examples of the forming method for the metal layer include a patterning method obtained by combining sputtering, photolithography, and etching, and a patterning method combining photolithography and electrolytic plating. Examples of the preferred aspect of the plating include electrolytic plating using a copper sulfate plating liquid or a copper cyanide plating liquid.

The thickness of the metal layer at the thickest portion is preferably 0.01 to 50 μm and more preferably 1 to 10 μm.

### <Use>

Examples of the field to which the method for producing a cured product according to the embodiment of the present invention or the cured product according to the embodiment of the present invention can be applied include an insulating film of an electronic device, an interlayer insulating film for a re-distribution layer, and a stress buffer film. In addition, examples thereof include a sealing film, a substrate material (a base film or coverlay of a flexible print substrate, an interlayer insulating film), and an insulating film for mounting use application as described above, the insulating film being patterned by etching. For these use applications, for example, Science & Technology Co., Ltd., “High functionality and applied technology of polyimide” April 2008, Technical library CMC TL “Basics and development of polyimide materials” supervised by Masaaki Kakimoto, published in November 2011, “Latest Polyimide Basics and Applications” edited by Japan Polyimide & Aromatic Polymers Study Group, NTS Inc., August 2010, or the like can be referred to.

The method for producing a cured product according to the embodiment of the present invention and the cured product according to the embodiment of the present invention can also be used for the production of plate surfaces such as an offset plate surface or a screen plate surface, for etching of molded parts, for the production of protective lacquers and dielectric layers in electronics, in particular, microelectronics.

### (Laminate and Method for Producing Laminate)

A laminate according to the embodiment of the present invention refers to a structure having a plurality of layers consisting of the cured product according to the embodiment of the present invention.

The laminate is a laminate including two or more layers consisting of a cured product, and it may be a laminate in which three or more layers are laminated.

At least one of the two or more layers consisting of a cured product which are included in the laminate is a layer consisting of the cured product according to the embodiment of the present invention, and from the viewpoint of suppressing the shrinkage of the cured product or the deformation of the cured product due to the shrinkage, it is also preferable that all the layers consisting of a cured product which are included in the laminate are layers consisting of the cured product according to the embodiment of the present invention.

That is, it is preferable that the method for producing a laminate according to the embodiment of the present invention includes the method for producing a cured product according to the embodiment of the present invention, and it is more preferable to include repeating the method for producing a cured product according to the embodiment of the present invention a plurality of times.

In the laminate according to the aspect of the present invention, an aspect in which two or more layers consisting of a cured product are included and a metal layer is provided between any layers consisting of the cured product is preferable. The metal layer is preferably formed in the metal layer forming step.

That is, it is preferable that the method for producing a laminate according to the embodiment of the present invention further includes a metal layer forming step of forming a metal layer on a layer consisting of the cured product, between the methods for producing a cured product which are carried out a plurality of times. The preferred aspect of the metal layer forming step is as described above.

Examples of the preferred laminate include a laminate including at least a layer structure in which three layers of a layer consisting of a first cured product, a metal layer, and a layer consisting of a second cured product are laminated in order.

It is preferable that both the layer consisting of the first cured product and the layer consisting of the second cured product are layers consisting of the cured product according to the embodiment of the present invention. The resin composition according to the embodiment of the present invention which is used for forming a layer consisting of the first cured product and the resin composition according to the embodiment of the present invention which is used for forming a layer consisting of the second cured product may have the same composition or may have compositions different from each other. The metal layer in the laminate according to the embodiment of the present invention is preferably used as the metal wire of the re-distribution layer or the like.

### <Lamination Step>

The method for producing a laminate according to the embodiment of the present invention preferably further includes a laminating step.

The laminating step is a series of steps including carrying out again, in this order on the surface of the pattern (the resin layer) or the metal layer, (a) the film forming step (the layer forming step), (b) the exposure step, (c) the development step, and (d) at least one of the heating step or the post-development exposure step. However, an aspect may be adopted in which (a) the film forming step and at least one of (d) the heating step or the post-development exposure step are repeated. In addition, (e) the metal layer forming step may be included after at least one of the heating step or the post-development exposure step of (d). It is needless to say that the laminating step may further include appropriately the above-described drying step or the like.

In a case where another laminating step is further carried out after the laminating step, a surface activation treatment step may be further carried out after the exposure step, the heating step, or the metal layer forming step. Examples of the surface activation treatment include plasma treatment. Details of the surface activation treatment will be described later.

The laminating step is preferably carried out 2 to 20 times and more preferably 2 to 9 times.

For example, a configuration having resin layers of 2 or more layers and 20 or fewer layers, such as a resin layer/a metal layer/a resin layer/a metal layer/a resin layer/a metal layer, is preferable, and a configuration having resin layers of 2 or more layers and 9 or fewer layers is still more preferable.

In the above layers, the compositions, shapes, film thicknesses, and the like may be the same or may be different from each other.

In the present invention, an aspect in which a metal layer is provided, and then furthermore, a cured product (a resin layer) of the resin composition according to the aspect of the present invention is formed to cover the metal layer is particularly preferable. Specific examples thereof include an aspect in which (a) the film forming step, (b) the exposure step, (c) the development step, (d) at least one of the heating step or the post-development exposure step, (e) the metal layer forming step are repeated in this order, and an aspect in which (a) the film forming step, (d) at least one of the heating step or the post-development exposure step, and (e) the metal layer forming step are repeated in order. By alternately carrying out the laminating step of laminating the resin composition layer (the resin layer) of the present invention and the metal layer forming step, the resin composition layer (the resin layer) according to the embodiment of the present invention and the metal layer can be alternately laminated.

### (Surface Activation Treatment Step)

The method for producing a laminate according to the embodiment of the present invention preferably includes a surface activation treatment step of subjecting at least a part of the metal layer or a part of the resin composition layer to surface activation treatment.

The surface activation treatment step is usually carried out after the metal layer forming step. However, in a case where the surface activation treatment step is carried out after the development step (preferably, after at least one of the heating step or the post-development exposure step), the metal layer forming step may be carried out after the resin composition layer is subjected to the surface activation treatment step.

Only at least a part of the metal layer may be subjected to the surface activation treatment, only at least a part of the resin composition layer after the exposure may be subjected to the surface activation treatment, or both at least a part of the metal layer and at least a part of the resin composition layer after the exposure may be subjected to the surface activation treatment. It is preferable to carry out the surface activation treatment on at least a part of the metal layer, and it is more preferable to carry out the surface activation treatment on a part or whole of the region of the metal layer having a surface on which the resin composition layer is formed. In a case where a surface of the metal layer is subjected to the surface activation treatment in this manner, it is possible to improve the adhesiveness to the resin composition layer (film) to be provided on the surface thereof.

It is preferable that the surface activation treatment is carried out on a part or whole of the resin composition layer (the resin layer) after the exposure. In a case where a surface of the resin composition layer is subjected to the surface activation treatment in this manner, it is possible to improve the adhesiveness to a metal layer or a resin layer to be provided on the surface that has been subjected to the surface activation treatment. In particular, in a case where the resin composition layer is cured, such as in a case where negative tone development is carried out, it is less likely to be damaged by the surface treatment, and thus the adhesiveness is likely to be improved.

The surface activation treatment can be carried out, for example, according to the method described in paragraph 0415 of WO2021/112189A. The contents thereof are incorporated into the present specification.

### (Semiconductor Device and Producing Method Therefor)

The present invention also discloses a semiconductor device, which includes the cured product according to the embodiment of the present invention or the laminate.

In addition, the present invention also discloses a method for producing a semiconductor device, which includes the method for producing a cured product according to the embodiment of the present invention or the method for producing a laminate according to the embodiment of the present invention.

As the specific examples of the semiconductor device using the resin composition according to the embodiment of the present invention for forming an interlayer insulating film for a re-distribution layer, the description in paragraphs 0213 to 0218 and the description of FIG. 1 of JP2016-027357A can be referred to, the content of which is incorporated in the present specification.

### (Method for Producing Resin)

The method for producing a resin of the present invention includes a step of synthesizing a polyimide oligomer having an amino group at a terminal, and a step of reacting the polyimide oligomer with a compound represented by Formula (A-1).

The preferred aspect of the method for producing a resin of the present invention is the same as the above-described preferred aspect of the method for producing a specific resin.

### EXAMPLES

Hereinafter, the present invention will be described in detail with reference to Examples. Materials, using amounts, proportions, treatment details, treatment content, and the like shown in the following examples can be appropriately changed without departing from the gist of the present invention. Accordingly, the scope of the present invention is not limited to the following specific examples. Unless otherwise specified, “parts” and “%” are based on mass.

### <Synthesis of Polymer>

### Synthesis Example A-1: Synthesis of Resin (A-1)

15.1 g (71.2 mmol) of 2,2′-dimethylbenzidine was dissolved in 87.9 g of N-methylpyrrolidone (NMP). 20.0 g (38.4 mmol) of 4,4′-(4,4′-isopropylidenediphenoxy)diphthalic acid anhydride and 1.97 g (9.0 mmol) of pyromellitic acid anhydride were dissolved in 73.2 g of NMP, and the solution was added dropwise to the above-described solution at a temperature of 0° C. to 10° C. for 1 hour, and stirred at 185° C. to 195° C. for 240 minutes. After the reaction, the mixture was cooled to room temperature to obtain a resin solution A-1a.

6.16 g (28.2 mmol) of pyromellitic acid anhydride, 0.77 g (1.5 mmol) of 4,4′-(4,4′-isopropylidenediphenoxy)diphthalic acid anhydride, 7.89 g (60.5 mmol) of 2-hydroxyethyl methacrylate, 0.05 g of hydroquinone, 10.42 g (131.8 mmol) of pyridine, and 35 g of diglyme were mixed and stirred at a temperature of 60° C. for 5 hours to produce a diester of pyromellitic acid anhydride and 4,4′-(4,4′-isopropylidenediphenoxy)diphthalic acid anhydride and 2-hydroxyethyl methacrylate. Next, the mixture was cooled to −20° C., and then 7.42 g (61.6 mmol) of thionyl chloride was added dropwise thereto over 90 minutes, and the mixture was stirred for 2 hours to obtain a white precipitate of pyridinium hydrochloride.

Next, the resin solution A-1a was added dropwise thereto over 2 hours. Next, 5.47 g (118.6 mmol) of ethanol was added thereto, and the mixture was stirred for 2 hours. Next, the resin was precipitated in 4 L of water, and the water-resin mixture was stirred at a speed of 500 rpm for 15 minutes. The resin was filtered to be acquired, and the resin was stirred again in 4 L of water for 30 minutes and filtered again. Next, the obtained resin was dried at 45° C. for 2 days under reduced pressure to obtain a resin (A-1). A weight-average molecular weight (Mw) of the obtained resin (A-1) was 43,000, and a number-average molecular weight (Mn) thereof was 18,500. It was confirmed by ¹H-NMR that the resin (A-1) had a structure including a repeating unit represented by Formula (A-1). In the following structures, the symbols in parentheses are values shown in the tables below, and represent the molar ratio of each structure. In addition, the weight-average molecular weight (Mw), the number-average molecular weight (Mn), and the imidization rate (%) of the resin (A-1) are shown in the tables below.

For convenience, two kinds of repeating units are described, that is, a repeating unit in which two imidizable moieties are present (repeating unit of m % by mole and n % by mole below) and a repeating unit in which two imidizable moieties form an imide ring (repeating unit of k % by mole and 1% by mole below), but in practice, a repeating unit in which only one of the two imidizable moieties forms an imide ring and the other does not form an imide ring is also included. The same applies to the following resins. Therefore, the molar ratio is merely a molar ratio in a case where only the following repeating units are present, and in practice, in a range in which the total amount of the imide ring structure is the same value, a repeating unit in which only one forms an imide ring and the other does not form an imide ring may be included. In addition, the proportion of the structure in which the imide ring is formed in the resin is shown in the tables below as the imidization rate (%). The same applies to the following other resins.

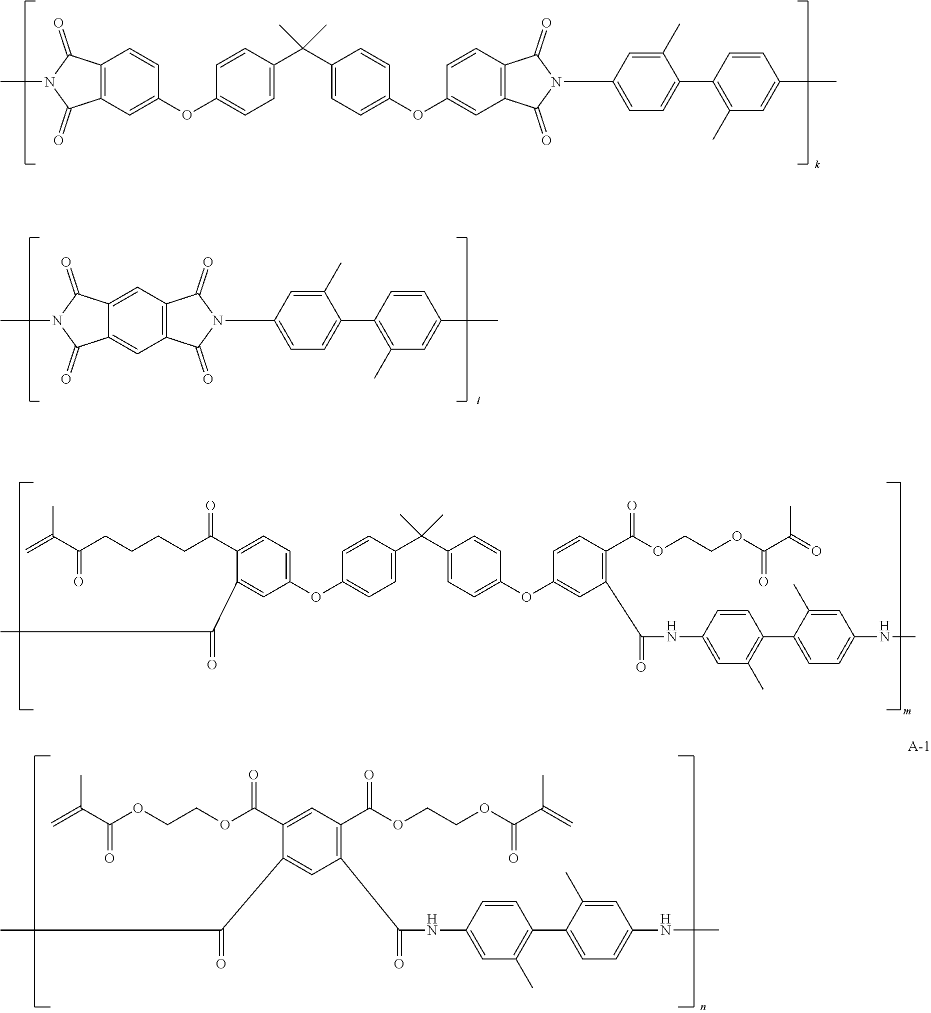

### Synthesis Examples A-2, A-14, and A-15: Synthesis of Resins (A-2), (A-14), and (A-15)

Resins A-2, A-14, and A-15 were synthesized in the same manner as in the resin A-1, except that the preparation ratios of the acid anhydride and the diamine as raw materials used in Synthesis Example A-1 were appropriately changed. The resins (A-2), (A-14), and (A-15) have the same repeating units as in Formula (A-1), except that the molar ratio of each structure in Formula (A-1) is changed to the value shown in the tables below. The weight-average molecular weight (Mw), the number-average molecular weight (Mn), and the imidization rate (%) of the resins (A-2), (A-14), and (A-15) are shown in the tables below.

### Synthesis Example A-3: Synthesis of Resin (A-3)

6.23 g (57.6 mmol) of 1,4-phenylenediamine was dissolved in 80.0 g of N-methyl-2-pyrrolidone (NMP). 20.0 g (38.4 mmol) of 4,4′-(4,4′-isopropylidenediphenoxy)diphthalic acid anhydride was dissolved in 73.2 g of NMP, and the solution was added dropwise to the above solution at a temperature of 0° C. to 10° C. for 1 hour, and stirred at 185° C. to 195° C. for 240 minutes. After the reaction, the reaction solution was cooled to room temperature to obtain a resin solution A-3a.

12.5 g (24.0 mmol) of 4,4′-(4,4′-isopropylidenediphenoxy)diphthalic acid anhydride, 6.39 g (49.0 mmol) of 2-hydroxyethyl methacrylate, 0.05 g of hydroquinone, 8.44 g (106.8 mmol) of pyridine, and 35 g of diglyme were mixed and stirred at a temperature of 60° C. for 5 hours to produce a diester of 4,4′-(4,4′-isopropylidenediphenoxy)diphthalic acid anhydride and 2-hydroxyethyl methacrylate. Next, the mixture was cooled to −20° C., 6.01 g (49.9 mmol) of thionyl chloride was added dropwise thereto over 90 minutes, and the mixture was stirred for 2 hours to obtain a white precipitate of pyridinium hydrochloride.

Next, the resin solution A-3a was added dropwise thereto over 2 hours. Next, 4.43 g (96.1 mmol) of ethanol was added thereto, and the mixture was stirred for 2 hours. Next, the resin was precipitated in 4 L of water, and the water-resin mixture was stirred at a speed of 500 rpm for 15 minutes. The resin was filtered to be acquired, and the resin was stirred again in 4 L of water for 30 minutes and filtered again. Next, the obtained resin was dried at 45° C. for 2 days under reduced pressure to obtain a resin (A-3). A weight-average molecular weight (Mw) of the obtained resin (A-3) was 32,300, and a number-average molecular weight (Mn) thereof was 11,500. It is presumed that the resin (A-3) has a structure including a repeating unit represented by Formula (A-3). In the following structures, the symbols in parentheses are values shown in the tables below, and represent the molar ratio of each structure. In addition, the weight-average molecular weight (Mw), the number-average molecular weight (Mn), and the imidization rate (%) of the resin (A-3) are described in the tables below.

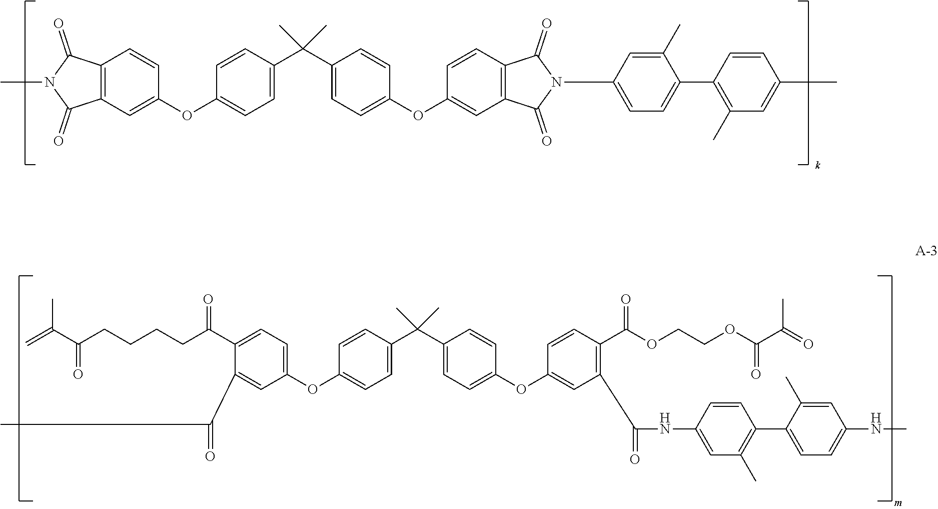

### Synthesis Examples A-4 to A-6, A-9 to A-13, and A-16 and A-17: Synthesis of Resins (A-4) to (A-6), (A-9) to (A-13), (A-16) to (A-17), and (A-21) to (A-24)

Resins (A-4) to (A-6), (A-9) to (A-13), (A-16) and (A-17), and (A-21) to (A-24) were synthesized in the same manner as in the resin (A-1), except that the type of the acid anhydride and the diamine as the raw materials used in Synthesis Example A-1, the preparation ratio, and 2-hydroxyethyl methacrylate (HEMA) were appropriately changed. The resins (A-4) to (A-6), (A-9) to (A-13), and (A-16) and (A-17) are resins having repeating units represented by Formulae (A-4) to (A-6), (A-9) to (A-13), (A-16) to (A-17), and (A-21) to (A-24). The structure of each repeating unit was determined from a ¹H-NMR spectrum. In the following structures, the symbols in parentheses are values shown in the tables below, and represent the molar ratio of each structure. In addition, the weight-average molecular weight (Mw), the number-average molecular weight (Mn), and the imidization rate (%) of these resins are described in the tables below.

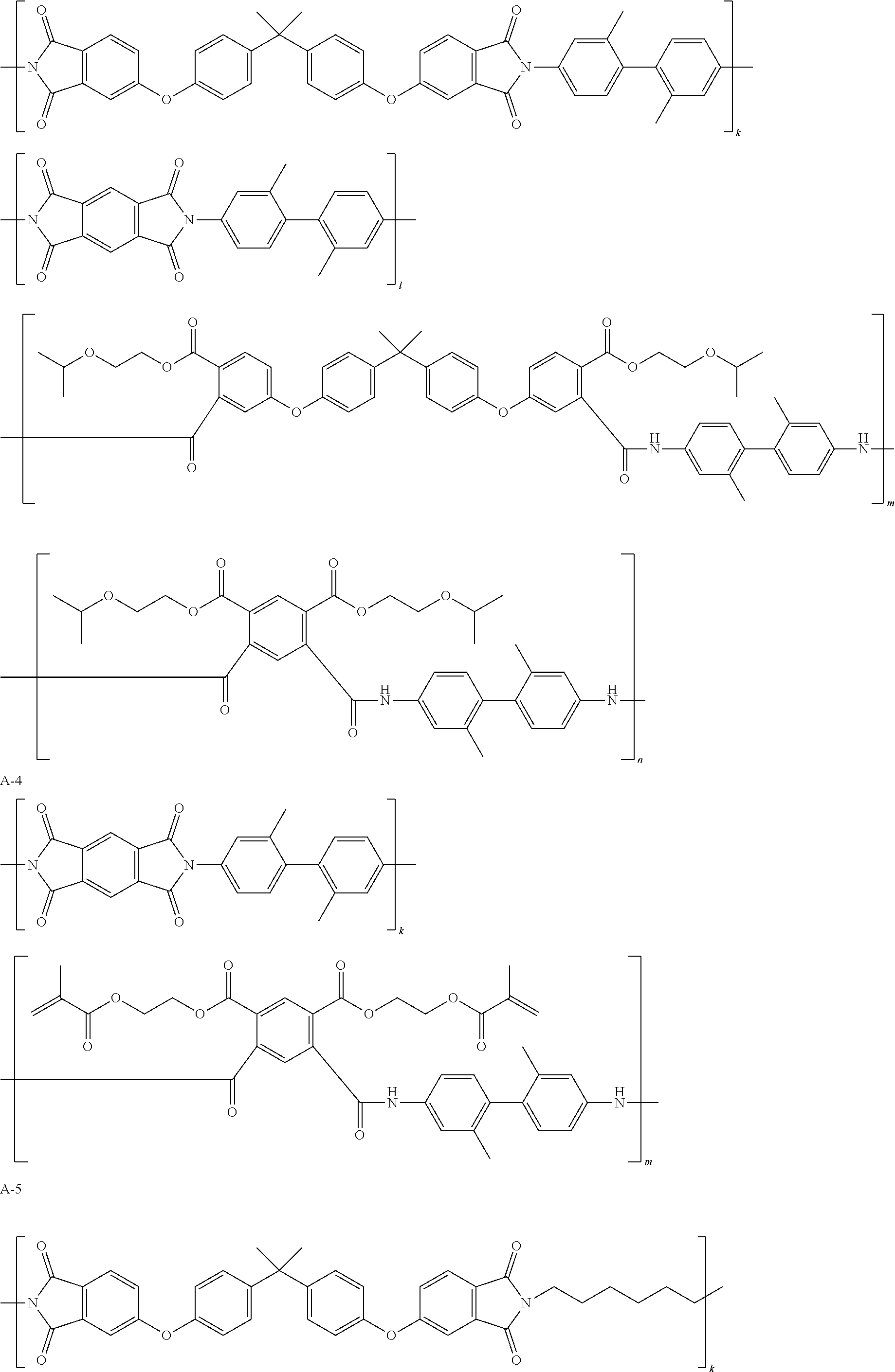

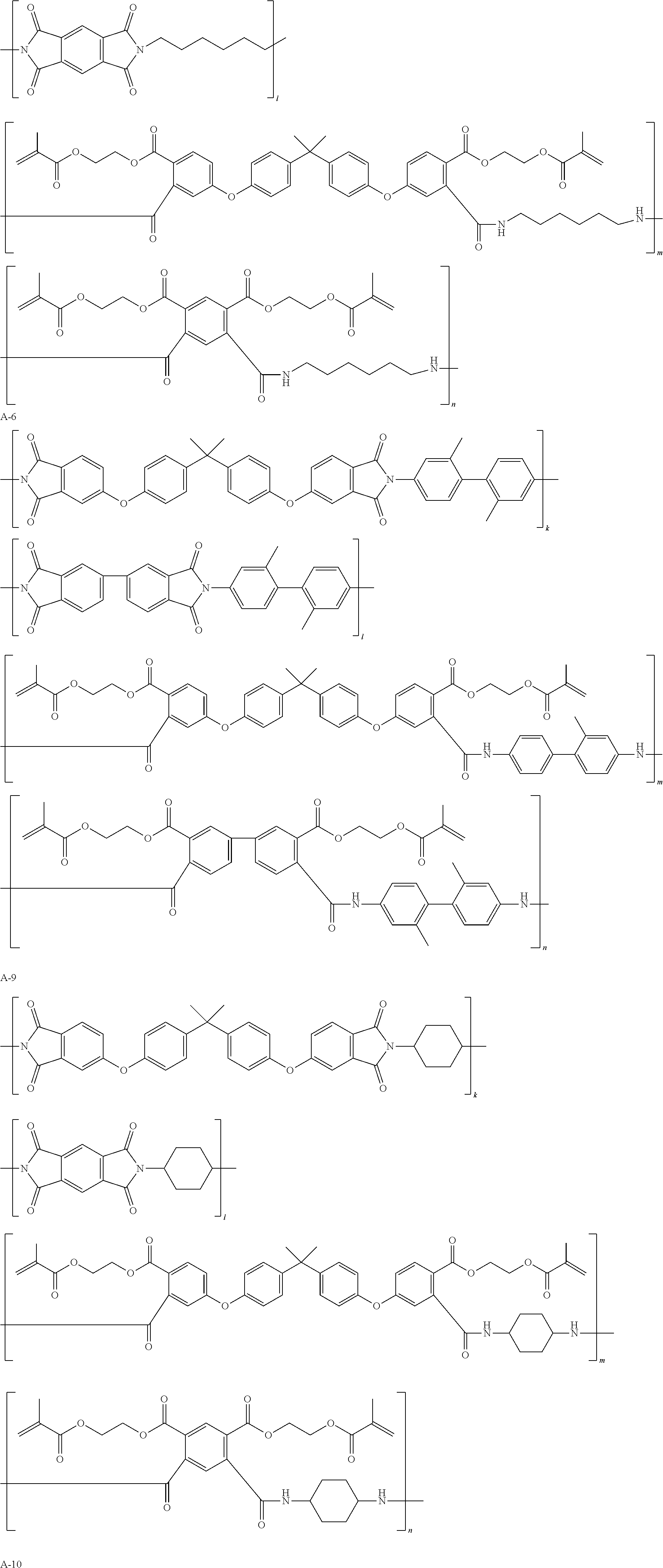

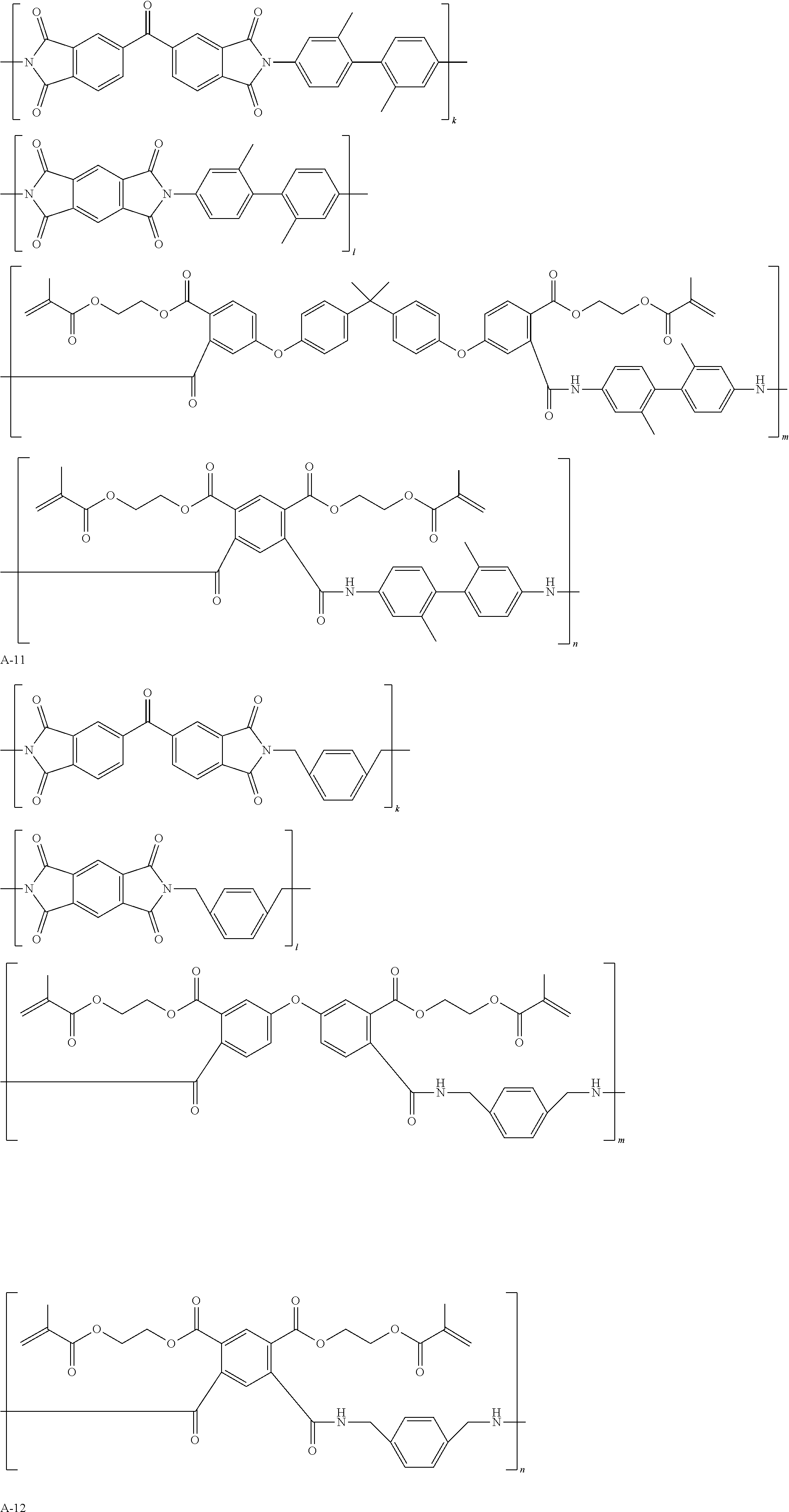

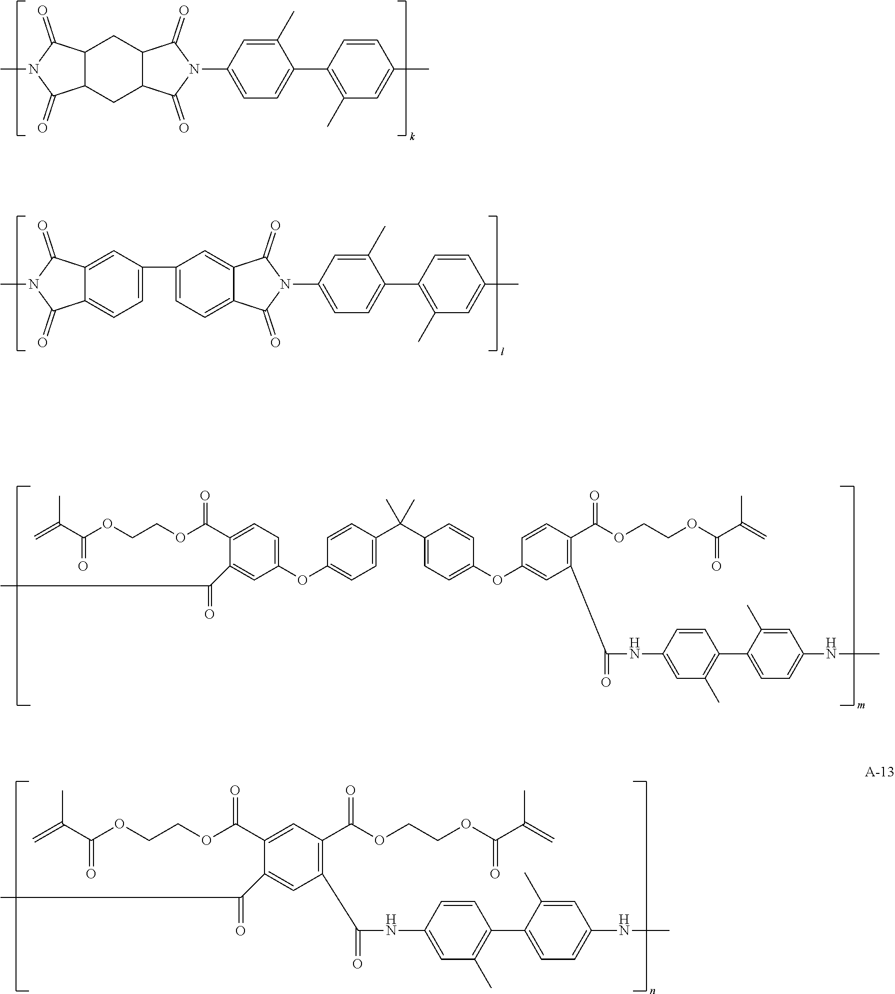

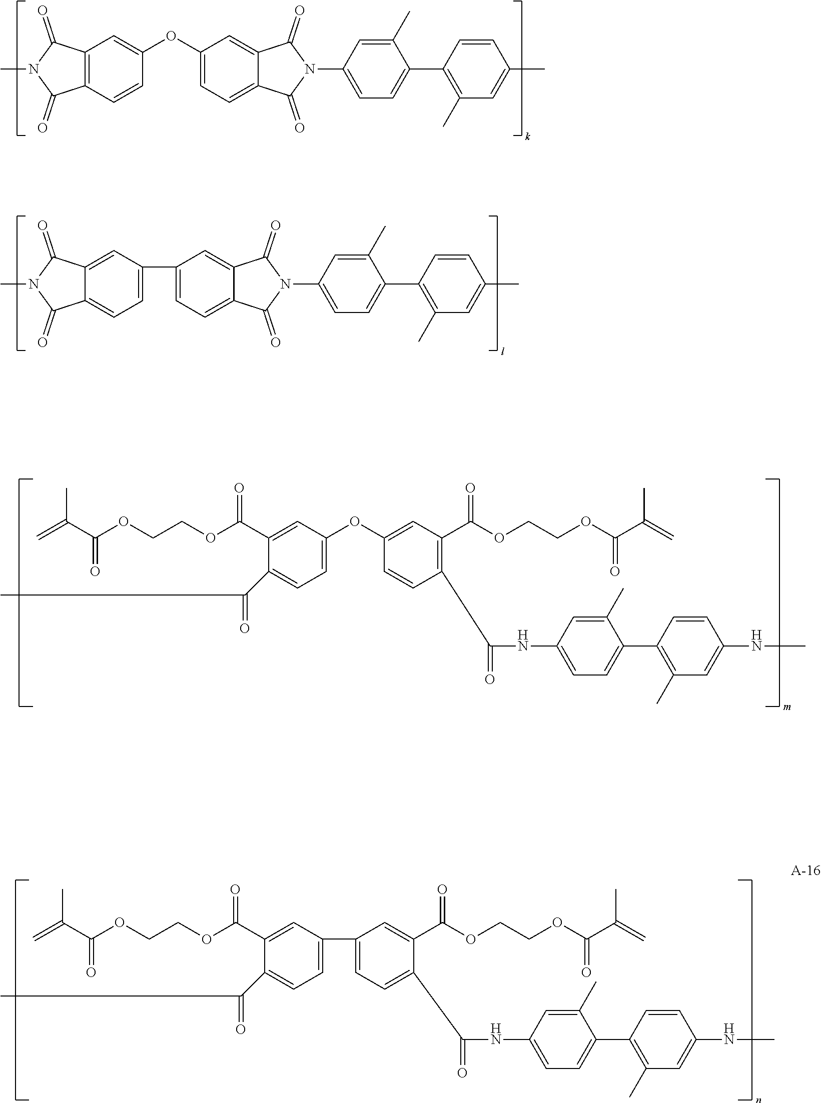

### Synthesis Examples A-7 and A-8: Synthesis of Resins (A-7) and (A-8)

Resins (A-7) and (A-8) were synthesized by the same method as the resin (AC-1) described later, except that the preparation ratios of the acid anhydride and the diamine as raw materials used in Synthesis Example AC-1 described later were appropriately changed. It is presumed that the resins (A-7) and (A-8) have a structure containing the same repeating unit as in Formula (AC-1), except that the molar ratio of each structure of Formula (AC-1) described later is changed to the value described in the table described later. The weight-average molecular weight, the number-average molecular weight, and the imidization rate (%) of the resins (A-7) and (A-8) are described in the table described later.

### Synthesis Example A-18: Synthesis of Resin (A-18)

8.38 g (38.4 millimoles) of pyromellitic anhydride, 20.0 g (38.4 millimoles) of 4,4′-(4,4′-isopropylidenediphenoxy)diphthalic anhydride, and 7.89 g (60.5 millimoles) of 2-hydroxyethyl methacrylate were dissolved in 165 g of N-methylpyrrolidone (NMP). A solution obtained by dissolving 14.2 g (71.5 millimoles) of 4,4′-diaminodiphenylmethane in 115 g of NMP was added dropwise thereto at a temperature of 0° C. to 10° C. for 1 hour. After returning to room temperature, the mixture was further stirred for 2 hours. 15.0 g (72.9 millimoles) of N,N′-dicyclohexylcarbodiimide was added thereto, 9.49 g (72.9 millimoles) of 2-hydroxyethyl methacrylate was added thereto, and the mixture was stirred at 40° C. for 12 hours. After completion of the reaction, 9.81 g (96.1 millimoles) of acetic anhydride and 12.2 g (153.7 millimoles) of pyridine were added thereto at room temperature, and the reaction was continued at 80° C. for 4 hours. After completion of the reaction, the temperature was returned to room temperature, the resin was precipitated in 4 L of water, and the water-resin mixture was stirred at a rate of 500 rpm for 15 minutes. The resin was filtered to be acquired, and the resin was stirred again in 4 L of water for 30 minutes and filtered again. Next, the obtained resin was dried at 45° C. for 2 days under reduced pressure to obtain a resin (A-18). A weight-average molecular weight (Mw) of the obtained resin (A-18) was 35,300, and a number-average molecular weight (Mn) thereof was 13,200. It is presumed that the resin (A-18) has a structure including a repeating unit represented by Formula (A-18). In the following structures, the symbols in parentheses are values shown in the tables below, and represent the molar ratio of each structure. In addition, the weight-average molecular weight (Mw), the number-average molecular weight (Mn), and the imidization rate (%) of the resin (A-18) are shown in the tables described later.

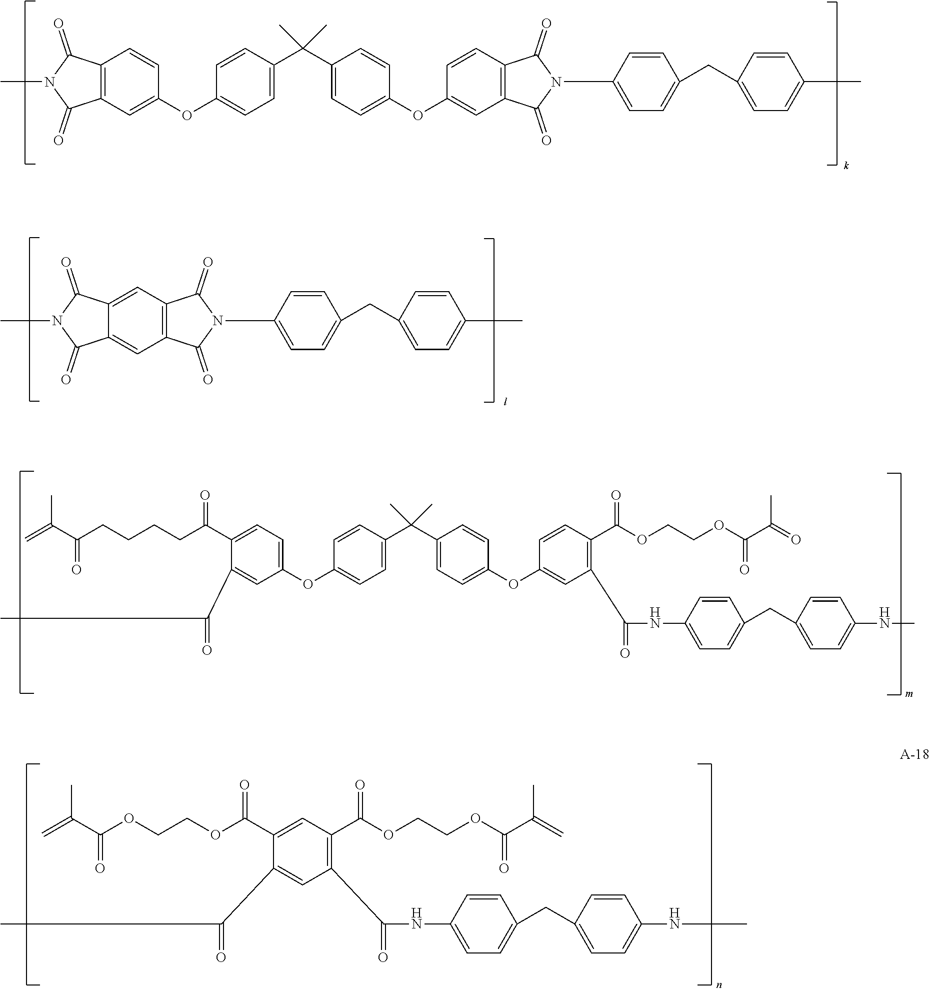

### Synthesis Example A-19: Synthesis of Resin (A-19)

25.1 g (48.2 millimoles) of 4,4′-(4,4′-isopropylidenediphenoxy)diphthalic acid anhydride, 10.5 g (48.2 millimoles) of pyromellitic acid anhydride, 25.3 g (194 millimoles) of 2-hydroxyethyl methacrylate, and 136.83 g of tetrahydrofuran were put into a vessel, stirred at room temperature (25° C.), and 15.7 g (198 millimoles) of pyridine was added thereto with stirring to obtain a reaction mixture. After the heat generation due to the reaction was finished, the mixture was allowed to cool to room temperature and allowed to stand at room temperature for 16 hours.

Next, under ice cooling, a solution obtained by dissolving 39.7 g (193 millimoles) of dicyclohexylcarbodiimide (DCC) in 61.6 g of tetrahydrofuran was added to the reaction mixture over 40 minutes with stirring, and a solution obtained by dissolving 14.2 g (71.5 millimoles) of 4,4′-diaminodiphenylmethane in 119.7 g of N-methylpyrrolidone (NMP) was added thereto over 60 minutes with stirring. After further stirring at room temperature for 2 hours, 4.56 g of ethanol was added thereto and stirred for 1 hour, and then 136.83 g of tetrahydrofuran was added thereto. The obtained reaction mixture was allowed to stand at room temperature for 20 hours, and the precipitate generated in the reaction mixture was removed by filtration to obtain a reaction solution.

The obtained reaction solution was added to 750 g of ethanol to produce a precipitate consisting of a crude polymer. The generated crude polymer was separated by filtration and dissolved in 250 g of tetrahydrofuran to obtain a crude polymer solution. The obtained crude polymer solution was added dropwise to 5 L of water to precipitate the polymer, and the obtained precipitate was filtered. Next, the obtained resin was dried at 45° C. for 2 days under reduced pressure to obtain a resin (A-19). A weight-average molecular weight of the obtained resin (A-19) was 31,200, and a number-average molecular weight (Mn) thereof was 10,900. It is presumed that the resin (A-19) has a structure including a repeating unit represented by Formula (A-19). In the following structures, the symbols in parentheses are values shown in the tables below, and represent the molar ratio of each structure. In addition, the weight-average molecular weight (Mw), the number-average molecular weight (Mn), and the imidization rate (%) of the resin (A-19) are described in the tables described later.

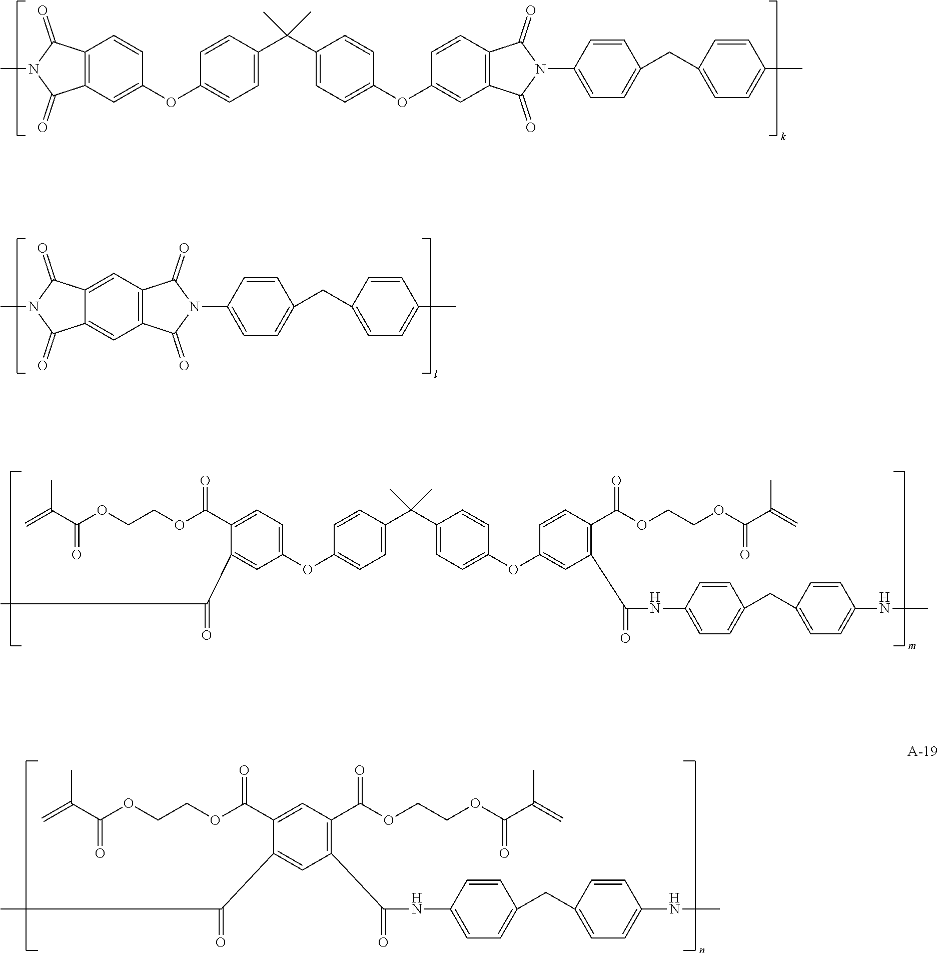

### Synthesis Example A-20: Synthesis of Resin (A-20)

A resin (A-20) was synthesized by the same method as that for the resin (A-18), except that, in Synthesis Example A-18, 2-hydroxyethyl methacrylate was changed to 4-vinylbenzylamine. It is presumed that the resin (A-20) has a structure including a repeating unit represented by Formula (A-20). In the following structures, the symbols in parentheses are values shown in the tables below, and represent the molar ratio of each structure. In addition, the weight-average molecular weight (Mw), the number-average molecular weight (Mn), and the imidization rate (%) of the resin (A-20) are described in the tables described later.

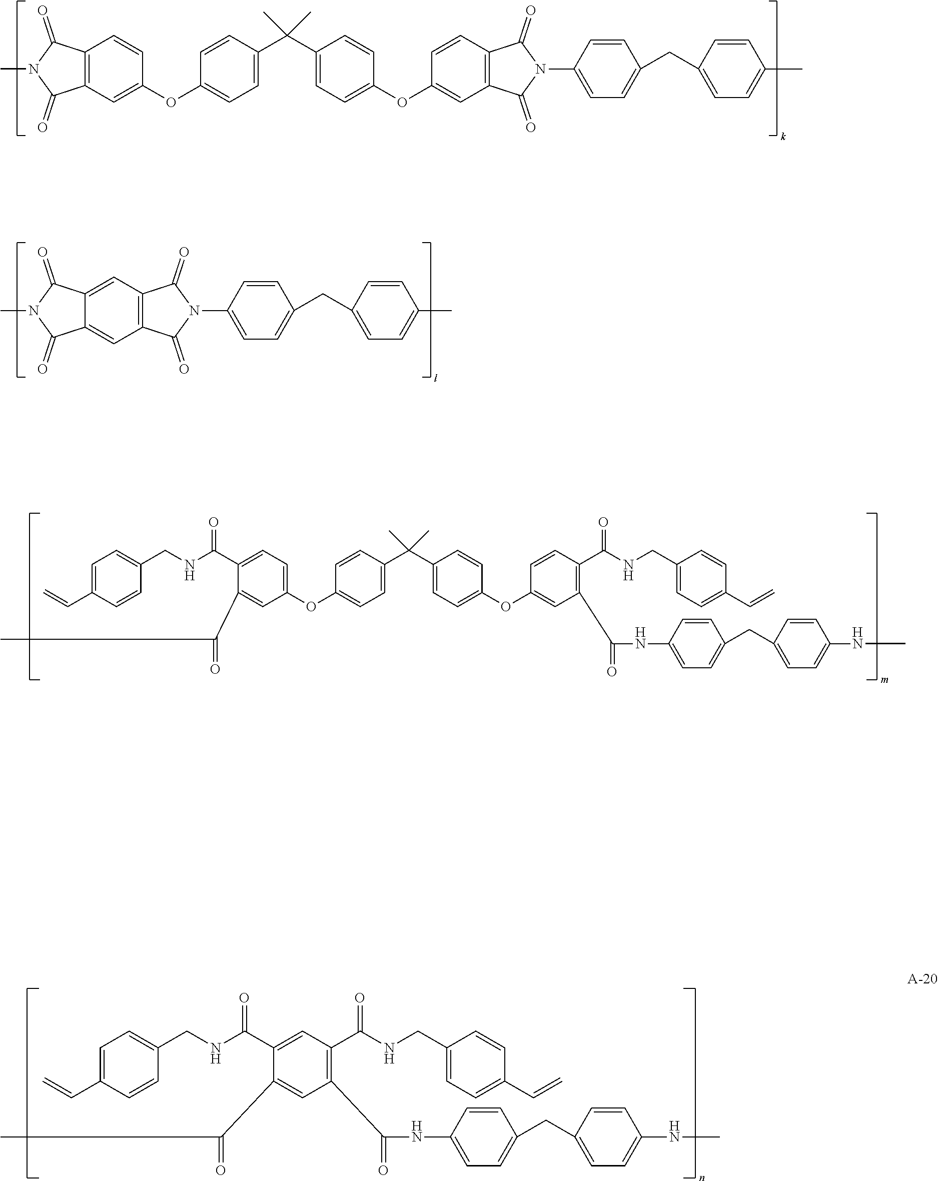

### Synthesis Example AC-1: Synthesis of Resin (AC-1)

37.7 g (117.8 mmol) of 2,2′-bis(trifluoromethyl)benzidine was dissolved in 91.2 g of N-methylpyrrolidone (NMP). 20.0 g (38.4 mmol) of 4,4′-(4,4′-isopropylidenediphenoxy)diphthalic acid anhydride and 2.79 g (12.8 mmol) of pyromellitic acid anhydride were dissolved in 76.0 g of NMP, and the solution was added dropwise to the solution at a temperature of 0° C. to 10° C. over 1 hour, and stirred at 185° C. to 195° C. for 240 minutes. After the reaction, the reaction solution was cooled to room temperature to obtain a resin solution AC-1a.

16.9 g (77.2 mmol) of pyromellitic acid anhydride, 2.11 g (4.1 mmol) of 4,4′-(4,4′-isopropylidenediphenoxy)diphthalic acid anhydride, 21.6 g (165.9 mmol) of 2-hydroxyethyl methacrylate, 0.05 g of hydroquinone, 28.6 g (361 mmol) of pyridine, and 100 g of diglyme were mixed and stirred at a temperature of 60° C. for 5 hours to produce a diester of pyromellitic acid anhydride and 4,4′-(4,4′-isopropylidenediphenoxy)diphthalic acid anhydride and 2-hydroxyethyl methacrylate. Next, the mixture was cooled to −20° C., then 20.3 g (168.7 mmol) of thionyl chloride was added dropwise thereto over 90 minutes, and the mixture was stirred for 2 hours to obtain a white precipitate of pyridinium hydrochloride.

Next, the resin solution AC-1a was added dropwise thereto over 2 hours. Next, 15.0 g (325 mmol) of ethanol was added thereto, and the mixture was stirred for 2 hours. Next, the resin was precipitated in 4 L of water, and the water-resin mixture was stirred at a speed of 500 rpm for 15 minutes. The resin was filtered to be acquired, and the resin was stirred again in 4 L of water for 30 minutes and filtered again. Next, the obtained resin was dried at 45° C. for 2 days under reduced pressure to obtain a resin (AC-1). It is presumed that the resin (AC-1) has a structure including a repeating unit represented by Formula (AC-1). In the following structures, the subscripts of the repeating units represent the content molar ratio of the respective repeating units. In addition, the weight-average molecular weight (Mw), the number-average molecular weight (Mn), and the imidization rate (%) of the resin (AC-1) are described in the table below.

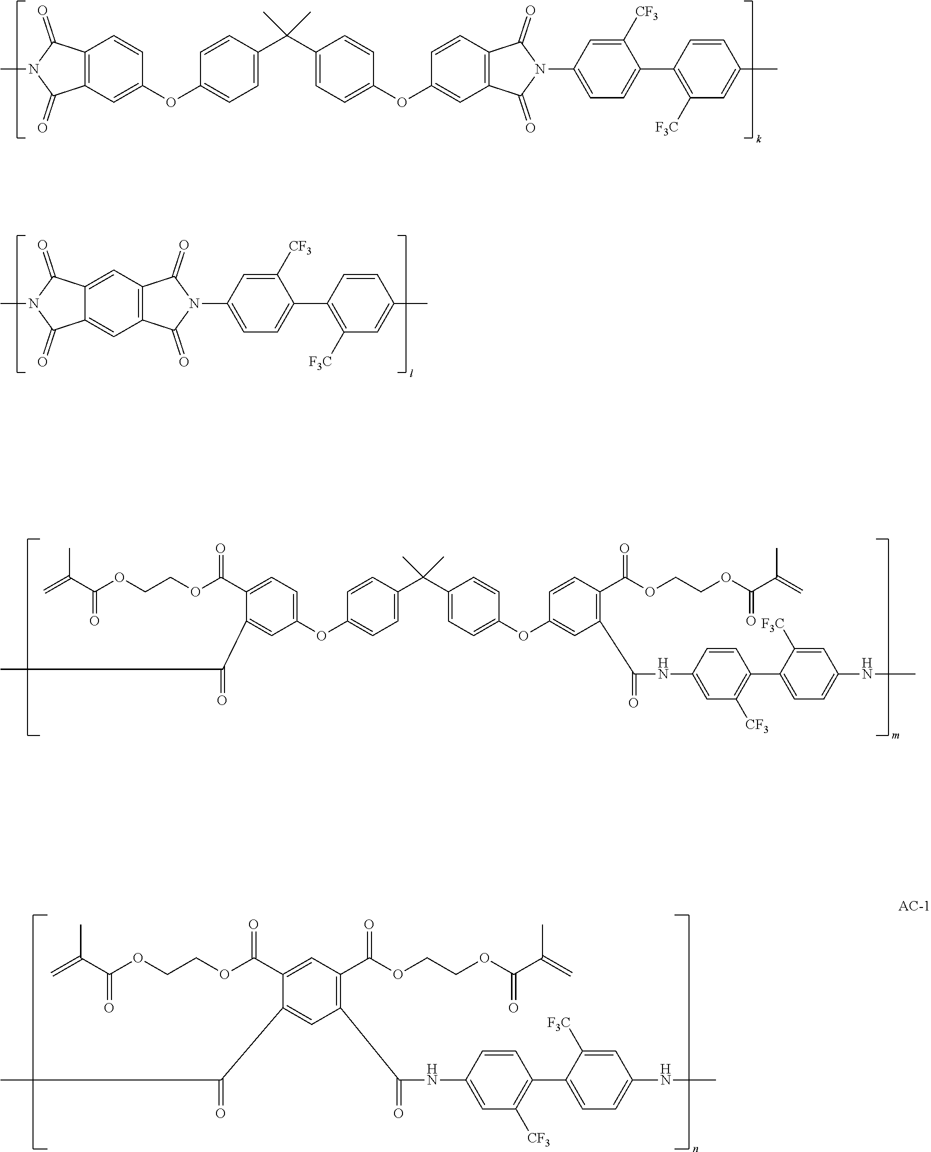

### Synthesis Example AC-2: Synthesis of Resin (AC-2)

A resin (AC-2) was synthesized by the same method as the resin (AC-1), except that the preparation ratios of the acid anhydride and the diamine as raw materials used in Synthesis Example AC-1 were appropriately changed. The resin (AC-2) has a structure including the same repeating unit as Formula (AC-1), except that the molar ratio of each structure of Formula (AC-1) is changed to a value described in the table below. The weight-average molecular weight (Mw) of the resin (AC-2) was 57,800, and the number-average molecular weight (Mn) thereof was 20,900. In addition, the weight-average molecular weight (Mw), the number-average molecular weight (Mn), and the imidization rate (%) of the resin (AC-2) are described in the table below.

### Synthesis Example AA-1

375 mL of dimethylformamide was mixed with 48.65 g (225 mmol) of 3,3′-dihydroxybenzidine in a flask. 98.21 g (450 millimoles) of di-t-butyl carbonate was added dropwise under ice cooling. Stirring was carried out at a temperature of 60° C. for 5 hours after completion of the dropwise addition. After the completion of the reaction, the mixture was cooled to room temperature, 35 mg of 2,2,6,6-tetramethylpiperidine 1-oxyl free radical, 68.68 g (450 mmol) of p-chloromethylstyrene, 74.63 g (540 mmol) of potassium carbonate, and 8.96 g (54.0 mmol) of potassium iodide were added thereto, and the mixture was stirred at a temperature of 60° C. for 3 hours. After completion of the reaction, filtration was carried out by a suction filtration operation, and the filtrate was added dropwise to 500 mL of water. Since white crystals were precipitated, the precipitated solid was collected by suction filtration. The obtained white solid was recrystallized and purified at 60° C. using 1000 mL of acetone. 125 g of the following intermediate AA-1a (yield: 85.6%) was obtained.

The structure of AA-1a is shown below. The following structure was confirmed from the ¹H-NMR spectrum.

¹H-NMR (BRUKER, AVANCE NEO 400): δ(ppm,DMSO-d6) 8.04-7.94 (s, 2H), 7.75-7.64 (d, 2H), 7.56-7.42 (m, 8H), 7.27-7.20 (d, 2H), 7.19-7.12 (d, 2H), 6.79-6.64 (2H), 5.89-5.77 (2H), 5.30-5.15 (6H), 1.49-1.43 (s, 18H)

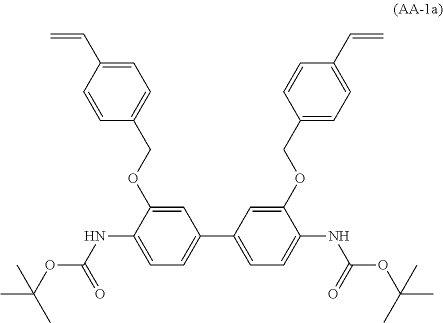 [SMILES: C=Cc1ccc(COc2cc(-c3ccc(NC(=O)OC(C)(C)C)c(OCc4ccc(C=C)cc4)c3)ccc2NC(=O)OC(C)(C)C)cc1]

75.0 g (115.6 millimoles) of (AA-1a) and 500 mL of methylene chloride were mixed in a flask. 131.8 g (1156 mmol) of trifluoroacetic acid was added thereto at room temperature, and the mixture was stirred at a temperature of 40° C. for 5 hours. After completion of the reaction, 250 mL of methanol and then 117.0 g (1156 mmol) of triethylamine were added dropwise under ice cooling. Since pale yellow crystals were precipitated, the precipitated solid was collected by suction filtration. Suspension washing was carried out with 750 mL of methanol to obtain 40.5 g (yield: 73%) of (AA-1). The structure of AA-1 is shown below. The following structure was confirmed from the ¹H-NMR spectrum.

¹H-NMR (BRUKER, AVANCE NEO 400): δ(ppm,DMSO-d6) 7.53-7.45 (s, 8H), 7.05-6.98 (d, 2H), 6.92-6.85 (d, 2H), 6.79-6.63 (4H), 5.89-5.78 (d, 2H), 5.29-5.22 (d, 2H), 5.20-5.13 (s, 4H), 4.92-4.64 (4H)

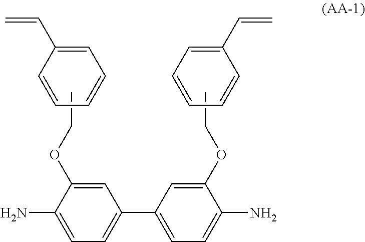

### Synthesis Example AT-1

AT-1 was obtained by the same method as in Synthesis Example AA-1, except that 3,3′-dihydroxybenzidine was replaced with p-methoxyphenol.

The structure of AT-1 is shown below. The following structure was confirmed from the ¹H-NMR spectrum.

¹H-NMR (BRUKER, AVANCE NEO 400): δ(ppm,DMSO-d6) 7.52-7.42 (d, 2H), 7.42-7.32 (d, 2H), 6.80-6.63 (3H), 6.54-6.43 (d, 2H), 5.92-5.77 (1H), 5.30-5.19 (1H), 4.95-4.89 (s, 2H), 4.68-4.54 (2H)

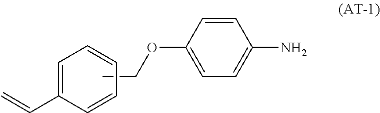

### (Synthesis of Polymer)

### Synthesis Example AC-3: Synthesis of Polyimide (AC-3)

30.0 g (57.64 mmol) of 4,4′-(4,4′-isopropylidenediphenoxy)diphthalic acid anhydride and 0.08 g of 2,2,6,6-tetramethylpiperidine 1-oxyl free radical were dissolved in 120 g of N-methylpyrrolidone (NMP) to obtain a solution. Subsequently, 4.88 g (23.0 mmol) of 2,2′-dimethylbenzidine, 10.32 g (23.0 mmol) of AA-1, and 1.30 g (5.76 mmol) of AT-1 were dissolved in 100 g of NMP, and the solution was added dropwise to the above-described dissolution solution at a temperature of 0° C. to 10° C. over 1 hour, stirred at 25° C. for 60 minutes, and then 18.2 g of pyridine and 14.7 g of acetic anhydride were added thereto, followed by reaction at 80° C. for 4 hours. After completion of the reaction, the mixture was cooled to 25° C. and diluted with 200 g of tetrahydrofuran. Subsequently, the reaction solution was added dropwise to a mixed solution of 2.0 L of methanol and 0.5 L of water, and the mixture was stirred for 15 minutes and a polyimide resin was filtered. Next, the resin was subjected to reslurrying with 1 L of water, filtered, reslurried again with 1 L of methanol, filtered, and dried at 40° C. for 10 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered to be acquired, and dried at 45° C. for 1 day under reduced pressure to obtain a polyimide resin (AC-3). A weight-average molecular weight of the obtained polyimide (AC-3) was 17,300, and a number-average molecular weight thereof was 7,250. An imidization rate was 95% or more. The polyimide (AC-3) is a resin having a repeating unit represented by Formula (AC-3). The structure of the repeating unit was determined from a ¹H-NMR spectrum.

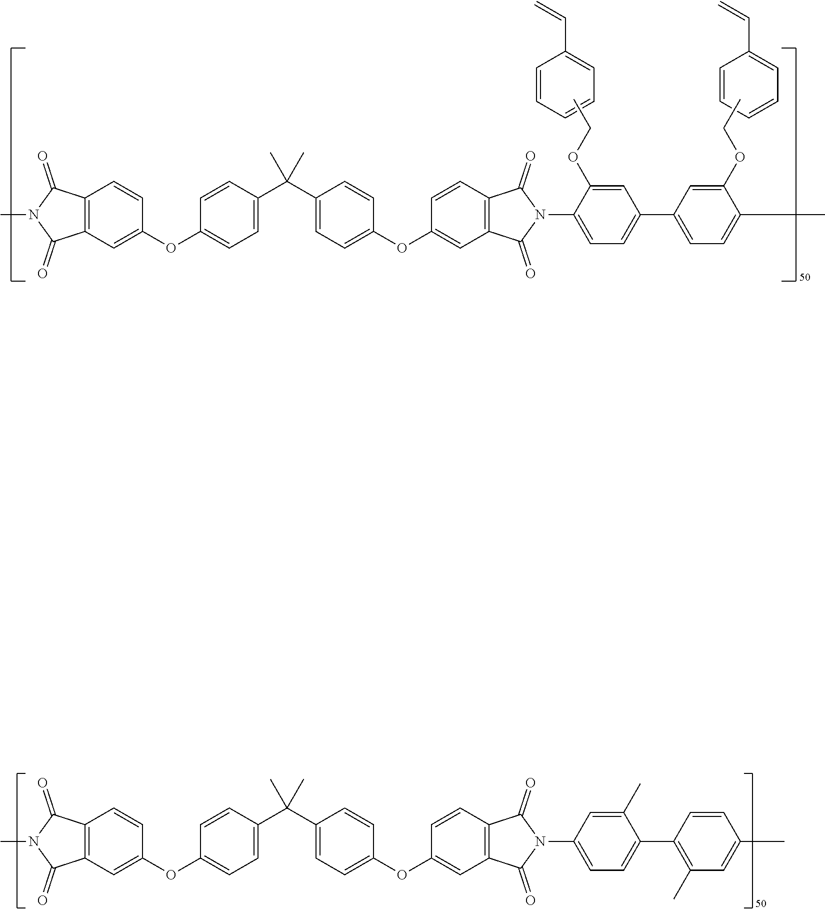

### Resin Terminal Structure:

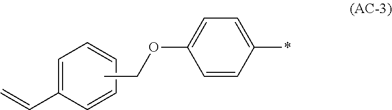

TABLE 1

| | k/l/m/n (% | Imidization | | |
|---|---|---|---|---|
| Resin | by mole) | rate (%) | Mw | Mn |
| A-1 | 50/12/2/36 | 62 | 43000 | 18500 |
| A-2 | 54/16/2/28 | 70 | 37500 | 16200 |
| A-3 | 62/0/38/0 | 62 | 32300 | 11500 |
| A-4 | 45/10/15/30 | 60 | 78400 | 29100 |
| A-5 | 50/0/50/0 | 50 | 29500 | 11600 |
| A-6 | 15/35/15/35 | 50 | 28800 | 10800 |
| A-7 | 25/15/7/53 | 40 | 40500 | 17500 |
| A-8 | 47/37/3/13 | 84 | 51200 | 19500 |
| A-9 | 38/17/5/40 | 55 | 29800 | 11300 |
| A-10 | 40/12/8/40 | 52 | 31500 | 11580 |
| A-11 | 43/17/5/35 | 60 | 57200 | 19860 |
| A-12 | 53/12/3/32 | 65 | 50500 | 19500 |
| A-13 | 40/20/3/37 | 60 | 34800 | 13400 |
| A-14 | 30/35/2/33 | 65 | 12200 | 4200 |
| A-15 | 48/5/20/27 | 53 | 105000 | 35200 |
| A-16 | 40/15/5/40 | 55 | 29500 | 10500 |
| A-17 | 37/15/8/40 | 52 | 23700 | 8700 |
| A-18 | 25/25/25/25 | 50 | 35300 | 13200 |
| A-19 | 25/25/25/25 | 50 | 31200 | 10900 |
| A-20 | 25/25/25/25 | 50 | 32200 | 12000 |
| A-21 | 30/30/5/35 | 60 | 54500 | 20350 |
| A-22 | 35/17/5/43 | 52 | 41500 | 15600 |
| A-23 | 35/30/5/30 | 65 | 30300 | 11700 |
| A-24 | 45/12/5/38 | 57 | 33700 | 13210 |
| AC-1 | 29/10/3/58 | 39 | 37400 | 16700 |
| AC-2 | 64/22/3/11 | 86 | 57800 | 20900 |

### [Method for Measuring Imidization Rate]

Each of the resins (A-1) to (A-20), (AC-1), (AC-2), and (AC-3) was dissolved in 7-butyrolactone, diluted so that a viscosity was 2,000 mPa·s, and applied onto a silicon wafer by a spin coating method to form a resin layer. The silicon wafer to which the obtained resin layer was applied was dried on a hot plate at 110° C. for 5 minutes, thereby obtaining a resin layer having a uniform thickness of a film thickness of approximately 15 μm after film formation on the silicon wafer.

The above-described resin layer was measured by an ATR method with Nicolet iS20 (manufactured by Thermo Fisher Scientific Inc.), and the measurement was performed in a measurement range of 4,000 to 700 cm⁻¹ and 50 times of measurement. A value obtained by dividing a peak height in a vicinity of 1,380 cm⁻¹ (in a case where there are a plurality of peaks, the peak having the maximum peak intensity in 1,350 to 1,450 cm⁻¹) by a peak height in a vicinity of 1,500 cm⁻¹ (in a case where there are a plurality of peaks, the peak having the maximum peak intensity in 1,460 to 1,550 cm⁻¹) was defined as an imidization index A of the resin, an imidization index B was calculated by the same method for a film obtained by raising the temperature at a temperature rising rate of 10° C./min in a nitrogen atmosphere and heating the film at 350° C. for 1 hour, and a value obtained by dividing the imidization index A by the imidization index B was calculated as an imidization rate of the resin.

### [Method for Measuring Weight-Average Molecular Weight (Mw) and Number-Average Molecular Weight (Mn)]

The weight-average molecular weight (Mw) and the number-average molecular weight (Mn) of the resins (A-1) to (A-20), (AC-1), (AC-2), and (AC-3) were measured by a gel permeation chromatography (GPC) method.

Specifically, the weight-average molecular weight (Mw) and the number-average molecular weight (Mn) were determined by using HLC-8420GPC (manufactured by Tosoh Corporation) and using TSK guard column Super AW-H and TSK Super AWM-H (two columns) (both manufactured by Tosoh Corporation) in series as columns. Using a lithium bromide (10 mmol/L)/phosphoric acid (30 mmol/L) NMP solution as an eluent, the polystyrene equivalent value was detected using a detector for ultraviolet rays (UV) having a wavelength of 275 nm.

### EXAMPLES AND COMPARATIVE EXAMPLES

In each of Examples, the components shown in the table below were mixed to obtain each of the resin compositions. Further, in each Comparative Example, components shown in the following table were mixed to obtain each of the comparative compositions.

Specifically, the content of each component described in the table was set to the amount (in terms of parts by mass) described in the column of “Parts by mass” of each column of the table. The amount of the solvent used was set to an amount at which the concentration of solid contents of the composition was the concentration of solid contents (% by mass) shown in the table, and a mixture obtained by mixing the solvents at the mixing ratio (mass ratio) shown in the column of “Ratio” was used.

The obtained resin composition and comparative composition were subjected to pressurization filtration using a polytetrafluoroethylene filter having a pore diameter of 0.8 μm.

In addition, in the table, the description of “-” indicates that the corresponding component is not contained in the composition.

TABLE 2

| | | | | Comparative | Comparative | | | | | |
|---|---|---|---|---|---|---|---|---|---|---|
| | | | Example | Example | Example | Example | Example | Example | Example | Example |
| | | | 1 | 2 | 2 | 2 | 3 | 4 | 5 | 6 |
| [symbol] | Resin | Type | A-1 | AC-1 | AC-2 | A-3 | A-4 | A-5 | A-6 | A-2 |
| | | Parts by mass | 85. [symbol] | [symbol] 0 | 80 | [symbol] . [symbol] | 78.5 | 81.5 | 83 | 81 |
| | [symbol] | Type | B-1 | B-1 | B-2 | [symbol] -2 | [symbol] -1 | [symbol] -1 | B-1 | B-1 |
| | compound | Parts by mass | 8.5 | [symbol] .0 | 5.0 | 7.5 | 10.5 | 7.5 | [symbol] .5 | 8.5 |
| | Polymerization | Type | C-1 | C-1 | C-1 | C-1 | C-1 | C-1 | C-1 | C-1 |
| | [symbol] | Parts by mass | 3.5 | [symbol] . [symbol] | 6.5 | 3.5 | 3.5 | 3.5 | 3.5 | [symbol] .5 |
| | Thermal-base | Type | — | — | — | — | D-1 | D-2 | — | — |
| | [symbol] | Parts by mass | — | — | — | — | 1 | 1 | — | — |
| | Polymerization | Type | E-1 | E-1 | E-1 | E- [symbol] | E-1 | E-1 | E-1 | E-3 |
| | [symbol] | Parts by mass | 0.5 | 0.5 | 0.5 | 0.5 | 0.5 | 0.5 | 0.5 | 0.5 |
| | Silicone coupling | Type | G-1 | G-1 | G-1 | G-1 | G-1 | G-1 | G-2 | G-2 |
| | agent | Parts by mass | 4.5 | 5.5 | 5.5 | 4.5 | 4.5 | 4.5 | 4.5 | 4.5 |
| | Migration | Type | F-1 | F-2 | F-2 | F-2 | F-3 | F-3 | — | — |
| | supporting agent | Parts by mass | 0.5 | 0.5 | 0.5 | 0.5 | 0.5 | 0.5 | — | — |
| | Additive | Type | — | H-1 | H-1 | H-1 | H-2 | H-1 | — | — |
| | | Parts by mass | — | 1 | 2 | 1 | 1 | 1 | — | — |
| | [symbol] | Type | — | — | — | — | — | — | — | — |
| | [symbol] | Parts by mass | — | — | — | — | — | — | — | — |
| | [symbol] | Type | — | — | — | — | — | — | — | — |
| | | Parts by mass | — | — | — | — | — | — | — | — |
| | Solvent | Type | GBL | GBL | GBL | GBL | GBL | GBL | GBL | NMP |
| | | Ratio | 100 | 100 | 100 | [symbol] 0 | [symbol] 0 | [symbol] 0 | [symbol] 0 | 100 |
| | | Type | — | — | — | DMSO | DMSO | DMSO | DMSO | — |
| | | Ratio | — | — | — | 20 | 20 | 20 | 20 | — |

| | | | | | | | | | |
|---|---|---|---|---|---|---|---|---|---|
| | Concentration of solid contents | 42 | 42 | 18 | 42 | 42 | 42 | 42 | 42 |
| | (% by mass) | | | | | | | | |
| [symbol] | Film thickness (μm) | 20 | 20 | 20 | 20 | 20 | 20 | 20 | 20 |
| | Developer | [symbol] | [symbol] | [symbol] | [symbol] | [symbol] | [symbol] | [symbol] | [symbol] |
| | [symbol] temperature (° C.) | 230 | 230 | 230 | 230 | 230 | 230 | 230 | 230 |
| | [symbol] time (min) | 180 | 180 | 180 | 180 | 180 | 180 | 180 | 180 |
| [symbol] | [symbol] | A | B | C | A | A | A | A | A |
| | Shrinkage ratio | A | C | B | A | A | B | A | A |
| | CTE | A | A | C | B | A | A | B | A |
| | Resolution | A | C | D | A | B | B | A | A |

| | | | Example | Example | Example | Example | Example | Example | Example | Example |
|---|---|---|---|---|---|---|---|---|---|---|
| | | | 7 | 8 | 9 | 10 | 11 | 12 | 13 | 14 |
| [symbol] | Resin | Type | A-7 | A-8 | A-9 | A-10 | A-11 | A-12 | A-13 | A-14 |
| | | Parts by mass | 80 | 80 | 80 | [symbol] 0 | [symbol] 0 | [symbol] 0 | [symbol] 0 | 79 |
| | [symbol] | Type | B-1 | B-1 | B-1 | B-1 | B-1 | B-1 | B-2 | B-1 |
| | compound | Parts by mass | 6.0 | [symbol] .0 | 10.5 | 8.5 | 1.03 | 10.3 | 10. [symbol] | 6.0 |
| | Polymerization | Type | C-1 | C-1 | C-2 | C-1 | C-1 | C-3 | C-1 | C-1 |
| | [symbol] | Parts by mass | [symbol] .5 | [symbol] .5 | [symbol] .5 | 4. [symbol] | 5.5 | [symbol] . [symbol] | [symbol] . [symbol] | 6.5 |
| | Thermal-base | Type | — | — | — | D-2 | D-3 | D-4 | — | — |
| | [symbol] | Parts by mass | — | — | — | 1 | 1 | 1 | — | — |
| | Polymerization | Type | E-1 | E-1 | [symbol] -1 | E-1 | E-1 | E-1 | E-2 | E-3 |
| | [symbol] | Parts by mass | 0. [symbol] | 0.5 | 0.2 | 0.2 | 0.5 | 0.2 | 0.5 | 0.5 |
| | Silicone coupling | Type | G-1 | G-1 | G-1 | G-2 | G-1 | G-1 | G-3 | G-1 |
| | agent | Parts by mass | 5.5 | 5.5 | 2.6 | 5.5 | 1.5 | 2 | 2 | 6.5 |
| | Migration | Type | F-2 | F-2 | F- [symbol] | F-3 | F-3 | F-4 | F-5 | F-3 |
| | supporting agent | Parts by mass | 0.5 | 0.5 | 0.2 | 0.2 | 0.2 | 0.2 | 0.5 | 0.5 |
| | Additive | Type | H-1 | H-1 | — | — | H-1 | — | — | H-2 |
| | | Parts by mass | 1 | 1 | — | — | — | — | — | 1 |
| | [symbol] | Type | — | — | — | — | — | — | — | — |
| | [symbol] | Parts by mass | — | — | — | — | — | — | — | — |
| | [symbol] | Type | — | — | — | — | — | — | — | — |
| | | Parts by mass | — | — | — | — | — | — | — | — |
| | Solvent | Type | GBL | GBL | GBL | GBL | NMP | GBL | GBL | NMP |
| | | Ratio | 100 | 100 | 80 | 80 | 80 | 80 | 80 | 100 |
| | | Type | — | — | DMSO | DMSO | [symbol] L | DMSO | DMSO | — |
| | | Ratio | — | — | 20 | 20 | 20 | 20 | 20 | — |

| | | | | | | | | | |
|---|---|---|---|---|---|---|---|---|---|
| | Concentration of solid contents | 42 | 42 | 42 | 42 | 42 | 42 | 42 | 42 |
| | (% by mass) | | | | | | | | |
| [symbol] | Film thickness (μm) | 20 | 20 | 20 | 20 | 20 | 20 | 20 | 20 |
| | Developer | [symbol] | [symbol] | [symbol] | [symbol] | [symbol] | [symbol] | [symbol] | [symbol] |
| | [symbol] temperature (° C.) | 230 | 230 | 230 | 230 | 230 | 230 | 230 | 230 |
| | [symbol] time (min) | 180 | 180 | 180 | 180 | 180 | 180 | 180 | 180 |
| [symbol] | [symbol] | A | B | A | A | A | A | A | A |
| | Shrinkage ratio | B | A | A | A | A | A | A | A |
| | CTE | A | A | A | A | A | A | A | B |
| | Resolution | B | B | A | A | A | A | A | A |

[symbol]

indicates data missing or illegible when filed

TABLE 3

| | | | Example | Example | Example | Example | Example | Example | Example | Example |
|---|---|---|---|---|---|---|---|---|---|---|
| | | | 15 | 16 | 17 | 18 | 19 | 20 | 21 | 22 |
| [symbol] | Resin | Type | A-15 | A-1 | A-4 | A-10 | A- [symbol] | A-1 | A-8 | A-1 |
| | | Parts by mass | 80 | [symbol] .1 | 79 | 80 | 81.5 | [symbol] .1 | 82.5 | 82.5 |
| | [symbol] | Type | B-1 | B-2 | B-3 | B-4 | B-1 | B-2 | B-1 | B-1 |
| | compound | Parts by mass | 10.0 | [symbol] .0 | 10.8 | [symbol] . [symbol] | [symbol] . [symbol] | 4.0 | 7.5 | 7.5 |
| | Polymerization | Type | C-1 | C-4 | C- [symbol] | C-6 | C-7 | C-4 | C-1/C-9 | C-1/C-10 |
| | [symbol] | Parts by mass | [symbol] . [symbol] | [symbol] . [symbol] | [symbol] . [symbol] | [symbol] | 3.5 | [symbol] . [symbol] | [symbol] .5/1. [symbol] | 2.0/1.5 |
| | Thermal-base | Type | D-5 | — | — | — | D-7 | — | — | — |
| | [symbol] | Parts by mass | 1 | — | — | — | 1 | — | — | — |
| | Polymerization | Type | E-1 | E-3 | E-3 | E-1 | E-1 | E- [symbol] | E-1 | E-1 |
| | [symbol] | Parts by mass | 0. [symbol] | 0.1 | 0. [symbol] | 0.5 | 0.5 | 0.1 | 0.5 | 0.5 |
| | Silicone coupling | Type | G-1 | G-1 | G-1 | G-1 | G- [symbol] | G-1 | G-1 | G-1 |
| | agent | Parts by mass | [symbol] | 1. [symbol] | 2. [symbol] | 2 | 4.5 | 1. [symbol] | 4. [symbol] | 4.5 |
| | Migration | Type | F-6 | F-3 | F-3 | F-3 | F-7 | F-3 | F-1 | F-8 |
| | supporting agent | Parts by mass | 0. [symbol] | 0.3 | 0.5 | 0.5 | 0.5 | 0.3 | 0.5 | 0.5 |
| | Additive | Type | — | — | H- [symbol] | H-1 | H-1 | — | H-1 | H-1 |
| | | Parts by mass | — | — | 1 | 1.5 | 1 | — | 1 | 1 |
| | [symbol] | Type | I-1 | I-1 | — | — | I-1 | I-1 | — | — |
| | | Parts by mass | 1 | 2 | — | — | 1 | 2 | — | — |
| | [symbol] | Type | — | — | — | — | — | — | — | — |
| | | Parts by mass | — | — | — | — | — | — | — | — |
| | Solvent | Type | NMP | GBL | GBL | GBL | GBL | GBL | GBL | GBL |
| | | Ratio | 100 | 100 | 100 | 100 | 100 | 100 | 80 | 100 |
| | | Type | — | — | — | — | — | — | DMSO | — |
| | | Ratio | — | — | — | — | — | — | 20 | — |

| | | | | | | | | | |
|---|---|---|---|---|---|---|---|---|---|
| | Concentration of solid contents | 38 | 42 | 42 | 42 | 42 | 42 | 42 | 42 |
| | (% by mass) | | | | | | | | |
| [symbol] | Film thickness (μm) | 20 | 20 | 20 | 15 | 20 | [symbol] 0 | [symbol] 0 | 20 |
| | Developer | [symbol] | [symbol] | [symbol] | [symbol] | [symbol] | [symbol] | [symbol] | [symbol] |
| | [symbol] temperature (° C.) | 230 | 230 | 230 | 180 | 1 [symbol] | 230 | 230 | 230 |
| | [symbol] time (min) | 180 | 180 | 180 | 120 | 120 | 180 | 180 | 180 |
| [symbol] | [symbol] | A | A | A | A | A | A | A | A |
| | Shrinkage ratio | A | A | A | A | A | A | A | A |
| | CTE | A | A | A | A | A | A | A | A |
| | Resolution | B | A | A | A | A | A | A | A |

| | | | Example | Example | Example | Example | Example | Example | Example |
|---|---|---|---|---|---|---|---|---|---|
| | | | 23 | 24 | 25 | 26 | 27 | 28 | 29 |
| [symbol] | Resin | Type | A- [symbol] | A-10 | A-2 | A-1 | A-1 | A- [symbol] | A-10 |
| | | Parts by mass | 82.5 | 80 | 82.5 | 82.5 | 82.5 | 82.5 | 81.5 |
| | [symbol] | Type | B-1 | B-1 | B-1 | B-1 | B-1 | B-1 | B-1 |
| | compound | Parts by mass | 7.5 | 8.5 | 7.5 | 7.5 | 7.5 | 7.5 | 7.5 |
| | Polymerization | Type | C-2/C-11 | C-1 | C-1 | C-1 | C-1 | C-2 | C-1 |
| | [symbol] | Parts by mass | 10./2.5 | 4. [symbol] | [symbol] . [symbol] | [symbol] .5 | [symbol] .5 | 3.5 | 3.5 |
| | Thermal-base | Type | — | D-6 | — | — | — | — | — |
| | [symbol] | Parts by mass | — | 180 | — | — | — | — | — |
| | Polymerization | Type | E-1 | E-1 | E-4 | E-1 | E-5 | E-1 | E-1 |
| | [symbol] | Parts by mass | 0.5 | 0. [symbol] | 0.5 | 0.5 | 0.5 | 0.5 | 0.5 |
| | Silicone coupling | Type | G-1 | G-2 | G-4 | G-5 | G-1 | G-1 | G-1 |
| | agent | Parts by mass | 4.5 | 5.5 | 4.5 | 4.5 | 4.5 | 4.5 | 4.5 |
| | Migration | Type | F-1 | F-3 | F-1 | F- [symbol] | F-1 | F-1 | F-1 |
| | supporting agent | Parts by mass | 0.5 | 0.2 | 0.5 | 0.5 | 0.5 | 0.5 | 0.5 |
| | Additive | Type | H-1 | — | H-1 | — | H-1 | H-3 | H- [symbol] |
| | | Parts by mass | 1 | — | 1 | — | 1 | 1 | 2 |
| | [symbol] | Type | — | — | — | I-2 | — | — | — |
| | | Parts by mass | — | — | — | 1 | — | — | — |
| | [symbol] | Type | — | — | — | — | — | — | — |
| | | Parts by mass | — | — | — | — | — | — | — |
| | Solvent | Type | GBL | GBL | GBL | NMP | GBL | NMP | NMP |
| | | Ratio | 80 | 80 | 80 | 100 | 100 | 80 | 80 |
| | | Type | DMSO | DMSO | DMSO | — | — | CP | CH |
| | | Ratio | 20 | 20 | [symbol] | — | — | 20 | 20 |

| | | | | | | | | |
|---|---|---|---|---|---|---|---|---|
| | Concentration of solid contents | 42 | 42 | 42 | 42 | 42 | 42 | 42 |
| | (% by mass) | | | | | | | |
| [symbol] | Film thickness (μm) | 20 | 20 | [symbol] 0 | [symbol] 0 | 20 | 20 | 20 |
| | Developer | [symbol] | [symbol] | [symbol] | [symbol] | [symbol] | [symbol] | [symbol] |
| | [symbol] temperature (° C.) | 230 | 230 | 230 | 230 | 230 | 230 | 230 |
| | [symbol] time (min) | 1 [symbol] 0 | 180 | 180 | 180 | 180 | 180 | 180 |
| [symbol] | [symbol] | A | A | A | A | A | A | A |
| | Shrinkage ratio | A | A | A | A | A | A | A |
| | CTE | A | A | A | A | A | A | A |
| | Resolution | A | A | A | A | A | A | A |

[symbol]

indicates data missing or illegible when filed

TABLE 4

| | | | Example | Example | Example | Example | Example | Example | Example | Example |
|---|---|---|---|---|---|---|---|---|---|---|
| | | | 30 | 31 | 32 | 33 | 34 | 35 | 36 | 37 |
| [symbol] | Resin | Type | A-11 | A-1 | A-1 | A-10 | A-1 | A- [symbol] | A-10 | A-11 |
| | | Parts by mass | 8.1 [symbol] | 89.1 | [symbol] . [symbol] | [symbol] . [symbol] | 83.5 | 82.5 | 82.5 | 82.5 |
| | [symbol] | Type | B-1 | B-1 | B-1 | B-1 | B-1 | B-1 | B-2 | B-1 |
| | compound | Parts by mass | 7.5 | 4.0 | 4.0 | 4.0 | 7.5 | 7.5 | 7.5 | 7.5 |
| | Polymerization | Type | C-1 | C-12 | C-12 | C-12 | C-1 | C-1 | C-1 | C-1 |
| | [symbol] | Parts by mass | [symbol] .5 | 2.9 | 2.9 | 2.9 | 3.5 | 3.5 | 3.5 | 3.5 |
| | Thermal-base | Type | — | — | — | — | — | — | — | — |
| | [symbol] | Parts by mass | — | — | — | — | — | — | — | — |
| | Polymerization | Type | E-4 | E-1 | E-3 | E-3 | E-2 | E-1 | E-1 | E-1 |
| | [symbol] | Parts by mass | 0.5 | 0.1 | 0.1 | 0.1 | 0.5 | 0.5 | 0.5 | 0.5 |
| | Silicone coupling | Type | G-1 | G-1 | G-1 | G-1 | G-1 | G-1 | G-1 | G-1 |
| | agent | Parts by mass | 4.5 | 1.6 | 1.6 | 1.6 | 4.5 | 4.5 | 4.5 | 4.5 |
| | Migration | Type | F-1 | F-4 | F-4 | F-4 | F-1 | F-1 | F-1 | F-1 |
| | supporting agent | Parts by mass | 0.5 | 0.3 | 0.3 | 0.3 | 0.5 | 0.5 | 0.5 | 0.5 |
| | Additive | Type | H-5 | — | — | — | — | — | — | — |
| | | Parts by mass | [symbol] .5 | — | — | — | — | — | — | — |
| | [symbol] | Type | — | I-1 | I-3 | I-4 | — | I-5 | I-6 | I-7 |
| | [symbol] | Parts by mass | — | 2 | 2 | 2 | — | 1 | 1 | 1 |
| | [symbol] | Type | — | — | — | — | — | — | — | — |
| | | Parts by mass | — | — | — | — | — | — | — | — |
| | Solvent | Type | GVL | GBL | GBL | GBL | [symbol] | GBL | GBL | NMP |
| | | Ratio | 80 | 100 | 100 | 100 | [symbol] | 100 | 100 | 100 |
| | | Type | DMSO | — | — | — | GBL | — | — | — |
| | | Ratio | 20 | — | — | — | 70 | — | — | — |
| | Concentration of solid contents | | 42 | 42 | 42 | 42 | 42 | 42 | 42 | 42 |
| | (% by mass) | | | | | | | | | |
| [symbol] | Film thickness (μm) | | 20 | [symbol] 0 | [symbol] 0 | [symbol] 0 | [symbol] 0 | [symbol] 0 | [symbol] 0 | [symbol] 0 |
| | Developer | | [symbol] | [symbol] | [symbol] | [symbol] | [symbol] | [symbol] | [symbol] | [symbol] |
| | [symbol] temperature (° C.) | | 230 | 230 | 180 | 180 | 230 | 230 | 230 | 230 |
| | [symbol] time (min) | | 180 | 180 | 120 | 120 | 180 | 180 | 180 | 180 |
| [symbol] | [symbol] | | A | A | A | A | A | A | A | A |
| | Shrinkage ratio | | A | A | A | A | A | A | A | A |
| | CTE | | A | A | A | A | A | A | A | A |
| | Resolution | | A | A | A | A | A | A | A | A |
| | | | Example | Example | Example | Example | Example | Example | Example | Example |
| | | | 38 | 39 | 40 | 41 | 42 | 43 | 44 | 45 |
| [symbol] | Resin | Type | A-12 | A-16 | A-17 | A-1 [symbol] | A-1 [symbol] | A-1 [symbol] | A-17 | A-1 [symbol] |
| | | Parts by mass | 89. [symbol] | 82.5 | 82.5 | 82.5 | 82.5 | 89.1 | 89.1 | 89.1 |
| | [symbol] | Type | B-2 | B-1 | B-1 | B-1 | B-1 | B-1 | B-1 | B-1 |
| | compound | Parts by mass | 4.0 | 7.5 | 7.5 | 7.5 | 7.5 | 4.0 | 4.0 | 4.0 |
| | Polymerization | Type | C-4 | C-3 | C-3 | C- [symbol] | C- [symbol] | C-12 | C-12 | C-12 |
| | [symbol] | Parts by mass | 2.9 | 3.5 | 3.5 | 3.5 | 3.5 | 2.9 | 2.9 | 2.9 |
| | Thermal-base | Type | — | — | — | — | — | — | — | — |
| | [symbol] | Parts by mass | — | — | — | — | — | — | — | — |
| | Polymerization | Type | E- [symbol] | E-1 | E-1 | E-1 | E-1 | E-3 | E-3 | E-3 |
| | [symbol] | Parts by mass | 0.1 | 0.5 | 0.5 | 0.5 | 0.5 | 0.1 | 0.1 | 0.1 |
| | Silicone coupling | Type | G-1 | G-1 | G-1 | G-1 | G-1 | G-1 | G-1 | G-1 |
| | agent | Parts by mass | 1.6 | 4.5 | 4.5 | 4.5 | 4.5 | 1.6 | 1.6 | 1.6 |
| | Migration | Type | F-3 | F-1 | F-1 | F-1 | F-1 | F-4 | F-4 | F-4 |
| | supporting agent | Parts by mass | 0.3 | 0.5 | 0.5 | 0.5 | 0.5 | 0.3 | 0.3 | 0.3 |
| | Additive | Type | — | H-1 | H-2 | H-1 | H-1 | — | — | — |
| | | Parts by mass | — | 1 | 1 | 1 | 1 | — | — | — |
| | [symbol] | Type | I-8 | — | — | — | — | I-8 | I-8 | I-8 |
| | [symbol] | Parts by mass | 1 | — | — | — | — | 2 | 2 | 2 |
| | [symbol] | Type | — | — | — | — | — | J-1 | J-2 | J- [symbol] |
| | | Parts by mass | — | — | — | — | — | 0.01 | 0.01 | 0.01 |
| | Solvent | Type | GBL | GBL | GBL | NMP | NMP | GBL | GBL | NMP |
| | | Ratio | 100 | 100 | 100 | 100 | 100 | 100 | 100 | 100 |
| | | Type | | — | — | — | — | — | — | — |
| | | Ratio | | — | — | — | — | — | — | — |

| | | | | | | | | | |
|---|---|---|---|---|---|---|---|---|---|
| | Concentration of solid contents | 42 | 42 | 42 | 42 | 42 | 42 | 42 | 42 |
| | (% by mass) | | | | | | | | |
| [symbol] | Film thickness (μm) | [symbol] 0 | [symbol] 0 | 20 | 20 | 20 | 20 | 20 | 20 |
| | Developer | [symbol] | [symbol] | [symbol] | [symbol] | [symbol] | [symbol] | [symbol] | [symbol] |
| | [symbol] temperature (° C.) | 230 | 230 | 230 | 230 | 230 | 230 | 230 | 230 |
| | [symbol] time (min) | 180 | 180 | 180 | 180 | 180 | 180 | 180 | 180 |
| [symbol] | [symbol] | A | A | A | A | A | A | A | A |
| | Shrinkage ratio | A | A | A | A | A | A | A | A |
| | CTE | A | A | A | A | A | A | A | A |
| | Resolution | A | A | A | A | A | A | A | A |

[symbol]

indicates data missing or illegible when filed

TABLE 5

| | | | Example | Example | Example | Example | Example | Example | Example |
|---|---|---|---|---|---|---|---|---|---|
| | | | 46 | 47 | 48 | 49 | 50 | 51 | 52 |
| [symbol] | Resin | Type | A-20 | A-18/A-20 | A-7/A-8 | A-1 | A-1 | A-1/A [symbol] -3 | A-1 |
| | | Parts by mass | 89.1 | 45/44.1 | 50/39.1 | 92.6 | 91.7 | 62.5/20.0 | 91.7 |
| | [symbol] | Type | B-1 | B-1 | B-1 | B-1 | B-1 | B-1 | B-1/B-4 |
| | compound | Parts by mass | 4.0 | 4.0 | 4.0 | 0.5 | 1.4 | 8.5 | 0.7/0.7 |
| | Polymerization | Type | C-12 | C-12 | C-12 | C-12 | C-12 | C-1 | C-12 |
| | [symbol] | Parts by mass | 2.9 | 2.9 | 2.9 | 2.9 | 2.9 | 3.5 | 2.9 |
| | Thermal-base | Type | — | — | — | — | — | — | — |
| | [symbol] | Parts by mass | — | — | — | — | — | — | — |
| | Polymerization | Type | E-3 | E-3 | E-3 | E-3 | E-3 | E-1 | E- [symbol] |
| | [symbol] | Parts by mass | 0.1 | 0.1 | 0.1 | 0.1 | 0.1 | 0.5 | 0.1 |
| | Silicone coupling | Type | G-1 | G-1 | G-1 | G-1 | G-1 | G-1 | G-1 |
| | agent | Parts by mass | 1.6 | 1. [symbol] | 1.8 | 1.6 | 1.6 | 4.5 | 1.6 |
| | Migration | Type | F-4 | F-4 | F-4 | F-4 | F-4 | F-4 | F-4 |
| | supporting agent | Parts by mass | 0.3 | 0.3 | 0.3 | 0.3 | 0.3 | 0.3 | 0.3 |
| | Additive | Type | — | — | — | — | — | — | — |
| | | Parts by mass | — | — | — | — | — | — | — |
| | [symbol] | Type | I-1 | I- [symbol] | I- [symbol] | I-8 | T-7 | — | I-7 |
| | | Parts by mass | 2 | 2 | 2 | 2 | 2 | — | [symbol] |
| | [symbol] | Type | — | — | — | — | — | — | — |
| | | Parts by mass | — | — | — | — | — | — | — |
| | Solvent | Type | GBL | GBL | GBL | GBL | GBL | GBL | GBL |
| | | Ratio | 100 | 100 | 100 | 100 | 100 | 100 | 100 |
| | | Type | — | — | — | — | — | — | — |
| | | Ratio | — | — | — | — | — | — | — |

| | | | | | | | | |
|---|---|---|---|---|---|---|---|---|
| | Concentration of solid contents | 42 | 42 | 42 | 42 | 42 | 42 | 42 |
| | (% by mass) | | | | | | | |
| [symbol] | Film thickness (μm) | 2 [symbol] | 20 | 20 | 20 | 20 | 20 | 20 |
| | Developer | [symbol] | [symbol] | [symbol] | [symbol] | [symbol] | [symbol] | [symbol] |
| | [symbol] temperature (° C.) | 230 | 230 | 230 | 230 | 230 | 230 | 230 |
| | [symbol] time (min) | 180 | 180 | 180 | 180 | 180 | 180 | 180 |
| [symbol] | [symbol] | A | A | A | A | A | A | A |
| | Shrinkage ratio | A | A | A | A | A | A | A |
| | CTE | A | A | A | A | A | A | A |
| | Resolution | A | A | A | B | A | A | A |

| | | | Example | Example | Example | Example | Example | Example |
|---|---|---|---|---|---|---|---|---|
| | | | 53 | 54 | 55 | 56 | 57 | 58 |
| [symbol] | Resin | Type | A-9 | A-21 | A-22 | A-23 | A-24 | A-15 |
| | | Parts by mass | 80 | 89.1 | 89.1 | 89.1 | 89.1 | 80 |
| | [symbol] | Type | B-1/B-2 | B-1 | B-1 | B-1 | B-1 | B-1 |
| | compound | Parts by mass | 7.0/3.5 | 4.0 | 4.0 | 4.0 | 4.0 | [symbol] .0 |
| | Polymerization | Type | C-2 | C-12 | C-12 | C-12 | C-12 | C-1 |
| | [symbol] | Parts by mass | 6. [symbol] | 2.0 | 2. [symbol] | 2.0 | 2. [symbol] | 6. [symbol] |
| | Thermal-base | Type | — | — | — | — | — | — |
| | [symbol] | Parts by mass | — | — | — | — | — | — |
| | Polymerization | Type | E-1 | E-3 | E-3 | E-3 | E-3 | E-1 |
| | [symbol] | Parts by mass | 0.2 | 0. [symbol] | 0.1 | 0.1 | 0. [symbol] | 0. [symbol] |
| | Silicone coupling | Type | G-1 | G-1 | G-1 | G-1 | G-1 | G-1 |
| | agent | Parts by mass | 2.6 | 1.6 | 1. [symbol] | 1. [symbol] | 1. [symbol] | 2 |
| | Migration | Type | F-4 | F-4 | F-4 | F-4 | F-4 | F-6 |
| | supporting agent | Parts by mass | 0.3 | 0.3 | 0.3 | 0.3 | 0.3 | 0.2 |
| | Additive | Type | — | — | — | — | — | — |
| | | Parts by mass | — | — | — | — | — | — |
| | [symbol] | Type | — | I-1 | I-8 | I-8 | I-8 | I-1 |
| | | Parts by mass | — | 2 | 2 | 2 | 2 | 1 |
| | [symbol] | Type | — | — | — | — | — | — |
| | | Parts by mass | — | — | — | — | — | — |
| | Solvent | Type | GBL | GBL | GBL | GBL | GBL | NMP |
| | | Ratio | 100 | 100 | 100 | 100 | 100 | 100 |
| | | Type | — | — | — | — | — | — |
| | | Ratio | — | — | — | — | — | — |

| | | | | | | | |
|---|---|---|---|---|---|---|---|
| | Concentration of solid contents | 42 | 42 | 42 | 42 | 42 | 42 |
| | (% by mass) | | | | | | |
| [symbol] | Film thickness (μm) | 20 | 20 | 20 | 20 | 20 | 20 |
| | Developer | [symbol] | [symbol] | [symbol] | [symbol] | [symbol] | [symbol] |
| | [symbol] temperature (° C.) | 230 | 230 | 230 | 230 | 230 | 230 |
| | [symbol] time (min) | 180 | 180 | 180 | 180 | 180 | 180 |
| [symbol] | [symbol] | A | A | A | A | A | B |
| | Shrinkage ratio | A | A | A | A | A | A |
| | CTE | A | A | A | A | A | A |
| | Resolution | A | A | A | A | A | B |

[symbol]

indicates data missing or illegible when filed

### [Resin]

A-1 to A-24: Resins (A-1) to (A-24) synthesized above
AC-1, AC-2, and AC-3: Resins (AC-1), (AC-2), and (AC-3) synthesized above

A-1 to A-24 are compounds corresponding to the specific resin.

AC-1, AC-2, and AC-3 are compounds that do not correspond to the specific resin.

### [Polymerizable Compound]

B-1: SR-209 (manufactured by Sartomer Company Inc.)
B-2: ADPH: dipentaerythritol hexaacrylate (manufactured by Shin-Nakamura Chemical Co., Ltd.)
B-3: compound having the following structure
B-4: compound having the following structure

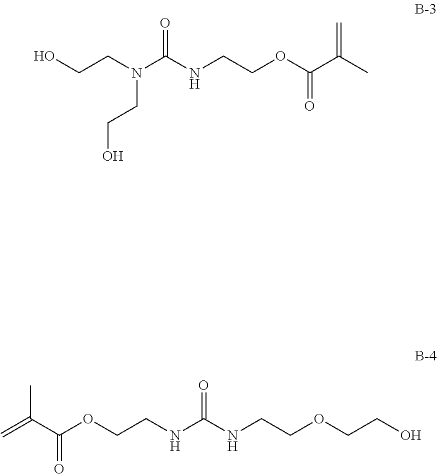

### [Polymerization Initiator]

C-1: IRGACURE OXE-01 (manufactured by BASF SE)
C-2: IRGACURE OXE-02 (manufactured by BASF SE)
C-3: IRGACURE 369 (manufactured by BASF SE)
C-4: compound having the following structure
C-5: compound having the following structure
C-6: compound having the following structure
C-7: Omnirad 1312 (manufactured by IGM Resins B.V.)
C-8: Omnirad TPO H (manufactured by IGM Resins B.V.)
C-9: CPI-310FG (manufactured by San-Apro Ltd.)
C-10: CPI-310B (manufactured by San-Apro Ltd.)
C-11: benzoyl peroxide (manufactured by Tokyo Chemical Industry Co., Ltd.)
C-12: TR-PBG-301

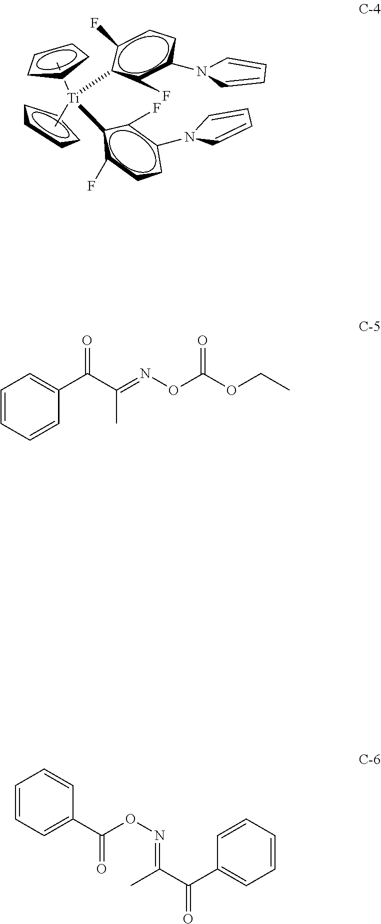

### [Thermal-Base Generator]

D-1 to D-7: compounds represented by Formulae (D-1) to (D-7)

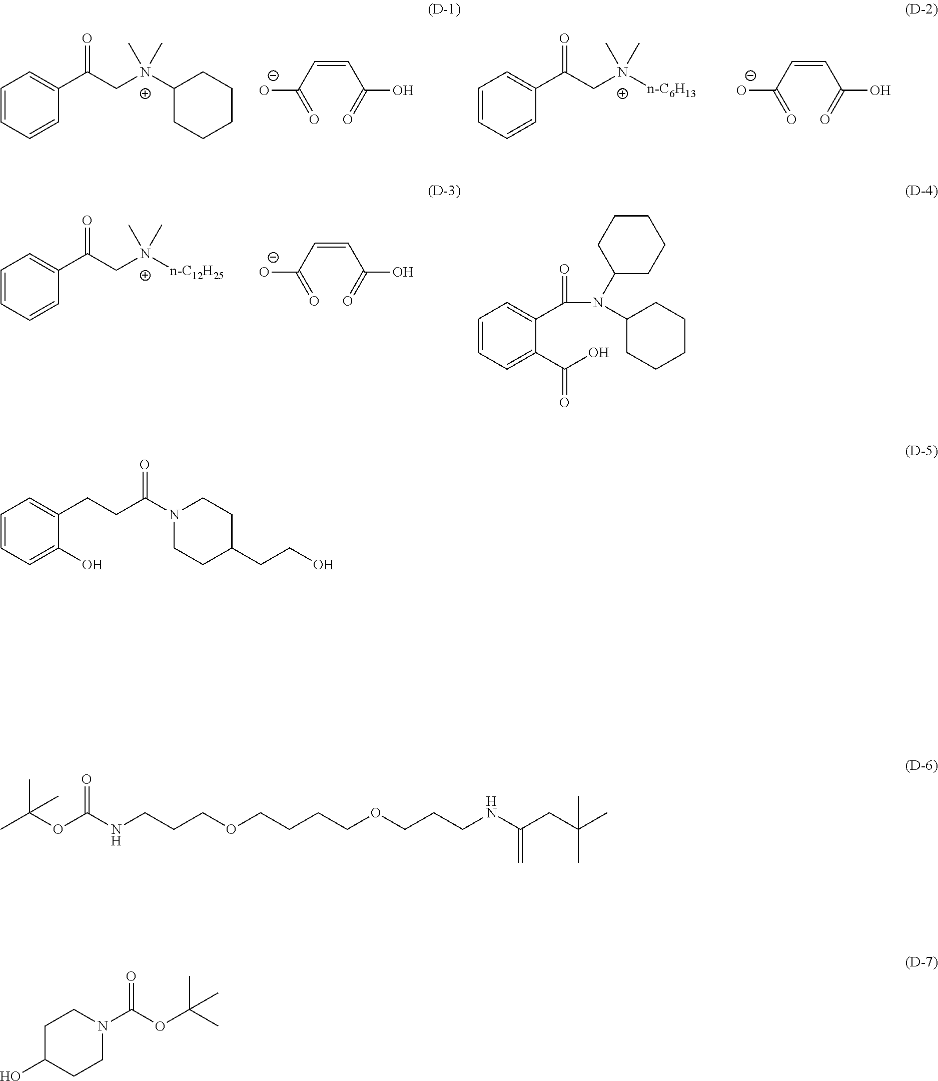

### [Polymerization Inhibitor]

E-1: 2-nitroso-1-naphthol (manufactured by Tokyo Chemical Industry Co., Ltd.)
E-2: parabenzoquinone (manufactured by Tokyo Chemical Industry Co., Ltd.)
E-3: paramethoxyphenol (manufactured by Tokyo Chemical Industry Co., Ltd.)
E-4: compound having the following structure
E-5: compound having the following structure

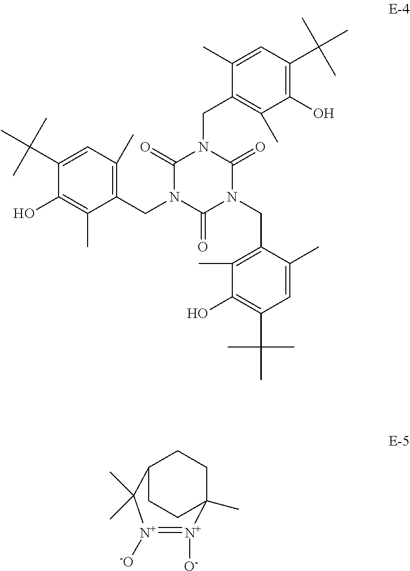

### [Migration Suppressing Agent]

F-1 to F-9: compound having the following structure

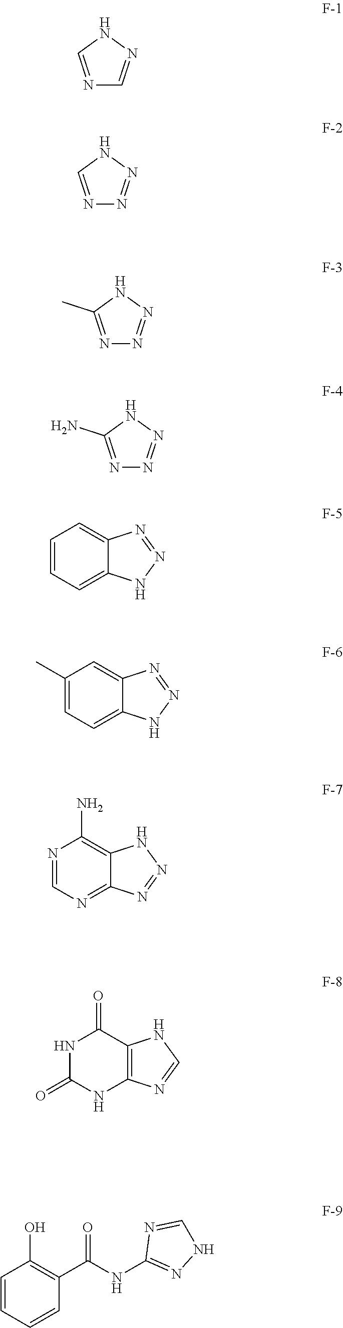

### [Silane Coupling Agent]

G-1 to G-4: compound having the following structure (here, in the following structural formulae, Et represents an ethyl group)
G-5: X-12-1293 (manufactured by Shin-Etsu Chemical Co., Ltd.)
G-6: KR-513 (manufactured by Shin-Etsu Chemical Co., Ltd.)

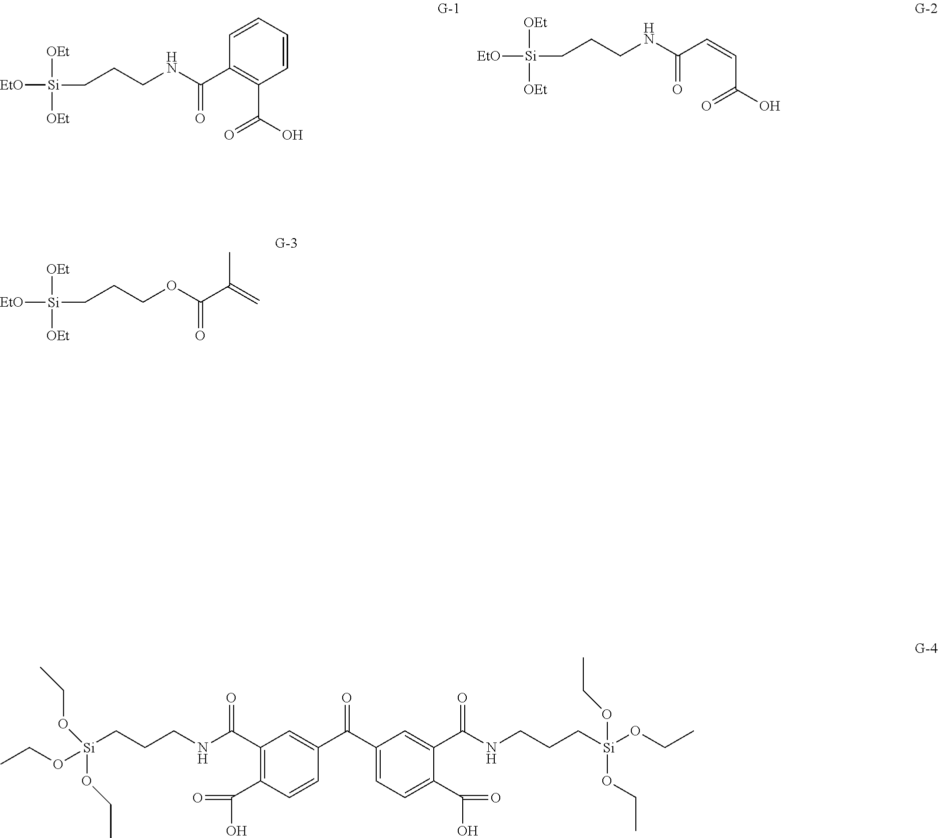 [SMILES: CCO[Si](CCCNC(=O)c1ccccc1C(=O)O)(OCC)OCC ; CCO[Si](CCCNC(=O)/C=C\C(=O)O)(OCC)OCC ; C=C(C)C(=O)OCCC[Si](OCC)(OCC)OCC ; CCO[Si](CCCNC(=O)c1cc(C(=O)c2ccc(C(=O)O)c(C(=O)NCCC[Si](OCC)(OCC)OCC)c2)ccc1C(=O)O)(OCC)OCC]

### [Solvent]

GBL: γ-butyrolactone
DMSO: dimethyl sulfoxide
NMP: N-methyl-2-pyrrolidone
EL: Ethyl lactate
GVL: γ-valerolactone
MDMPA: KJCMPA-100 (manufactured by KJ Chemicals Co., Ltd., 3-methoxy-N,N-dimethylpropanamide)
CP: cyclopentanone
CH: cyclohexanone

### [Additive]

H-1: compound represented by Formula (H-1)
H-2: N-phenyldiethanolamine
H-3: compound having the following structure
H-4: compound having the following structure
H-5: compound having the following structure (synthesized based on the following synthesis method)

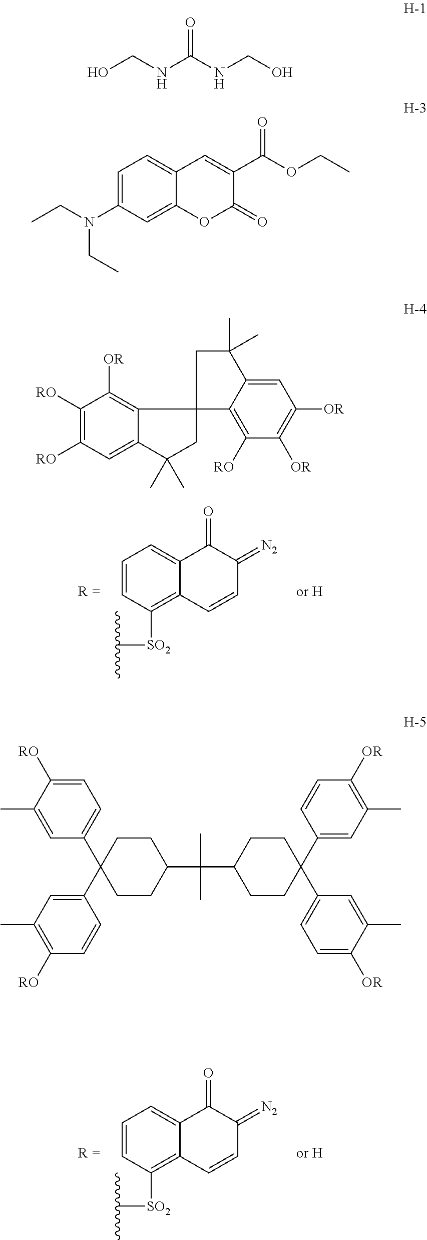

### [Synthesis Method of H-5]

29.72 g (70 mmol) of 4,4′-((1-(2-(4-hydroxyphenyl)-2-propyl)phenyl)ethylidene)bisphenol (manufactured by Honshu Chemical Industry Co., Ltd.: Tris-PA) was added to a flask. Subsequently, 46.93 g (174.9 mmol) of 1,2-naphthoquinone diazide-5-sulfonic acid chloride and 17.9 g of triethylamine were dissolved in 300 g of acetone with stirring, the solution was added dropwise to the flask using a dropping funnel for 30 minutes, and the solution was stirred at an internal temperature of 30° C. for 30 minutes. Subsequently, hydrochloric acid was added dropwise, and the mixture was further stirred for 30 minutes. Subsequently, a solution of 1640 g of pure water and 30 g of hydrochloric acid was prepared in a beaker, the filtrate obtained by filtering the hydrochloride in the reaction solution was added dropwise thereto, the precipitate was filtered, washed with water, and vacuum-dried at 40° C. for 50 hours to obtain a diazonaphthoquinone compound H-5.

### [Titanium Compound]

I-1: TC-750 (manufactured by Matsumoto Fine Chemical Co., Ltd.)
I-2: TC-401 (manufactured by Matsumoto Fine Chemical Co., Ltd.)
I-3: TC-800 (manufactured by Matsumoto Fine Chemical Co., Ltd.)
I-4: TC-810 (manufactured by Matsumoto Fine Chemical Co., Ltd.)
I-5 to I-8: compounds having the following structures

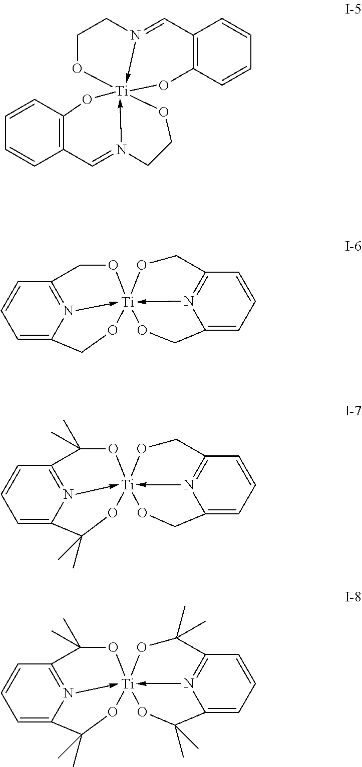

### [Surfactant]

J-1: F-554 (manufactured by DIC Corporation)
J-2: BYK-3760 (manufactured by BYK-Chemie GmbH)
J-3: BYK-333 (manufactured by BYK-Chemie GmbH)

### <Evaluations>

### [Evaluation of Coatability]

Each resin composition or each comparative composition prepared in each of Examples and Comparative Examples was spin-coated on a 4-inch silicon wafer at 1,000 rpm, and heated on a hot plate at 100° C. for 5 minutes to form a film. The surface of the obtained wafer was observed, and the coatability was evaluated by visual observation or using an optical microscope. In a case where the evaluation is A or B, it can be said that the unevenness during coating is suppressed, and in a case where the evaluation is A, it can be said that the unevenness during coating is further suppressed.

### (Evaluation Standard)

A: no foreign substances were observed on the surface.

B: some foreign substances were observed on the surface.

C: foreign substances were observed on the entire surface.

### [Evaluation of Shrinkage Ratio]

Each of the resin compositions or comparative compositions in Examples and Comparative Examples was applied onto a silicon wafer by a spin coating method to form a resin composition layer. The silicon wafer to which the obtained resin composition layer was applied was dried on a hot plate at 100° C. for 5 minutes, thereby obtaining a uniform curable resin composition layer having a thickness of about 15 μm on the silicon wafer. The film thickness of the curable resin composition layer was measured using a reflection spectroscopic film thickness meter (FE-3000, manufactured by Otsuka Electronics Co., Ltd.), and this value was defined as a “film thickness A”.

Subsequently, the entire surface of the obtained curable resin composition layer was exposed to i-rays at an exposure energy of 500 mJ/cm² using a stepper (Nikon NSR 2005 i9C).

The curable resin composition layer (resin layer) after the above-described exposure was heated at a temperature rising rate of 10° C./min in a nitrogen atmosphere, heated at a temperature and for a time described in the columns of “Cure temperature (° C.)” and “Cure time (min)” in the table, and cooled to 25° C. to obtain a cured product.

The film thickness of the cured product was measured using a reflection spectroscopic film thickness meter (FE-3000, manufactured by Otsuka Electronics Co., Ltd.), and this value was defined as a “film thickness B”. From the following calculation formula, the shrinkage ratio of the film was calculated.

$$shrinkage ratio ( \% ) = 100 - ( film thickness B + film thickness A \times 100 ) \qquad Calculation formula$$

The evaluation was performed according to the following evaluation standard, and the evaluation results are described in the column of “Shrinkage ratio” in the table. It can be said that the smaller the value of the above-described shrinkage ratio, the better the curing shrinkage properties of the obtained composition layer.

### (Evaluation Standard)

A: The shrinkage ratio was less than 15%.

B: The shrinkage ratio was 15% or more and less than 30%.

C: The shrinkage ratio was 30% or more.

### [Evaluation of Coefficient of Thermal Expansion (CTE)]

Each of the resin compositions or comparative compositions in Examples and Comparative Examples was applied onto a silicon wafer by a spin coating method to form a resin composition layer. The silicon wafer to which the obtained resin composition layer was applied was dried on a hot plate at 110° C. for 5 minutes, and a resin composition layer having a uniform thickness of a film thickness described in the column of “Film thickness (m)” in the table was obtained on the silicon wafer after film formation.

The obtained resin composition layer was exposed with an USHIO exposure machine (light source: 500 W/m², ultra-high pressure mercury lamp) using a dumbbell-shaped mask at an exposure energy of 400 mJ/cm². The dumbbell shape was set to a dumbbell-shape No. 7 shape, which is described in JIS K 6251: 2017.

The resin composition layer (resin layer) after the exposure was developed with a developer described in the column of “Developer” in the table until the non-exposed portion was removed, and rinsed with PGMEA for 30 seconds. Further, the temperature was raised at a temperature rising rate of 10° C./min in a nitrogen atmosphere, and heating was carried out at a temperature and a time described in the columns of “Cure temperature (° C.)” and “Cure time (min)” in the table. The resin layer (cured product) after curing was immersed in a 4.9% by mass aqueous hydrofluoric acid solution, and a cured product (test piece) having a dumbbell shape was peeled off from the silicon wafer (specimen width: 2 mm, specimen length: 35 mm).

The CTE of the test piece produced above at 25° C. to 125° C. was measured with TMA450 (TA Instruments). The temperature rising and falling conditions at the time of evaluation were set to the following (1) to (4).

(1) The temperature was raised from room temperature to 130° C. at a temperature rising rate of 5° C./min.

(2) The temperature was lowered from 130° C. to 10° C. at a temperature lowering rate of 5° C./min.

(3) The temperature was raised from 10° C. to 300° C. at a temperature rising rate of 5° C./min.

(4) The sample was naturally cooled to room temperature.

In the above-described temperature rising and falling processes (1) to (4), the elongation (displacement) of the specimen was measured, and a calculation was carried out to determine a value obtained by dividing the elongation (displacement) of the specimen at 25° C. and 125° C. in the process (3) by the temperature, where the value was defined as the coefficient of thermal expansion.

(Example: In a case where the length of the specimen at 25° C. was 50 mm, and the length of the specimen at 125° C. was 50.2 mm, the displacement was calculated as 0.4%=4,000 ppm, and the coefficient of thermal expansion was calculated as 4,000/(125−25)=40 ppm/° C.)

The obtained CTE was evaluated according to the following evaluation standards, and the evaluation results were described in the column of “CTE” in the table.

### (Evaluation Standard)

A: CTE was less than 30 ppm/° C.

B: CTE was 30 ppm/° C. or more and less than 55 ppm/° C.

C: CTE was more than 55 ppm/° C.

### [Evaluation of Resolution]

The resin composition used in each of Examples and Comparative Examples was applied in a layer shape to the surface of the thin copper layer of the resin base material on which the thin copper layer was formed on the surface by a spin coating method, dried at 110° C. for 5 minutes, and a resin composition layer having a film thickness after film formation, which is described in the column of “Film thickness (m)” in the table, was formed. Then, the obtained resin composition layer was exposed to each exposure amount in a range of 100 to 800 mJ/cm² at 50 mJ/cm² intervals using an i-ray stepper (manufactured by Canon Inc.: FPA-3000 i5, NA=0.5, σ=0.7) using a square via mask in which a pattern having a size of 0.5 to 10 μm in increments of 0.5 μm was formed. Subsequently, development was performed with the developer described in the column of “Developer” in the table until the non-exposed portion was removed, rinsing was performed with PGMEA for 30 seconds, and the temperature was raised at a temperature rising rate of 10° C./min in a nitrogen atmosphere, and heating was performed at the temperature and time described in the columns of “Cure temperature (° C.)” and “Cure time (min)” in the table.

The minimum opening mask diameter of the obtained cured product was determined by observing the cross section of the opening pattern portion with a scanning electron microscope S-4800 (manufactured by Hitachi High-Technologies Corporation), and evaluated according to the following evaluation standard. The minimum opening mask diameter was the smallest among the mask diameters in which the opening pattern was formed with at least one exposure amount among the above-described exposure amounts. The evaluation results are described in the column of “Resolution” in the table.

### (Evaluation Standard)

A: The minimum opening mask diameter was 3 μm or less.

B: The minimum opening mask diameter was more than 3 μm and 5 μm or less.

C: The minimum opening mask diameter was more than 5 μm and 7 μm or less.

D: The minimum opening mask diameter was more than 7 μm.

From the above results, it was found that the unevenness during coating and the shrinkage during curing were suppressed by using the resin composition according to the embodiment of the present invention. In comparison with this, it was found that the cured products obtained from the compositions according to Comparative Examples 1 and 2, which did not contain a resin having a predetermined imidization rate, were inferior in any of the unevenness during coating and the shrinkage during curing.

### Example 1001

The resin composition used in Example 1 was applied in a layer shape onto a surface of a thin copper layer of the resin base material on the surface of which the thin copper layer was formed, by a spin coating method, dried at 100° C. for 5 minutes, and after forming a photosensitive film having a thickness of 20 μm, exposure was carried out using a stepper (NSR1505 i6, manufactured by Nikon Corporation). Exposure was carried out through a mask (a binary mask in which the pattern is a pattern of 1:1 line and space and the line width is 10 μm) at a wavelength of 365 nm. After the exposure, the layer was developed with cyclopentanone for 2 minutes and rinsed with PGMEA for 30 seconds to obtain a layer pattern.

Next, the temperature was raised at a temperature rising rate of 10° C./min in a nitrogen atmosphere, and after the temperature reached 230° C., the temperature was maintained at 230° C. for 180 minutes, thereby forming an interlayer insulating film for a re-distribution layer. This interlayer insulating film for a re-distribution layer was excellent in insulating properties.

In addition, in a case where a semiconductor device was manufactured using this interlayer insulating film for a re-distribution layer, it has been confirmed that the semiconductor device operates without any problem.

What is claimed is:

1. A resin composition comprising:
a resin having at least one repeating unit selected from the group consisting of a repeating unit represented by Formula (1-2), a repeating unit represented by Formula (1-3), and a repeating unit represented by Formula (1-4);
a polymerization initiator; and
a solvent,
wherein an imidization rate of the resin is 40% to 85%, 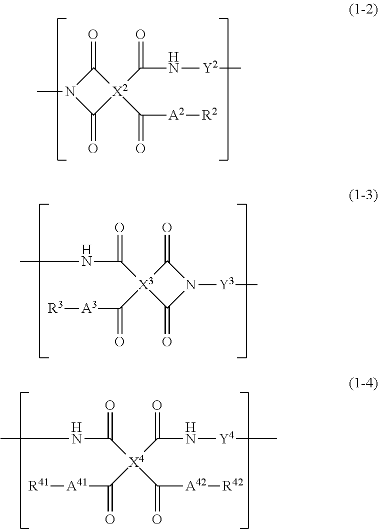
in Formula (1-2), A² is —O— or —NR^{Z}—, R^{Z} is a hydrogen atom or a monovalent organic group, R² is a hydrogen atom or a monovalent organic group, X² is a tetravalent organic group, and Y² is a divalent organic group,
in Formula (1-3), A³ is —O— or —NR^{Z}—, R^{Z} is a hydrogen atom or a monovalent organic group, R³ is a hydrogen atom or a monovalent organic group, X³ is a tetravalent organic group, and Y³ is a divalent organic group, and
in Formula (1-4), A⁴¹ and A⁴² are each independently —O— or —NR^{Z}—, R^{Z} is a hydrogen atom or a monovalent organic group, R⁴¹ and R⁴² are each independently a hydrogen atom or a monovalent organic group, X⁴ is a tetravalent organic group, and Y⁴ is a divalent organic group.

2. The resin composition according to claim 1,
wherein the resin includes at least one repeating unit selected from the group consisting of a repeating unit A-2, a repeating unit A-3, and a repeating unit A-4,
repeating unit A-2: a repeating unit represented by Formula (1-2), in which X² is any of structures represented by Formulae (2a) to (2g),
repeating unit A-3: a repeating unit represented by Formula (1-3), in which X³ is any of structures represented by Formulae (2a) to (2g),
repeating unit A-4: a repeating unit represented by Formula (1-4), in which X⁴ is any of structures represented by Formulae (2a) to (2g), and 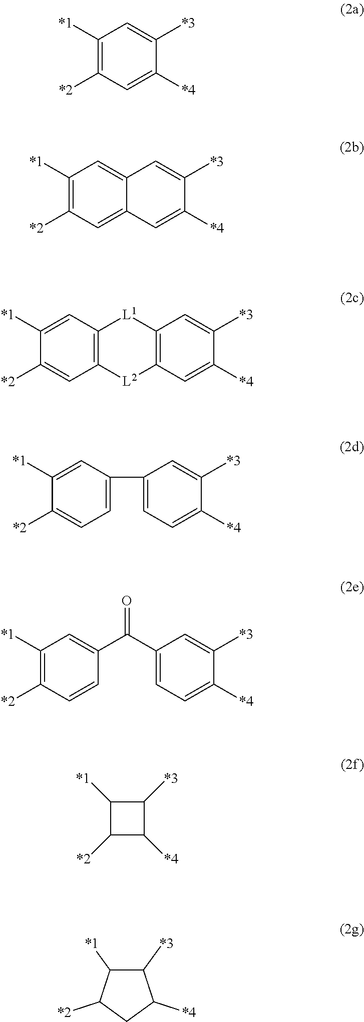
in Formulae (2a) to (2g), L¹ and L² are each independently a divalent group that is not conjugated with a benzene ring to which each of L¹ and L² is bonded, or a single bond, * 1 to *4 each represent a bonding site to the carbonyl group described in Formula (1-2), Formula (1-3), or Formula (1-4), and hydrogen atoms in these structures may be substituted with a substituent.

3. The resin composition according to claim 2,
wherein the resin further includes at least one repeating unit selected from the group consisting of a repeating unit B-2, a repeating unit B-3, and a repeating unit B-4,
repeating unit B-2: a repeating unit represented by Formula (1-2), in which X² includes a structure obtained by removing two or more hydrogen atoms from a structure represented by any of Formulae (V-1) to (V-10),
repeating unit B-3: a repeating unit represented by Formula (1-3), in which X³ includes a structure obtained by removing two or more hydrogen atoms from a structure represented by any of Formulae (V-1) to (V-10),
repeating unit B-4: a repeating unit represented by Formula (1-4), in which X⁴ includes a structure obtained by removing two or more hydrogen atoms from a structure represented by any of Formulae (V-1) to (V-10), 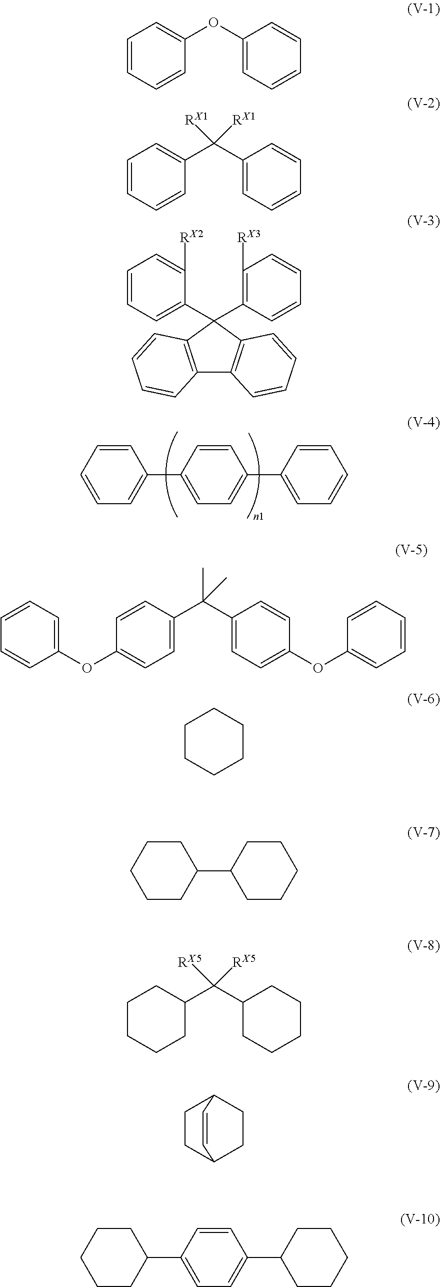
in Formula (V-2), R^{X1}'s each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure,
in Formula (V-4), n1 represents an integer of 1 or more, and
in Formula (V-8), R^{X5}'s each independently represent a hydrogen atom, an alkyl group, or a halogenated alkyl group.

4. The resin composition according to claim 1,
wherein the resin includes at least one repeating unit selected from the group consisting of a repeating unit represented by Formula (1-2), in which R² is a monovalent organic group having an ethylenically unsaturated bond, a repeating unit represented by Formula (1-3), in which R³ is a monovalent organic group having an ethylenically unsaturated bond, and a repeating unit represented by Formula (1-4), in which at least one of R⁴¹ or R⁴² is a monovalent organic group having an ethylenically unsaturated bond.

5. The resin composition according to claim 1,
wherein the resin includes at least one repeating unit selected from the group consisting of a repeating unit represented by Formula (1-2), in which Y² is a structure including a structure represented by Formulae (C-1) to (C-5), a repeating unit represented by Formula (1-3), in which Y³ is a structure including a structure represented by Formulae (C-1) to (C-5), and a repeating unit represented by Formula (1-4), in which Y⁴ is a structure including a structure represented by Formulae (C-1) to (C-5), 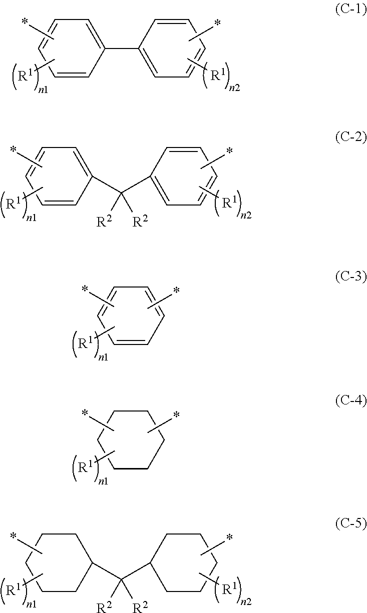
in Formula (C-1), R¹'s each independently represent a hydrogen atom or a monovalent organic group, n1 represents an integer of 0 to 3, n2 represents an integer of 0 to 3, and * represents a bonding site to another structure,
in Formula (C-2), R¹'s each independently represent a hydrogen atom or a monovalent organic group, n1 represents an integer of 0 to 3, n2 represents an integer of 0 to 3, R²'s each independently represent an alkyl group or a fluoroalkyl group, and * represents a bonding site to another structure,
in Formula (C-3), R¹'s each independently represent a hydrogen atom or a monovalent organic group, n1 represents an integer of 0 to 3, and * represents a bonding site to another structure,
in Formula (C-4), R¹'s each independently represent a hydrogen atom or a monovalent organic group, n1 represents an integer of 0 to 3, and * represents a bonding site to another structure, and
in Formula (C-5), R¹'s each independently represent a hydrogen atom or a monovalent organic group, n1 represents an integer of 0 to 3, n2 represents an integer of 0 to 3, R²'s each independently represent an alkyl group or a fluoroalkyl group, and * represents a bonding site to another structure.

6. The resin composition according to claim 1,
wherein the resin includes a repeating unit represented by Formula (1-1), 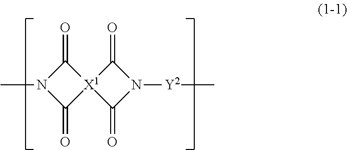
X¹ is a tetravalent organic group, and Y¹ is a divalent organic group.

7. The resin composition according to claim 1,
wherein a weight-average molecular weight of the resin is 5,000 or more and less than 120,000.

8. The resin composition according to claim 1,
wherein the resin composition contains no polymerizable compound or contains a polymerizable compound in an amount of less than 15% by mass with respect to a total solid content.

9. The resin composition according to claim 1,
wherein the resin composition contains no polymerizable compound or contains a polymerizable compound in an amount of 10 parts by mass or less with respect to 100 parts by mass of the resin.

10. The resin composition according to claim 1,
wherein the resin composition contains a polymerizable compound in an amount of 1 to 10 parts by mass with respect to 100 parts by mass of the resin.

11. The resin composition according to claim 1,
wherein the imidization rate is 55% or more and less than 70%.

12. The resin composition according to claim 1,
wherein the resin composition is a negative-type photosensitive resin composition.

13. The resin composition according to claim 1,
wherein the resin composition is used for forming an interlayer insulating film for a re-distribution layer.

14. A cured product obtained by curing the resin composition according to claim 1.

15. A laminate comprising two or more layers consisting of the cured product according to claim 14; and a metal layer provided between any of the layers consisting of the cured product.

16. A method for producing a cured product, comprising a film forming step of applying the resin composition according to claim 1 onto a base material to form a film.

17. The method for producing a cured product according to claim 16, further comprising an exposure step of selectively exposing the film; and a development step of developing the film using a developer to form a pattern.

18. The method for producing a cured product according to claim 16, further comprising a heating step of heating the film at 50° C. to 450° C.

19. A method for producing a laminate, comprising the method for producing a cured product according to claim 16.

20. A method for producing a semiconductor device, comprising the method for producing a cured product according to claim 16.

21. A semiconductor device comprising the cured product according to claim 14.

22. A method for producing a resin, comprising:
a step of synthesizing a polyimide oligomer having an amino group at a terminal; and
a step of reacting the polyimide oligomer with a compound represented by Formula (A-1), 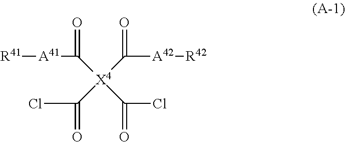
in Formula (A-1), A⁴¹ and A⁴² are each independently —O— or —NR^{Z}—, R^{Z} is a hydrogen atom or a monovalent organic group, R⁴¹ and R⁴² are each independently a hydrogen atom or a monovalent organic group, and X⁴ is a tetravalent organic group.
